(19) United States
(12) Patent Application Publication
(10) Pub. No.: US 2013/0020647 A1
(43) Pub. Date: Jan. 24, 2013

(54) SEMICONDUCTOR DEVICES AND METHODS OF FABRICATING THE SAME

(71) Applicants: Sung-Min HWANG, Seoul (KR); In-Wook Oh, Suwon-si (KR); Woonkyung Lee, Seongnam-si (KR); Aaron Park, Seoul (KR); Hoosung Cho, Yongin-si (KR)

(72) Inventors: Sung-Min HWANG, Seoul (KR); In-Wook Oh, Suwon-si (KR); Woonkyung Lee, Seongnam-si (KR); Aaron Park, Seoul (KR); Hoosung Cho, Yongin-si (KR)

(21) Appl. No.: 13/540,799

(22) Filed: Jul. 3, 2012

(30) Foreign Application Priority Data
Jul. 19, 2011 (KR) 10-2011-0071399

(51) Int. Cl. H01L 29/78; H01L 23/498

(52) U.S. Cl. 257/365; 257/773; 257/E23.06; 257/E29.264

(57) ABSTRACT

Semiconductor devices are provided. The semiconductor device includes conductive patterns vertically stacked on a substrate to be spaced apart from each other, and pad patterns electrically connected to respective ones of the conductive patterns. Each of the pad patterns includes a flat portion extending from an end of the conductive pattern in a first direction parallel with the substrate and a landing sidewall portion upwardly extending from an end of the flat portion. A width of a portion of the landing sidewall portion in a second direction parallel with the substrate and perpendicular to the first direction is less than a width of the flat portion in the second direction. The related methods are also provided.

### CROSS-REFERENCE TO RELATED APPLICATIONS

This U.S. non-provisional patent application claims priority under 35 U.S.C. §119 to Korean Patent Application No. 10-2011-0071399, filed on Jul. 19, 2011, the disclosure of which is hereby incorporated by reference in its entirety.

### TECHNICAL FIELD

Embodiments of the present disclosure herein relate to semiconductor devices having horizontal and vertical conductive patterns and methods of fabricating the same.

### DISCUSSION OF RELATED ART

Demand for highly integrated semiconductor memory devices has been increasing with the development of electronic industry. To make semiconductor devices further integrated, integration density can be increased, for example, by decreasing the sizes of the conductive patterns. However, even with high integration density, the capacity of a planar semiconductor memory device is limited by its available planar area.

### SUMMARY

According to an exemplary embodiment, there is provided a semiconductor device including conductive patterns vertically stacked on a substrate to be spaced apart from each other and pad patterns electrically connected to respective ones of the conductive patterns. Each of the pad patterns includes a flat portion extending from an end of the conductive pattern in a first direction parallel with the substrate and a landing sidewall portion upwardly extending from an end of the flat portion. A width of a portion of the landing sidewall portion in a second direction parallel with the substrate and perpendicular to the first direction is less than a width of the flat portion in the second direction.

In an embodiment, the landing sidewall portion includes a first portion extending in the first direction and a second portion extending in the second direction. A width of the first portion in the first direction is greater than a thickness of each of the conductive patterns in a third direction perpendicular to a top surface of the substrate.

In an embodiment, the semiconductor device further includes auxiliary pad patterns extending from respective ones of the conductive patterns in the first direction to be spaced apart from the pad patterns. Each of the auxiliary pad patterns includes an auxiliary flat portion parallel with the substrate and an auxiliary sidewall portion upwardly extending from an end of the auxiliary flat portion.

In an embodiment, a top surface area of the auxiliary sidewall portion is equal to a top surface area of the landing sidewall portion in a plan view.

In an embodiment, the conductive patterns include first and second conductive patterns, which are located at the same level from the substrate and are spaced apart from each other. The first conductive pattern includes first gate electrodes and a first connector connecting first ends of the first gate electrodes to each other. The second conductive pattern includes second gate electrodes and a second connector connecting first ends of the second gate electrodes to each other. One of the first gate electrodes is disposed between the second gate electrodes, and one of the second gate electrodes is disposed between the first gate electrodes.

In an embodiment, the pad patterns include a first pad pattern extending from the first connector in the first direction and a second pad pattern extending from the second connector in a direction opposite to the first direction

In an embodiment, the conductive patterns include first and second conductive patterns, which are located at the same level from the substrate and are spaced apart from each other. The first conductive pattern includes first gate electrodes and a first connector connecting first ends of the first gate electrodes to each other. The second conductive pattern includes second gate electrodes and a second connector connecting first ends of the second gate electrodes to each other. The first gate electrodes may not be disposed between the second gate electrodes, and the second gate electrodes may not be disposed between the first gate electrodes.

In an embodiment, the semiconductor device further includes semiconductor pillars penetrating the stacked conductive patterns and a data storage layer between the semiconductor pillars and the conductive patterns.

In an embodiment, the semiconductor device further includes a contact plug on the landing sidewall portion.

According to an exemplary embodiment, there is provided a method of manufacturing a three dimensional semiconductor memory device, the method including providing a substrate including a first region and a second region, and forming a pattern structure having an intaglio pattern on the substrate in the first region. A top surface of the pattern structure is higher than a top surface of the substrate in the second region. A width of the intaglio pattern in a second direction is stepwise reduced toward a first direction perpendicular to the second direction. The intaglio pattern is opened toward the second region. The first direction and the second direction are parallel with the top surface of the substrate.

In an embodiment, the method further includes alternately and repeatedly stacking first material layers and second material layers on the substrate including the pattern structure, forming semiconductor pillars penetrating the first and second material layers, patterning the first and second material layers to form a first trench defining first material patterns and second material patterns, and partially removing the first material patterns exposed by the first trench to form recessed regions. The first trench includes a first area extending in the first direction and a second area extending in the second direction.

In an embodiment, the number of the semiconductor pillars is two or more and the semiconductor pillars are arrayed in rows parallel with the first direction. The method further includes patterning the first material layers and the second material layers to form second trenches disposed between the rows to extend in the first direction.

In an embodiment, the method further includes patterning the first material layers and the second material layers to form third trenches connecting ends of the second trenches.

In an embodiment, the third trenches are formed to be parallel with the second direction.

### BRIEF DESCRIPTION OF THE DRAWINGS

The embodiments of the disclosure will become more apparent in view of the attached drawings and accompanying detailed description.

FIGS. 1, 2A and 2B are perspective views illustrating a semiconductor device according to an exemplary embodiment.

FIG. 3 is an enlarged view illustrating a portion ‘I’ of FIG. 1 to describe a data storage layer of a semiconductor device according to an exemplary embodiment.

FIGS. 4A to 4I are perspective views illustrating a method of fabricating a semiconductor device according to an exemplary embodiment.

FIG. 5 is a perspective view illustrating a semiconductor device according to an exemplary embodiment.

FIG. 6 is an enlarged view illustrating a portion ‘II’ of FIG. 5 to describe a barrier layer of a semiconductor device according to an exemplary embodiment.

FIG. 7A to 7I are perspective views illustrating a method of fabricating a semiconductor device according to an exemplary embodiment.

FIGS. 8, 9A and 9B are perspective views illustrating a semiconductor device according to an exemplary embodiment.

FIG. 10A to 10G are perspective views illustrating a method of fabricating a semiconductor device according to an exemplary embodiment.

FIGS. 11, 12A and 12B are perspective views illustrating a semiconductor device according to an exemplary embodiment.

FIG. 13 is an enlarged view illustrating a portion ‘III’ of FIG. 11 to describe a data storage layer of a semiconductor device according to an exemplary embodiment.

FIGS. 14A to 14F are perspective views illustrating a method of fabricating a semiconductor device according to an exemplary embodiment.

FIG. 15 is a perspective view illustrating a semiconductor device according to an exemplary embodiment.

FIG. 16 is an enlarged view illustrating a portion ‘IV’ of FIG. 15 to describe a barrier layer of a semiconductor device according to an exemplary embodiment.

FIG. 17A to 17I are perspective views illustrating a method of fabricating a semiconductor device according to an exemplary embodiment.

FIGS. 18, 19A and 19B are perspective views illustrating a semiconductor device according to an exemplary embodiment.

FIGS. 20A to 20G are perspective views illustrating a method of fabricating a semiconductor device according to an exemplary embodiment.

FIGS. 21 and 22 are perspective views illustrating a semiconductor device according to an exemplary embodiment.

FIGS. 23A to 23D are perspective views illustrating a method of fabricating a semiconductor device according to an exemplary embodiment.

FIGS. 24A to 24F are perspective views illustrating a method of fabricating a semiconductor device according to an exemplary embodiment and a semiconductor device fabricated by the method.

FIGS. 25A to 25D are perspective views illustrating a method of fabricating a semiconductor device according to an exemplary embodiment and a semiconductor device fabricated by the method.

FIG. 26 is a perspective view illustrating conductive patterns and pad patterns of a semiconductor device fabricated according to an exemplary embodiment.

FIGS. 27A and 27B are perspective views illustrating a method of fabricating a semiconductor device according to an exemplary embodiment and a semiconductor device fabricated by the method.

FIG. 28 is a perspective view illustrating conductive patterns and pad patterns of a semiconductor device fabricated according to an exemplary embodiment.

FIG. 29 is a block diagrams illustrating an exemplary memory card including a semiconductor device according to an exemplary embodiment.

FIG. 30 is block diagrams illustrating an exemplary information processing system including a semiconductor device according to an exemplary embodiment.

### DETAILED DESCRIPTION OF THE EMBODIMENTS

Exemplary embodiments are described below with reference to the accompanying drawings. Many different forms and embodiments are possible without deviating from the spirit and teachings of this disclosure and so the disclosure should not be construed as limited to the exemplary embodiments set forth herein. In the drawings, the sizes and relative sizes of layers and regions may be exaggerated for clarity. Like reference numbers may refer to like or similar elements throughout the specification and the drawings.

It will be understood that when an element is referred to as being “coupled,” “connected,” or “responsive” to, or “on,” another element, it can be directly coupled, connected, or responsive to, or on, the other element, or intervening elements may also be present.

As used herein, the singular forms “a,” “an,” and “the” are intended to include the plural forms as well, unless the context clearly indicates otherwise.

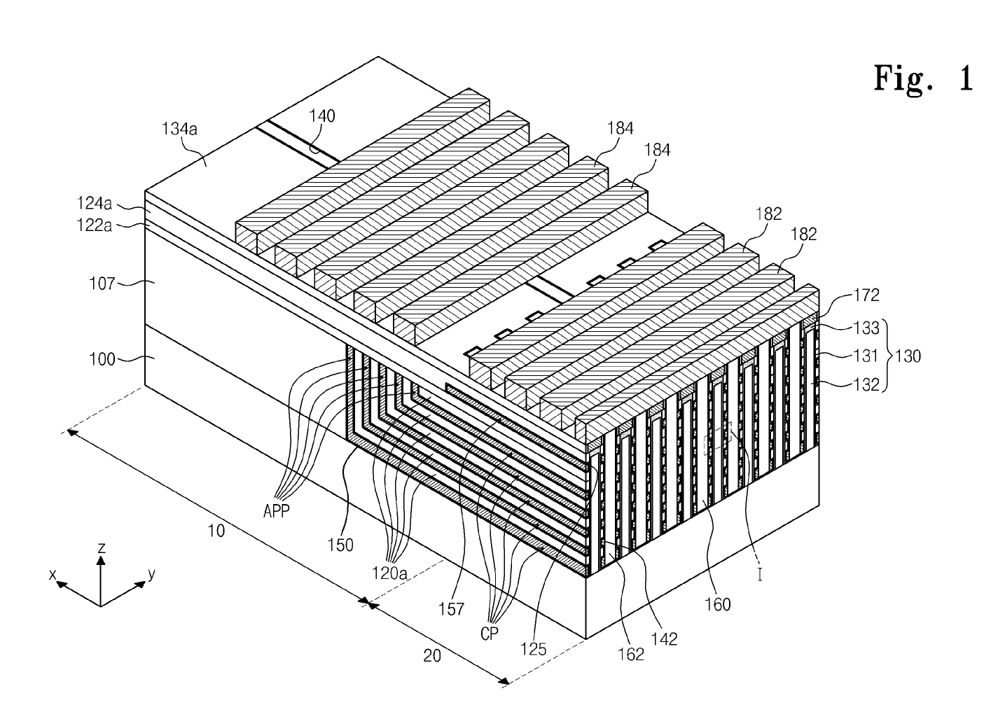

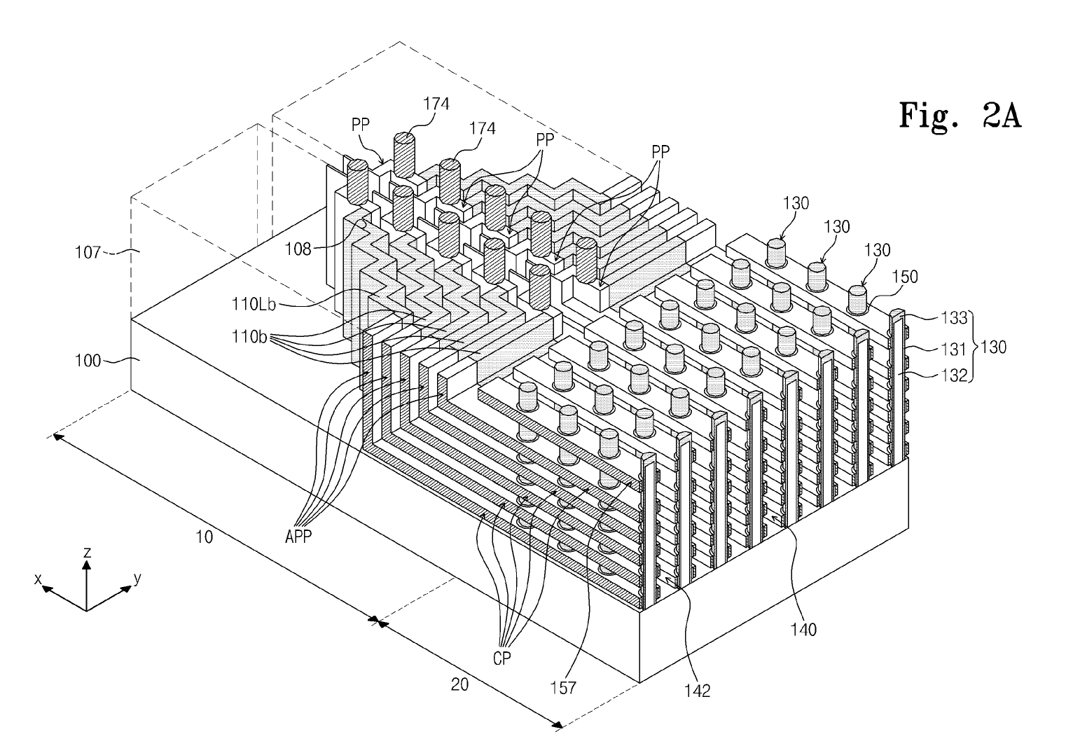

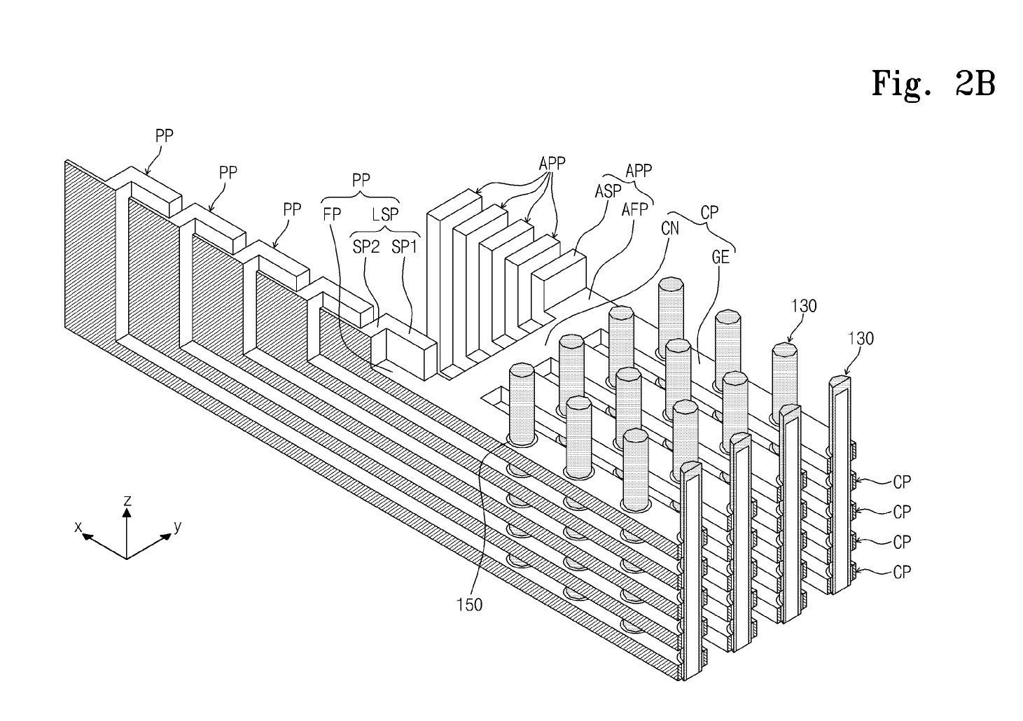

FIGS. 1, 2A and 2B are perspective views illustrating a semiconductor device according to an exemplary embodiment. For convenience of description, FIG. 2A illustrates conductive patterns CP, pad patterns PP, auxiliary pad patterns APP, string selection lines 157, semiconductor pillars 130, sacrificial patterns 110Lb and 110b, cell contact plugs 174, conductive interconnection lines 184, bit lines 182 and a substrate 100 which are described below, and FIG. 2B illustrates conductive patterns CP included in a single stack structure, pad patterns PP connected to the conductive patterns CP, and auxiliary pad patterns APP connected to the conductive patterns CP. For convenience of recognition, portions of the conductive patterns CP, the pad patterns PP and the auxiliary pad patterns APP of FIGS. 2A and 2B are hatched.

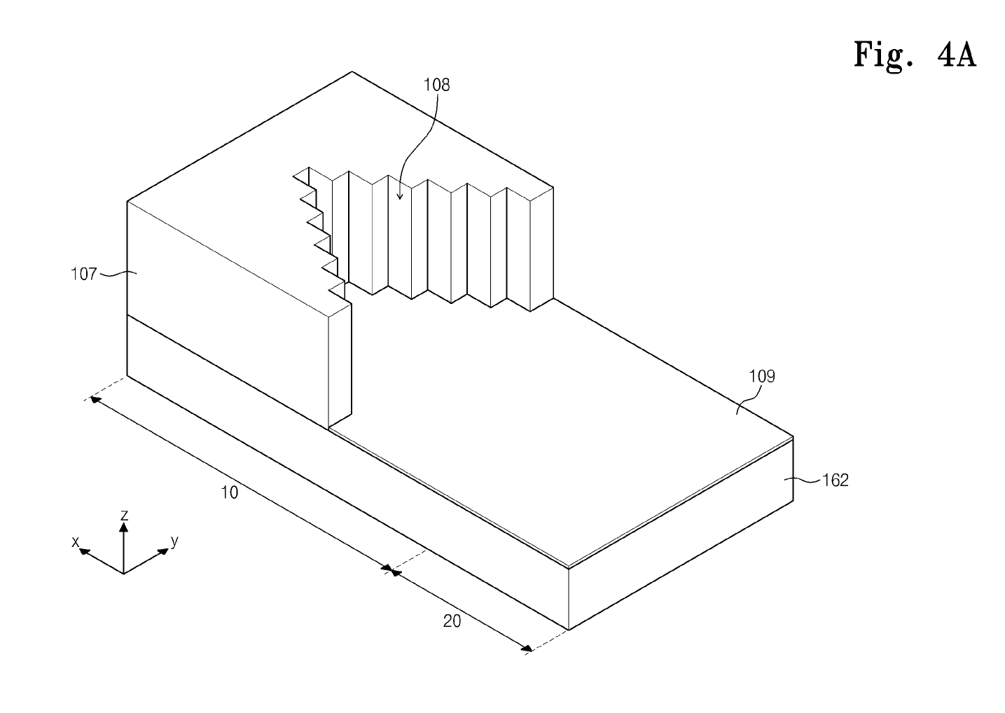

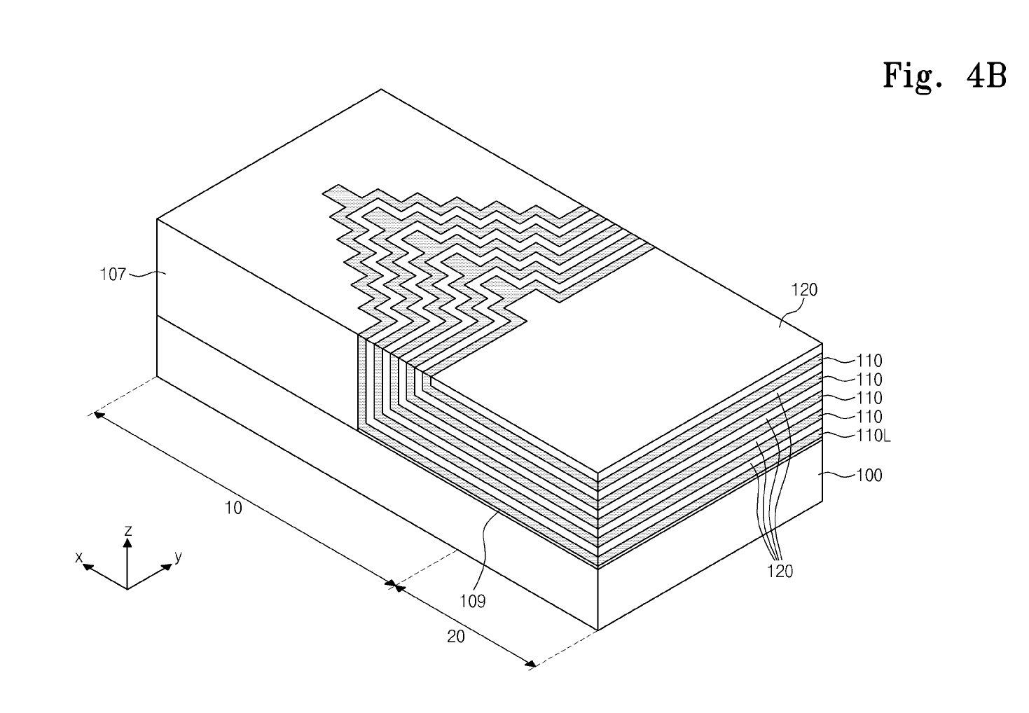

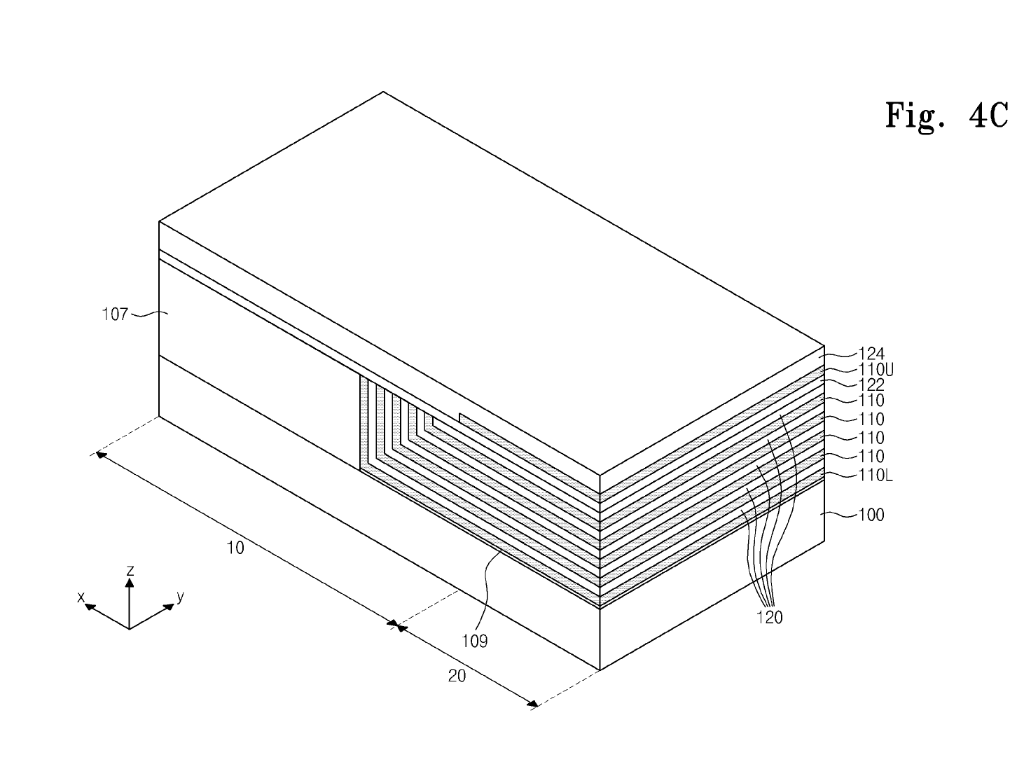

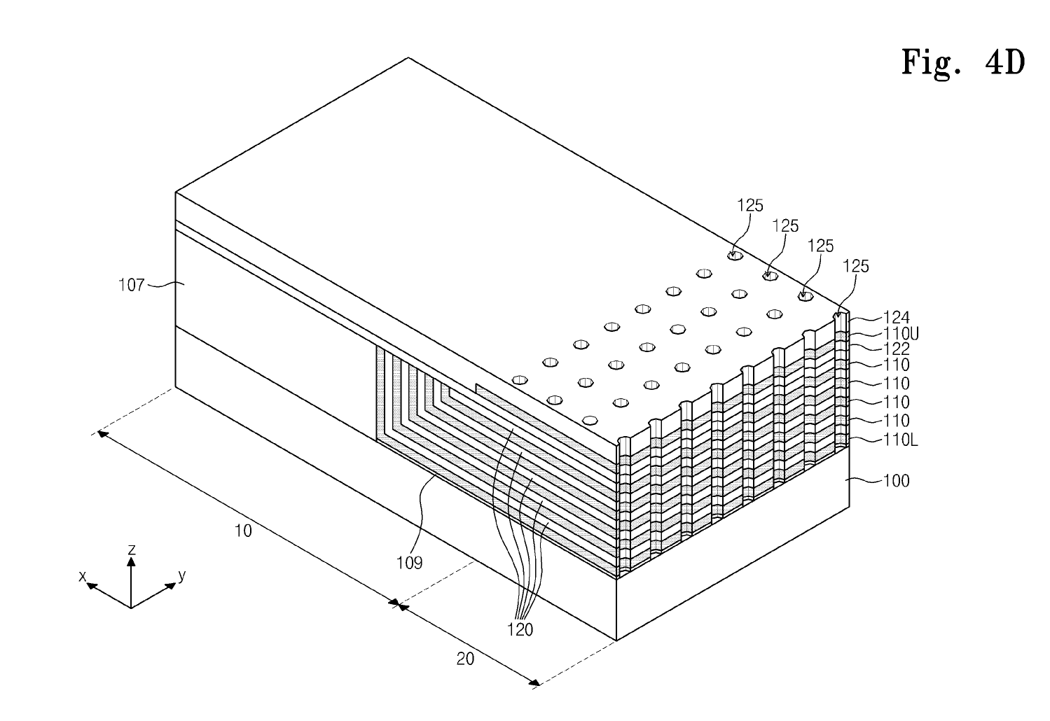

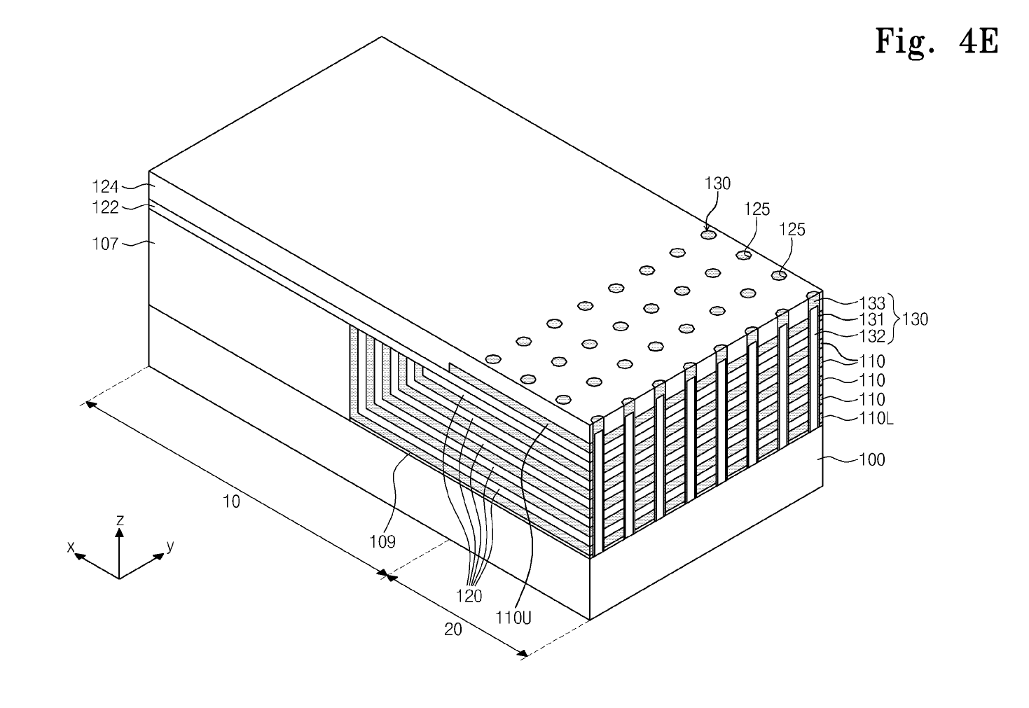

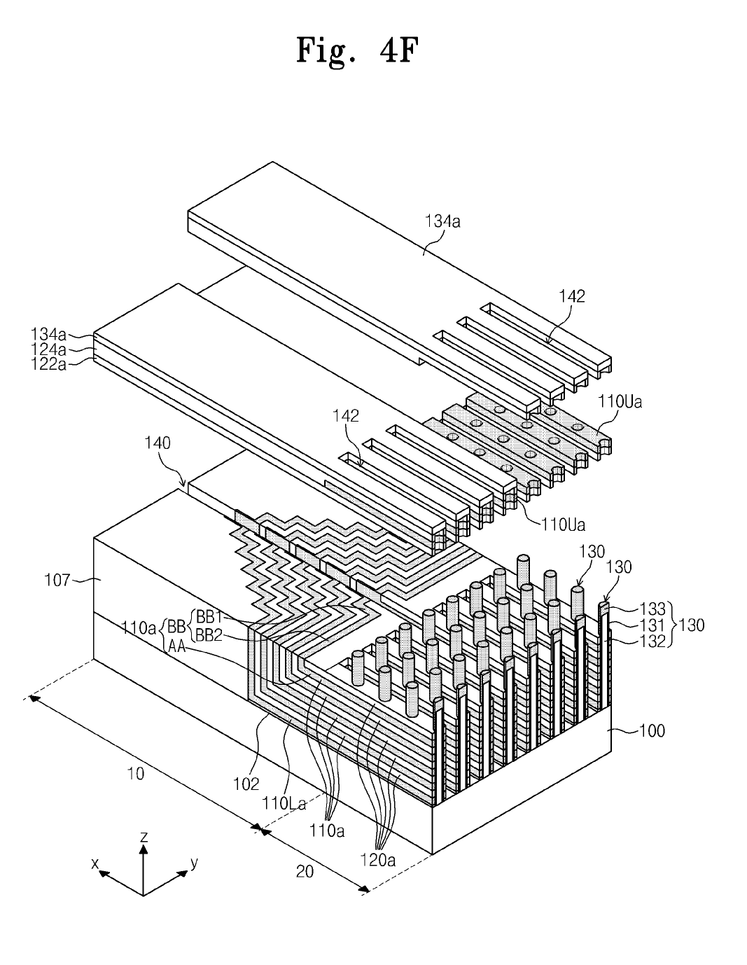

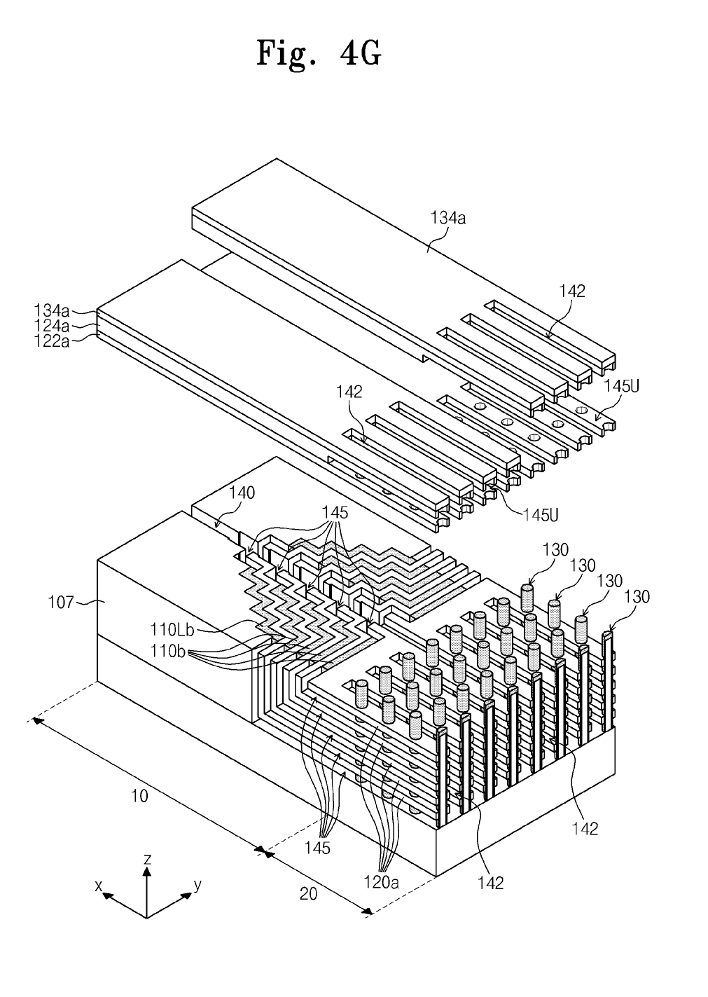

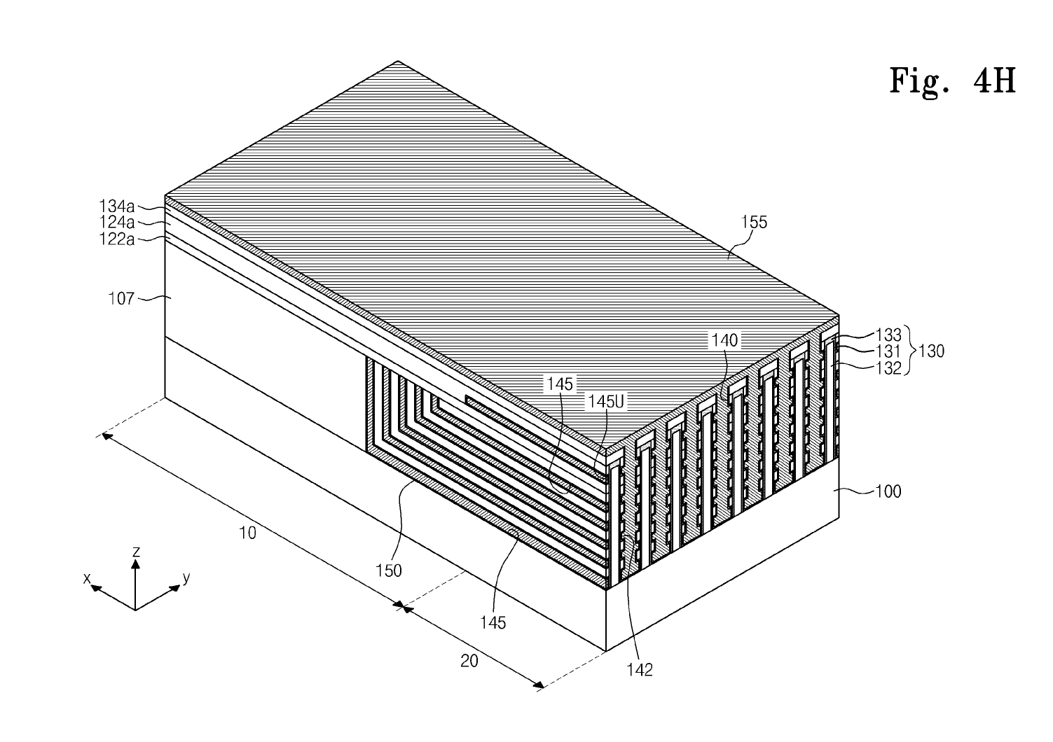

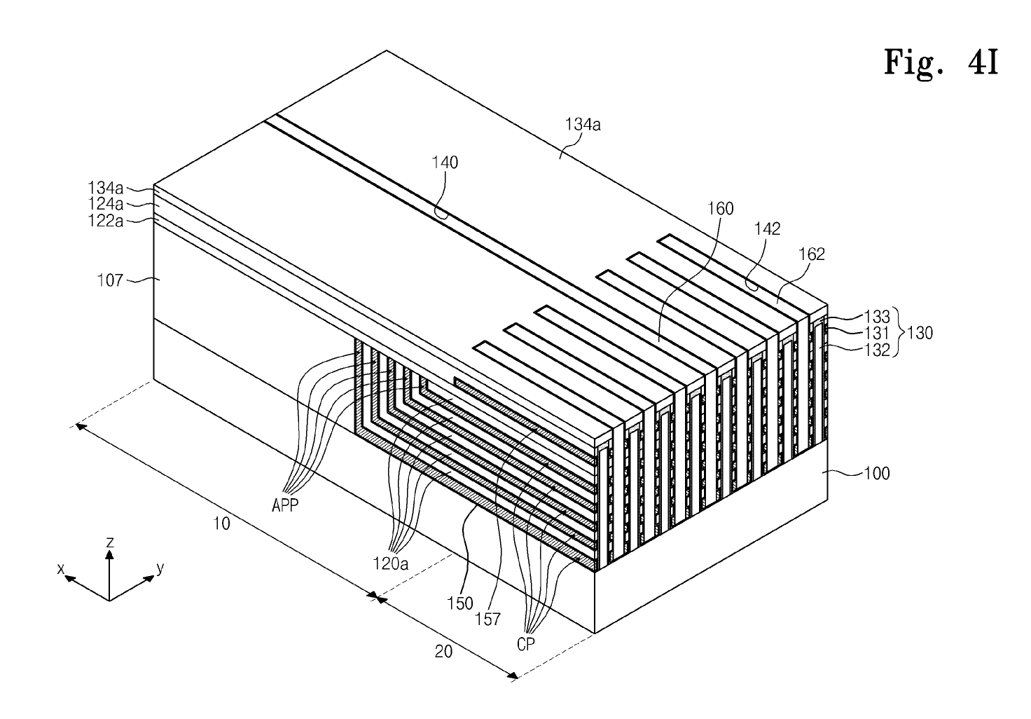

Referring to FIG. 1, 2A and 2B, the substrate 100 includes a first region 10 and a second region 20. In the first region 10, the pad patterns are disposed, and in the second region 20, cells are three-dimensionally arrayed. The substrate 100 includes a semiconductor substrate. For example, according to an embodiment, the substrate 100 includes a silicon substrate, a germanium substrate, a silicon-germanium substrate or a compound semiconductor substrate. The substrate 100 is doped with dopants of a first conductivity type. A pattern structure 107 is disposed on the substrate 100 in the first region 10. Top surfaces of the pattern structure 107 are higher than a top surface of the substrate 100. The pattern structure 107 includes an empty space defined by an intaglio pattern 108 (refer to FIGS. 2A and 4A). A width of the intaglio pattern 108 in a second direction is stepwise reduced in a first direction from an edge of the pattern structure 107 toward a bulk region of the pattern structure 107. The first direction and the second direction are parallel with the top surface of the substrate 100, and the first direction intersects the second direction. In the drawings, the first direction corresponds to an x-axis direction, and the second direction corresponds to a y-axis direction. The intaglio pattern 108 is opened toward the second region 20. The intaglio pattern 108 has an opened upper portion and an opened side portion. The pattern structure 107 (e.g., a body of the pattern structure 107) includes an insulation material. For example, according to an embodiment, the pattern structure 107 includes a silicon oxide layer. Alternatively, the pattern structure 107 is formed of the same material as the substrate 100. According to an embodiment, the pattern structure 107 extends from the substrate 100. The pattern structure 107 and the substrate 100 constitute an integrated body without any junction between the pattern structure 107 and the substrate 100.

The plurality of conductive patterns CP are vertically stacked on the substrate 100 in the second region 20 and are spaced apart from each other. Each of the conductive patterns CP includes a plurality of gate electrodes GE and a connector CN connecting ends of the gate electrodes GE to one another. The plurality of conductive patterns CP are included in the single stack structure.

The gate electrodes GE included in each of the conductive patterns CP extend in the first direction at the same level from the top surface of the substrate 100 which is regarded as a reference level. The gate electrodes GE included in each of the conductive patterns CP are spaced apart from each other in the second direction. The gate electrodes GE each have a line shape in the first direction. Sub-trenches 142 are provided between the gate electrodes GE included in each of the conductive patterns CP. The sub-trenches 142 are filled with sub-isolation patterns 162. The sub-isolation patterns 162 each include a silicon oxide layer.

The connector CN includes a first sidewall contacting the gate electrodes GE and a second sidewall opposite to the first sidewall. The connector CN has a line shape extending in the second direction. Connectors CN are vertically stacked on the substrate 100 in the second region 20 and are spaced apart from each other.

The pad patterns PP extend from respective ones of ends of the conductive patterns CP. The pad patterns PP extend in the first region 10 along the first direction. Each of the pad patterns PP is connected to a portion of the second sidewall of each corresponding connector of the connectors CN. Each of the pad patterns PP is adjacent to an end of each corresponding connector of the connectors CN. The pad pattern PP connected to the conductive pattern CP located at a relatively lower level extends in the first direction to be longer than the pad pattern PP connected to the conductive pattern CP located at a relatively higher level.

Each of the pad patterns PP includes a flat portion FP and a landing sidewall portion LSP upwardly extending from a top surface of the flat portion FP. The flat portion FP extends from a portion of the second sidewall of the connector CN, which is adjacent to an end of the connector CN, along the first direction. The flat portion FP of each of the pad patterns PP and the conductive pattern CP connected to the flat portion FP are located at the same level from the top surface of the substrate 100 and have the same thickness. The flat portion FP connected to the conductive pattern CP located at a relatively lower level extends in the first direction to be longer than the flat portion FP connected to the conductive pattern CP located at a relatively higher level. Thus, the flat portions FP connected to respective ones of the conductive patterns CP have a terraced structure. For example, a length of the flat portion FP in the first direction decreases upwardly from the top surface of the substrate 100. Thus, the flap portions FP vertically stacked have a downward step structure in the first direction (e.g., a positive x-axis direction).

Top surfaces of all the landing sidewall portions LSP are located at substantially the same level from the substrate 100. The landing sidewall portion LSP extending from the flat portion FP connected to the conductive pattern CP located at a relatively lower level has a greater length in a third direction than the landing sidewall portion LSP extending from the flat portion FP connected to the conductive pattern CP located at a relatively higher level. The third direction corresponds to a z-axis direction which is perpendicular to the x-axis direction and the y-axis direction.

Each of the landing sidewall portion LSP includes a first portion SP1 extending in the first direction and a second portion SP2 extending in the second direction. A width of the first portion SP1 of the landing sidewall portion LSP in the first direction is less than a width of the flat portion FP in the first direction and is greater than a thickness of the conductive pattern CP in the third direction. A width of the first portion SP1 of the landing sidewall portion LSP in the second direction is less than a width of the flat portion FP in the second direction. A width of the second portion SP2 of the landing sidewall portion LSP in the second direction is equal to a width of the flat portion FP in the second direction. A distance between the first portion SP1 and the conductive pattern CP is less than a distance between the second portion SP2 and the conductive pattern CP.

When viewed from a plan view parallel with an x-y plane, top surfaces of the first portions SP1 of the landing sidewall portions LSP connected to the conductive patterns CP are arrayed along the first direction and constitute a row which is parallel with the x-axis direction. The first portions SP 1 arrayed in the row are spaced apart from each other. Each of top surfaces of the first portions SP1 has two long sides which are parallel with the first direction. Each of the top surfaces of the first portions SP1 has a rectangular shape. Distances between the first portions SP1 adjacent to each other along the first direction are less than a length of the long sides of the top surfaces of the first portions SP1. An area of each of the top surfaces of the first portions SP 1 is greater than an area of each of top surfaces of the second portions SP2. Top surfaces of the landing sidewall portions LSP have substantially the same area. A length of short sides of the top surfaces of the first portions SP1 is substantially equal to the thickness of the conductive patterns CP in the third direction. In each of the pad patterns PP, a width of the first portion SP1 in the second direction is equal to a width of the second portion SP2 in the first direction.

The auxiliary pad patterns APP extend from respective ones of the conductive patterns CP in the first direction. The auxiliary pad patterns APP are spaced apart from the pad patterns PP. When each of the connectors CN has first and second ends which face each other, the pad patterns PP are connected to the second sidewalls of the connectors CN adjacent to the first ends of the connectors CN, and the auxiliary pad patterns APP are connected to the second sidewalls of the connectors CN adjacent to the second ends of the connectors CN. The auxiliary pad pattern APP connected to the conductive pattern CP located at a relatively lower level extends in the first direction to be longer than the auxiliary pad pattern APP connected to the conductive pattern CP located at a relatively higher level.

Each of the auxiliary pad patterns APP includes an auxiliary flat portion AFP extending from a corresponding conductive pattern CP of the conductive patterns CP in the first direction and an auxiliary sidewall portion ASP upwardly extending from an end of the auxiliary flat portion AFP. The auxiliary flat portion AFP extends from the second sidewalls of the connectors CN adjacent to the second ends of the connectors CN in the first direction. The auxiliary flat portion AFP connected to the conductive pattern CP located at a relatively lower level extends in the first direction to be longer than the auxiliary flat portion AFP connected to the conductive pattern CP located at a relatively higher level. Thus, the auxiliary flat portions AFP connected to respective ones of the conductive patterns CP have a terraced structure. For example, a length of the auxiliary flat portion AFP in the first direction decreases upwardly from the top surface of the substrate 100. Thus, the auxiliary flap portions AFP vertically stacked have a downward step structure in the first direction (e.g., a positive x-axis direction). The auxiliary flat portion AFP of each of the auxiliary pad patterns APP and the conductive pattern CP connected to the auxiliary flat portion AFP are located at the same level from the top surface of the substrate 100 and have the same thickness.

Top surfaces of all the auxiliary sidewall portions ASP are located at substantially the same level from the substrate 100. The auxiliary sidewall portions ASP extend in the second direction. A width of the respective auxiliary sidewall portions ASP in the second direction is equal to a width of the respective auxiliary flat portions AFP in the second direction. A width of the respective auxiliary sidewall portions ASP in the first direction is substantially equal to a thickness of the respective auxiliary flat portions AFP in the third direction.

Each of the conductive patterns CP, the pad pattern PP connected to the conductive pattern, and the auxiliary pad pattern APP connected to the conductive pattern constitute a single unified body without any junction between the conductive pattern CP, the pad pattern PP, and the auxiliary pad pattern APP.

Insulation patterns 120a are disposed in respective ones of spaces between the conductive patterns CP vertically stacked. Each of the insulation patterns 120a under the uppermost insulation pattern 120a includes an insulation flat portion and an insulation sidewall portion. The insulation flat portion is parallel with the substrate 100, and the insulation sidewall portion upwardly extends from an end of the insulation flat portion. The insulation flat portions of the insulation patterns 120a are disposed in respective ones of spaces between the conductive patterns CP. The insulation flat portions extend and intervene between the flat portions FP and between the auxiliary flat portions AFP. The insulation sidewall portions of the insulation patterns 120a are disposed in respective ones of spaces between the landing sidewall portions LSP and in respective ones of spaces between the auxiliary sidewall portions ASP.

A first upper insulation pattern 122a, string selection lines 157, a second upper insulation pattern 124a and a capping insulation pattern 134a are sequentially stacked on the substrate including the insulation patterns 120a. The string selection lines 157 are disposed on the first upper insulation pattern 122a in the second region 20, and each of the string selection lines 157 has a line shape extending in the first direction. The string selection lines 157 are spaced apart from each other in the second direction. The string selection lines 157 are disposed on respective ones of the gate electrodes GE of the uppermost conductive pattern CP. The string selection lines 157 are disposed to be parallel with the gate electrodes GE. The number of the string selection lines 157 is equal to the number of the gate electrodes GE of each of the conductive patterns CP. The string selection lines 157 are located at the same level from the substrate 100.

The single stack structure includes the vertically stacked conductive patterns CP, the string selection lines 157 on the vertically stacked conductive patterns CP, the insulation patterns 120a, the first upper insulation pattern 122a and the second upper insulation pattern 124a. In an embodiment, the number of the stack structures disposed on the substrate 100 is two or more. A main isolation pattern 160 is disposed between two adjacent stack structures. The two adjacent stack structures have a symmetrical configuration with respect to the main isolation pattern 160. The main isolation pattern 160 is disposed in a main trench 140 defined between the two adjacent stack structures. The main isolation pattern 160 is disposed on the substrate 100 at a side of each of the stack structures. The main isolation pattern 160 includes a silicon oxide layer. The stack structures are spaced apart from each other in the second direction.

The sacrificial patterns 110Lb and 110b are disposed between the pad patterns PP and the auxiliary pad pattern APP, which are connected to the conductive patterns CP in each of the stack structures. Each of the sacrificial patterns 110Lb and 110b includes a sacrificial flat portion extending from a corresponding conductive pattern CP of the conductive patterns CP in the first direction and a sacrificial sidewall portion upwardly extending from an end of the sacrificial flat portion. The sacrificial flat portion is disposed between the flat portion FP of the pad pattern PP and the auxiliary flat portion AFP of the auxiliary pad pattern APP. The sacrificial sidewall portion is disposed between the landing sidewall portion LSP of the pad pattern PP and the auxiliary sidewall portion ASP of the auxiliary pad pattern APP.

The sacrificial flat portion connected to the conductive pattern CP located at a relatively lower level extends in the first direction to be longer than the sacrificial flat portion connected to the conductive pattern CP located at a relatively higher level. A width (e.g., a distance along the second direction) of each of the sacrificial flat portions under the uppermost sacrificial flat portion is stepwise reduced in a direction away from the conductive pattern CP connected to the sacrificial flat portion. Each of the sacrificial sidewall portions connected to the sacrificial flat portions under the uppermost sacrificial flat portion upper includes a first portion extending in the first direction and a second portion extending in the second direction. In an embodiment, a width (e.g., a distance along the first direction) of the first portions of the sacrificial sidewall portions is greater than a thickness (e.g., a distance along the third direction) of the sacrificial flat portions.

Each of the insulation patterns 120a, 122a, 124a and 134a includes an oxide material, such as a silicon oxide material. The conductive patterns CP, the pad patterns PP and the auxiliary pad patterns APP are formed of a conductive material, such as at least one of a metal layer (e.g., a tungsten layer, an aluminum layer, a titanium layer or a tantalum layer), a conductive metal nitride layer (e.g., a titanium nitride layer or a tantalum nitride layer) and a doped semiconductor layer (e.g., a doped silicon layer, a doped germanium layer or a doped silicon-germanium layer). The sacrificial patterns 110Lb and 110b are formed of a material having an etch selectivity with respect to the insulation patterns 120a, 122a and 124a, such as a silicon nitride layer.

The semiconductor pillars 130 penetrate the gate electrodes GE of the conductive patterns CP and the insulation patterns 120a, 122a and 124a. The semiconductor pillars 130 extend in the third direction. The semiconductor pillars 130 contact the substrate 100. The semiconductor pillars 130 are two-dimensionally arrayed along the first and second directions in a plan view. The plurality of semiconductor pillars 130 penetrate each of the stack structures.

Each of the semiconductor pillars 130 includes a semiconductor portion 131, a filling insulation material 132 and a drain region 133. The semiconductor portion 131 covers a sidewall of a channel opening 125 that penetrates the vertically stacked gate electrodes GE and the insulation patterns 120a, 122a and 124a. The filling insulation material 132 fills an empty space surrounded by the semiconductor portion 131. The drain region 133 fills an upper portion of the channel opening 125. The semiconductor portion 131 and the drain region 133 include a single crystalline semiconductor or a polycrystalline semiconductor. The drain region 133 is doped with dopants of a second conductivity type. For example, the drain region 133 has a different conductivity type from the substrate.

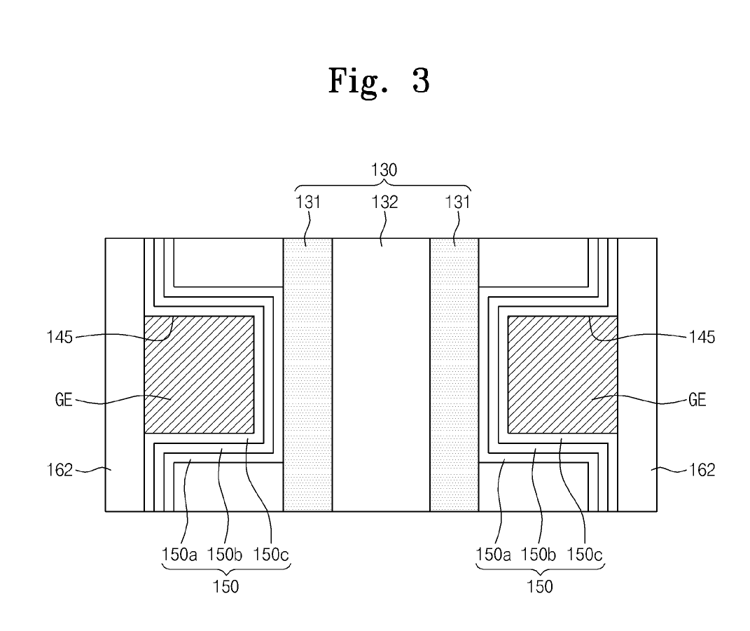

Data storage layers 150 are disposed between respective corresponding semiconductor pillars 130 and respective corresponding gate electrodes GE surrounding the respective semiconductor pillars 130. The data storage layers 150 are fouled of a multi-layered film. Detailed configurations of the data storage layers 150 will be described with reference to FIG. 3.

FIG. 3 is an enlarged view illustrating a portion ‘I’ of FIG. 1 to describe a data storage layer of a semiconductor device according to an exemplary embodiment.

Referring to FIGS. 1, 2A, 2B and 3, the data storage layer 150 includes a tunnel insulation layer 150a, a charge storage layer 150b and a blocking layer 150c. The data storage layer 150 is disposed between the semiconductor pillar 130 and the gate electrodes GE surrounding the semiconductor pillar 130. The tunnel insulation layer 150a is formed to cover the sidewall of the semiconductor pillar 130. The tunnel insulation layer 150a includes a single-layered film or a multi-layered film. For example, the tunnel insulation layer 150a includes at least one of a silicon oxide layer, a silicon oxynitride layer, a silicon nitride layer and a metal oxide layer.

The charge storage layer 150b is separated from the semiconductor pillar 130 by the tunnel insulation layer 150a. The charge storage layer 150b includes charge trap sites which can store electrical charges. For example, the charge storage layer 150b includes at least one of a silicon nitride layer, a metal nitride layer, a metal oxynitride layer, a metal silicate layer, a metal silicon oxynitride layer and a nano-dot layer.

The blocking layer 150c is disposed on the charge storage layer 150b opposite to the tunnel insulation layer 150a. The blocking layer 150c includes at least one of a silicon oxide layer, a silicon oxynitride layer, a silicon nitride layer and a high-k dielectric layer. The high-k dielectric layer includes at least one of a metal oxide layer, a metal nitride layer and metal oxynitride layer. In an embodiment, the high-k dielectric layer contains hafnium (Hf), zirconium (Zr), aluminum (Al), tantalum (Ta), lanthanum (La), cerium (Ce) or praseodymium (Pr) as a metal element of the high-k dielectric layer. The blocking layer 150c has a dielectric constant which is greater than a dielectric constant of the tunnel insulation layer 150a.

The data storage layers 150 between the gate electrodes GE and the semiconductor pillars 130 correspond to data storage elements of the memory cells. The data storage layer 150 between the lowermost gate electrode GE and the semiconductor pillar 130 is included in a gate insulation layer of a lower selection transistor, for example, a ground selection transistor. The data storage layer 150 between the uppermost gate electrode GE (corresponding to the string selection line 157) and the semiconductor pillar 130 is included in a gate insulation layer of an upper selection transistor, for example, a string selection transistor.

One of the semiconductor pillars 130, the gate electrodes GE surrounding the semiconductor pillar 130, and the data storage layer 150 between the gate electrodes GE and the semiconductor pillar 130 constitutes a vertical cell string. The vertical cell string includes a lower selection transistor, a plurality of memory cells and an upper selection transistor which are sequentially stacked and serially connected to each other. The lowermost gate electrode of the gate electrodes GE corresponds to a gate of the lower selection transistor, and the uppermost gate electrode (e.g., the string selection line 157) of the gate electrodes GE corresponds to a gate of the upper selection transistor. The gate electrodes GE between the lowermost gate electrode and the uppermost gate electrode (e.g., the string selection line 157) correspond to gates of the memory cells, respectively.

According to an embodiment, common source regions (not shown) are disposed in the substrate 100 under the main isolation pattern 160 and the sub-isolation patterns 162. The common source regions extend in the first direction. The common source regions are doped with dopants of the second conductivity type. An electrical bias applied to one selected from the lowermost gate electrodes GE controls electrical connections between the semiconductor pillars 130 surrounded by the selected lowermost gate electrode GE and the common source region adjacent to the selected lowermost gate electrode GE.

Cell contact plugs 174 are provided on respective ones of the first portions SP1 of the landing sidewall portions LSP of the pad patterns PP. The cell contact plugs 174 penetrate the capping insulation pattern 134a, the second upper insulation pattern 124a and the first upper insulation pattern 122a. A width of each of the cell contact plugs 174 in the first direction and a width of each of the contact plugs 174 in the second direction are greater than a width of each of the first portions SP1 of the landing sidewall portions LSP in the second direction. A width of each of the first portions SP1 in the first direction is greater than a width of each of the cell contact plugs 174 in the first direction. Thus, a misalignment between the cell contact plugs 174 and the landing sidewall portions LSP or a short circuit between the cell contact plugs 174 may occur less often. Consequently, a high reliable semiconductor device may be realized. Conductive interconnection lines 184 are provided on the capping insulation pattern 134a. The conductive interconnection lines 184 are electrically connected to the conductive patterns CP through the cell contact plugs 174.

Bit lines 182 are also disposed on the capping insulation pattern 134a. The bit lines 182 are electrically connected to the drain regions 133 of the semiconductor pillars 130 through bit line contact plugs 172 that penetrate the capping insulation pattern 134a. An electrical bias applied to one selected from the string selection lines 157 controls electrical connections between the bit lines 182 and the vertical cell strings connected to the selected string selection line 157. The bit lines 182 extend in the second direction. The bit lines 182 intersect the gate electrodes GE in a plan view. The number of the bit lines 182 is two or more. The bit lines 182 are parallel with each other. Each of the bit lines 182 is electrically connected to the drain regions 133 of the semiconductor pillars 130 arrayed in a column which is parallel with the second direction.

A method of fabricating a semiconductor device according to an exemplary embodiment is now described. FIGS. 4A to 4I are perspective views illustrating a method of fabricating a semiconductor device according to an exemplary embodiment.

Referring to FIG. 4A, a substrate 100 having a first region 10 and a second region 20 is provided. The substrate 100 may be doped with dopants of a first conductivity type. A pattern structure 107 is formed on the substrate 100 in the first region 10. The pattern structure 107 includes an empty space defined by an intaglio pattern 108. A width of the intaglio pattern 108 in a second direction is stepwise reduced in a first direction running from an edge of the pattern structure 107 toward a bulk region of the pattern structure 107. The first direction and the second direction are parallel with a top surface of the substrate 100, and the first direction intersects the second direction. In the drawings, the first direction corresponds to an x-axis direction, and the second direction corresponds to a y-axis direction. The intaglio pattern 108 is opened toward the second region 20.

The pattern structure 107 is formed by forming an insulation layer on a top surface of the substrate 100 and patterning the insulation layer. Alternatively, the pattern structure 107 is formed by etching the substrate 100. In the event that the pattern structure 107 is formed by etching the substrate 100, the pattern structure 107 and the substrate 100 constitute a single unified body without any junction between the pattern structure 107 and the substrate 100.

The intaglio pattern 108 includes first sidewalls parallel with the first direction and second sidewalls parallel with the second direction. A height of the first sidewalls of the intaglio pattern 108 is substantially equal to a height of the second sidewalls of the intaglio pattern 108. The intaglio pattern 108 includes two first sidewalls which are opposite to each other. The two first sidewalls is referred to as a first sidewall-pair in the specification. Accordingly, the intaglio pattern 108 includes a plurality of first sidewall-pairs. A distance between the first sidewalls included in a first sidewall-pair located to be relatively closer to the second region 20 is greater than a distance between the first sidewalls included in a first sidewall-pair located to be relatively farther from the second region 20.

A buffer dielectric layer 109 is formed to cover the top surface of the substrate 100. The buffer dielectric layer 109 is formed by a thermal oxidation process. For example, the buffer dielectric layer 109 includes a thermal oxide layer. When the pattern structure 107 is formed of an insulation layer, the buffer dielectric layer 109 formed by the thermal oxidation process is formed on the top surface of the substrate 100.

Referring to FIG. 4B, first material layers and second material layers different from the first material layers are alternately and repeatedly stacked on an entire surface of the substrate including the buffer dielectric layer 109. The first material layers correspond to sacrificial layers 110L and 110, and the second material layers correspond to insulation layers 120. After the sacrificial layers 110L and 110 and the insulation layers 120 are stacked, the sacrificial layers 110L and 110 and the insulation layers 120 are planarized using the pattern structure 107 as an etch stopper.

According to an embodiment, the sacrificial layers 110L and 110 are formed of a material having an etch selectivity with respect to the insulation layers 120. For example, the insulation layers 120 is formed of an oxide material, and the sacrificial layers 110L and 110 are formed of a nitride material and/or an oxynitride material. According to an embodiment, the sacrificial layers 110L and 110 are formed of the same material. According to an embodiment, the insulation layers 120 are formed of the same material.

The sacrificial layers 110L and 110 are formed to have the same thickness. Alternatively, the lowermost sacrificial layer 110L is formed to be thicker than the sacrificial layers 110 disposed on the lowermost sacrificial layer 110L. According to an embodiment, the sacrificial layers 110 disposed on the lowermost sacrificial layer 110L are formed to have the same thickness. The insulation layers 120 are formed to have the same thickness.

Each of the sacrificial layers 110L and 110 includes a flat portion parallel with the substrate 100 and a sidewall portion upwardly extending from an end of the flat portion. The sidewall portion includes at least one first portion extending in the first direction and at least one second portion extending in the second direction. The number of the first and second portions of a sacrificial layer located at a relatively lower level is greater than the number of the first and second portions of a sacrificial layer located at a relatively higher level. When viewed from a plan view, each of top surfaces of the first portions of the sidewall portions of the sacrificial layers 110L and 110 has substantially a rectangular shape that includes two long sides which are parallel with the first direction. The long sides of the top surfaces of the first portions of the sidewall portions of the sacrificial layers 110L and 110 may be longer than distances between the top surfaces of the first portions of the sidewall portions of the sacrificial layers 110L and 110. The sidewall portions of the sacrificial layers 110L and 110 are formed on the substrate 100 in the first region 10.

Each of the insulation layers 120 includes a flat portion parallel with the substrate 100 and a sidewall portion upwardly extending from an end of the flat portion. The sidewall portion of each of the insulation layers 120 includes at least one first portion extending in the first direction and at least one second portion extending in the second direction. The number of the first and second portions of an insulation layer 120 located at a relatively lower level is greater than the number of the first and second portions of an insulation layer 120 located at a relatively higher level.

Referring to FIG. 4C, after planarization of the sacrificial layers 110L and 110 and the insulation layers 120, a first upper insulation layer 122, an uppermost sacrificial layer 110U and a second upper insulation layer 124 are sequentially formed on the substrate including the planarized sacrificial layers 110L and 110 and the planarized insulation layers 120. The uppermost sacrificial layer 110U is formed by forming a material layer on the first upper insulation layer 122 and by patterning the material layer using the first upper insulation layer 122 as an etch stop layer. The material layer for forming the uppermost sacrificial layer 110U includes the same material layer as the sacrificial layers 110L and 110, and the uppermost sacrificial layer 110U is formed to cover the first upper insulation layer 122 in the second region 20 and to expose the first upper insulation layer 122 in the first region 10. The uppermost sacrificial layer 110U is parallel with the top surface of the substrate 100. The uppermost sacrificial layer 110U is formed to be thicker than the sacrificial layers 110 between the lowermost sacrificial layer 110L and the uppermost sacrificial layer 110U. The first and second upper insulation layers 122 and 124 are formed of the same material as the insulation layers 120.

Referring to FIG. 4D, the upper insulation layers 122 and 124, the sacrificial layers 110, 110L and 110U, the insulation layers 120, and the buffer dielectric layer 109 are patterned to form channel openings 125 that expose the top surface of the substrate 100. The channel openings 125 penetrate the flat portions of the sacrificial layers 110, 110L and 110U. The channel openings 125 are formed by an anisotropic etching process. Each of the channel openings 125 is formed to have a hole shape in a plan view. The channel openings 125 are spaced apart from each other. The channel openings 125 are two-dimensionally arrayed along the first and second directions. According to an embodiment, each of the channel openings 125 is formed to have a circular shape, an oval shape or a polygonal shape in a plan view.

Referring to FIG. 4E, semiconductor pillars 130 are formed to fill the respective ones of the channel openings 125. Each of the semiconductor pillars 130 includes a semiconductor portion 131 covering a sidewall of the channel opening 125, a filling insulation material 132 filling an empty region surrounded by the semiconductor portion 131, and a drain region 133 formed on an upper portion of the semiconductor portion 131. The semiconductor portion 131 and the drain region 133 are formed of a single crystalline semiconductor or a poly crystalline semiconductor. The drain region 133 is doped with dopants of a second conductivity type different from the first conductivity type.

Referring to FIG. 4F, a capping insulation layer is formed on the substrate including the semiconductor pillars 130. The capping insulation layer is formed of the same material as the insulation layers 120. The capping insulation layer, the pattern structure 107, the upper insulation layers 122 and 124, the insulation layers 120 and the sacrificial layers 110L, 110 and 110U are patterned to form at least one main trench 140 and a plurality of sub-trenches 142. The main trench 140 is disposed on the substrate 100 across the first and second regions 10 and 20, and the sub-trenches 142 are disposed on the substrate 100 in the second region 20. A length of the main trench 140 in the first direction is greater than a length of each of the sub-trenches 142 in the first direction. The main trench 140 and the sub-trenches 142 are formed by an anisotropic etching process, for example, an anisotropic dry etching process.

At least two separate preliminary stack structures are defined by the main trench 140. Each of the preliminary stack structures includes sacrificial patterns 110La, 110a and 110Ua, and insulation patterns 120a, 122a, 124a and 134a which are alternately and repeatedly stacked. The main trench 140 extends in the first direction, and the preliminary stack structures are symmetrical to each other with respect to the main trench 140.

The sub-trenches 142 extend in the first direction and split a portion of each of the preliminary stack structures into a plurality of line-shaped sections extending in the first direction. The semiconductor pillars 130 pass through the preliminary stack structures.

Each of the sacrificial patterns 110La and 110a under the uppermost sacrificial patterns 110Ua includes a flat portion AA parallel with the substrate 100 and a sidewall portion BB upwardly extending from an end of the flat portion AA. The sidewall portion BB of each of the sacrificial patterns 110La and 110a includes at least one first portion BB1 extending in the first direction and at least one second portion BB2 extending in the second direction. When viewed from a plan view, each of top surfaces of the first portions BB1 of the sidewall portions BB of the sacrificial patterns 110La and 110a has substantially a rectangular shape that includes two long sides which are parallel with the first direction. The long sides of the top surfaces of the first portions BB1 are longer than distances between the top surfaces of the first portions BB1. Each of the uppermost sacrificial patterns 110Ua has a line shape that is parallel with the first direction.

The semiconductor pillars 130 arrayed in a straight line parallel with the first direction constitute a row, and the semiconductor pillars 130 arrayed in a straight line parallel with the second direction constitute a column. The semiconductor pillars 130 are two-dimensionally arrayed along the rows and the columns. Each of the sub-trenches 142 is disposed between two adjacent rows.

Sidewalls of the sacrificial patterns 110La, 110a 110Ua and the insulation patterns 120a, 122a, 124a and 134a are exposed through the main trench 140 and the sub-trenches 142.

Referring to FIG. 4G, the uppermost sacrificial patterns 110Ua are completely removed by a selective etching process to form uppermost recessed regions 145U. During removal of the uppermost sacrificial patterns 110Ua, the sacrificial patterns 110La and 110a under the uppermost sacrificial patterns 110Ua are partially removed to form recessed regions 145, and the flat portions AA of the sacrificial patterns 110La and 110a are removed to form the recessed regions 145.

During removal of the uppermost sacrificial patterns 110Ua, at least the outermost first and second portions BB1 and BB2 of the sidewall portions BB of the sacrificial patterns 110La and 110a are removed. After the selective etching process for removal of the uppermost sacrificial patterns 110Ua, sacrificial patterns 110Lb and 110b remain in the first region 10.

According to an embodiment, the selective etching process uses an isotropic etching technique including, e.g., a wet etching technique and/or an isotropic dry etching technique. When the sacrificial patterns 110La, 110a and 110Ua, the insulation patterns 120a, 122a, 124a and 134a, and the semiconductor pillars 130 are exposed by the selective etching process, an etch rate of the sacrificial patterns 110La, 110a and 110Ua is greater than etch rates of the insulation patterns 120a, 122a, 124a and 134a and the semiconductor pillars 130. Thus, even after the selective etching process is performed, the insulation patterns 120a, 122a, 124a and 134a and the semiconductor pillars 130 may remain. In an embodiment, the buffer dielectric layer 109 is thinner than the insulation patterns 120a, 122a, 124a and 134a. Thus, the buffer dielectric layer 109 is removed during the selective etching process. Alternatively, the buffer dielectric layer 109 remains even after the selective etching process. Hereinafter, for the purpose of illustration, the buffer dielectric layer 109 is removed during the selective etching process.

According to an embodiment, the recessed regions 145 and 145U expose portions of a sidewall of each of the semiconductor pillars 130.

Referring to FIG. 4H, a data storage layer 150 is formed on the substrate including the recessed regions 145 and 145U. The data storage layer 150 is formed by a deposition technique (e.g., a chemical vapor deposition (CVD) technique or an atomic layer deposition (ALD) technique) exhibiting an excellent step coverage. Accordingly, the data storage layer 150 is conformally formed in the recessed regions 145 and 145U. The data storage layer 150 is formed to substantially a uniform thickness along inner surfaces of the recessed regions 145 and 145U. The data storage layer 150 is formed by sequentially stacking a tunnel insulation layer 150a, a charge storage layer 150b and a blocking layer 150c, as described with reference to FIG. 3.

After formation of the data storage layer 150, a gate conductive layer 155 is formed on the data storage layer 150. The gate conductive layer 155 is formed to fill the recessed regions 145 and 145U. The gate conductive layer 155 is formed to partially or fully fill the main trench 140 and the sub-trenches 142. The gate conductive layer 155 is electrically insulated from the semiconductor pillars 130 and the substrate 100 by the data storage layer 150. The gate conductive layer 155 is formed by a chemical vapor deposition (CVD) process, a physical vapor deposition (PVD) process or an atomic layer deposition (ALD) process. The gate conductive layer 155 is formed to include at least one of metal, metal silicide, conductive metal nitride and doped semiconductor material.

Referring to FIG. 41, after formation of the gate conductive layer 155, the gate conductive layer 155 located outside the recessed regions 145 and 145U is selectively removed to form conductive patterns CP, pad patterns PP, auxiliary pad patterns APP and string selection lines 157, which are described with reference to FIGS. 1, 2A and 2B, in the recessed regions 145 and 145U. As illustrated in FIGS. 1, 2A and 2B, each of the pad patterns PP includes a flat portion FP and a landing sidewall portion LSP, and the landing sidewall portion LSP includes a first portion SP1 and a second portion SP2. The first portions SP1 fills respective ones of the recessed regions 145 which are generated by removal of the first portions BB1 of the sidewall portions BB of the sacrificial patterns 110La and 110a. The gate conductive layer 155 located outside the recessed regions 145 and 145U is selectively removed by a wet etching process and/or a dry etching process.

The stacked conductive patterns CP, the string selection lines 157 on the stacked conductive patterns CP, and the insulation patterns 120a, 122a and 124a, which are located at a side of the main trench 140, constitute a stack structure. The two stack structures respectively disposed at two sides of the main trench 140 are symmetrical to each other with respect to the main trench 140. The number of the stack structures is two or more. The plurality of stack structures are provided on the substrate 100.

The conductive patterns CP and the string selection lines 157 correspond to portions of the gate conductive layer 155, which are left in the recessed regions 145 and 145U. In each of the stack structures, the lowermost conductive pattern CP corresponds to a common gate of lower selection transistors, and the string selection lines 157 corresponds to gates of upper selection transistors. The conductive patterns CP between the lowermost conductive pattern CP and the string selection lines 157 correspond to control gates of memory cells.

Common source regions (not shown) are formed in the substrate 100 under the main trench 140 and the sub-trenches 142. Each of the common source regions has a line shape extending in the first direction. The common source regions are doped with dopants of the second conductivity type. The common source regions are formed by implanting impurities of the second conductivity type into the substrate 100 under the main trench 140 and the sub-trenches 142. While the impurities of the second conductivity type are implanted into the substrate 100, the data storage layer 150 on the substrate 100 and under the trenches 140 and 142 are used as an ion implantation buffer layer.

A main isolation pattern 160 and sub-isolation patterns 162 are formed to fill the main trench 140 and the sub-trenches 142, respectively. Forming the main isolation pattern 160 and the sub-isolation patterns 162 includes forming an isolation layer on the substrate having the common source regions and planarizing the isolation layer using the capping insulation patterns 134a as etch stoppers. The isolation layer includes an insulation layer, such as a high density plasma (HDP) oxide layer, a spin on glass (SOG) layer and/or a chemical vapor deposition (CVD) oxide layer.

Referring again to FIGS. 1, 2A and 2B, bit line contact plugs 172 are formed to penetrate the capping insulation pattern 134a in the second region 20, and cell contact plugs 174 are formed to penetrate the capping insulation pattern 134a, the second upper insulation pattern 124a and the first upper insulation pattern 122a in the first region 10. The bit line contact plugs 172 are electrically connected to respective ones of the drain regions 133. The cell contact plugs 174 are electrically connected to respective ones of the first portions SP1 of the landing sidewall portions LSP. The bit line contact plugs 172 and the cell contact plugs 174 are formed by etching the capping insulation pattern 134a, the second upper insulation pattern 124a and the first upper insulation pattern 122a to form contact holes exposing the drain regions 133 and the first portions SP1 and by filling the contact holes with a conductive layer. Bit lines 182 and conductive interconnection lines 184 are formed on the capping insulation pattern 134a. The bit lines 182 are formed to extend in the second direction and are electrically connected to the bit line contact plugs 172. The conductive interconnection lines 184 are formed to extend in the second direction and are electrically connected to the cell contact plugs 174.

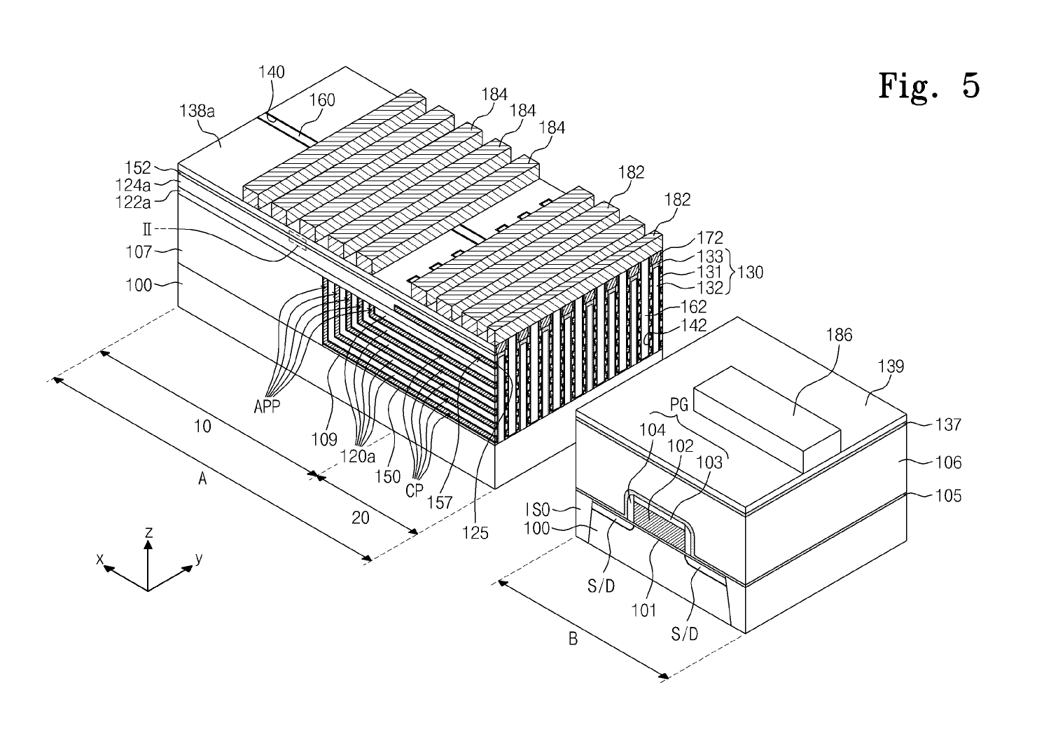

A semiconductor device according to an exemplary embodiment is now described. FIG. 5 is a perspective view illustrating a semiconductor device according to an exemplary embodiment.

Referring to FIG. 5, a substrate 100 includes a cell region A and a peripheral region B. The substrate 100 is doped with dopants of a first conductivity type. The cell region A includes a memory cell array, and the peripheral region B includes a peripheral circuit. The cell region A includes a first region 10 and a second region 20. The first region 10 and the second region 20 respectively correspond to the first and second regions 10 and 20 described with reference to FIGS. 1, 2A and 2B. The pattern structure 107 described with reference to FIGS. 1, 2A and 2B is disposed on the substrate 100 in the first region 10.

Two stack structures are disposed on the substrate 100 in the cell region A. Each of the stack structures includes conductive patterns CP stacked on the substrate 100 in the cell region A, string selection lines 157 on the stacked conductive patterns CP, and insulation patterns 120a, 122a and 124a. According to an embodiment, the stack structure has the same configuration as the stack structure described with reference to FIGS. 1, 2A and 2B.

The pad patterns PP described with reference to FIGS. 1, 2A and 2B extend from respective ones of ends of the conductive patterns CP in a first direction parallel with an x-axis direction. The auxiliary pad patterns APP described with reference to FIGS. 1, 2A and 2B also extend from respective ones of ends of the conductive patterns CP in the first direction. The pad patterns PP are spaced apart from the auxiliary pad patterns APP. The sacrificial patterns 110Lb and 110b described with reference to FIGS. 1, 2A and 2B are disposed between the pad patterns PP and the auxiliary pad patterns APP.

Semiconductor pillars 130 penetrate the gate electrodes GE of the conductive patterns CP and the insulation patterns 120a, 122a and 124a. The semiconductor pillars 130 correspond to the semiconductor pillars 130 described with reference to FIGS. 1, 2A and 2B.

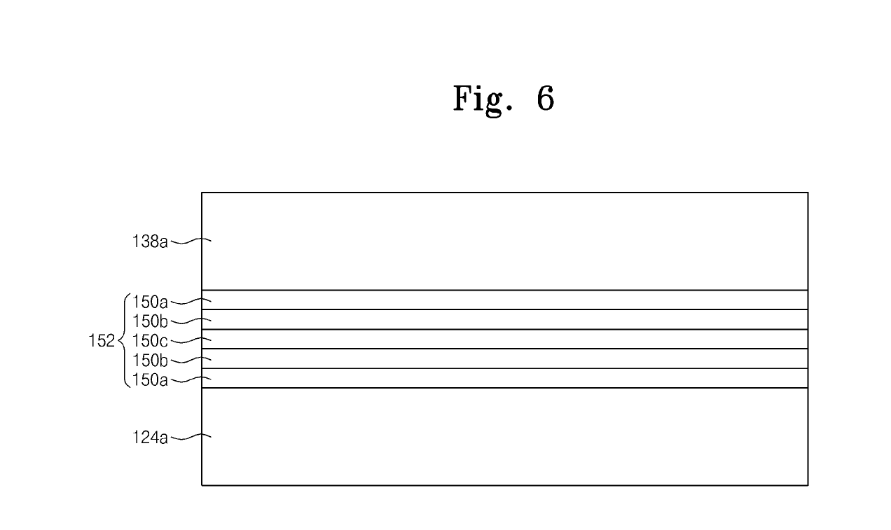

A barrier layer 152 and a capping insulation pattern 138a are sequentially stacked on the stack structure. The barrier layer 152 includes the same materials as the data storage layer 150 described with reference to FIG. 3. The barrier layer 152 is described in detail with reference to FIG. 6.

FIG. 6 is an enlarged view illustrating a portion ‘IF of FIG. 5 to describe the barrier layer of a semiconductor device according to an exemplary embodiment. Referring to FIG. 6, the barrier layer 152 includes a tunnel insulation layer 150a, a charge storage layer 150b, a blocking layer 150c, a charge storage layer 150b and a tunnel insulation layer 150a which are sequentially stacked on the second upper insulation pattern 124a. The tunnel insulation layer 150a, the charge storage layer 150b and the blocking layer 150c include the same material as the tunnel insulation layer 150a, the charge storage layer 150b and the blocking layer 150c illustrated in FIG. 3, respectively.

Referring again to FIG. 5, bit line contact plugs 172 are disposed to penetrate the capping insulation pattern 138a and the barrier layer 152. Cell contact plugs 174 are disposed to penetrate the capping insulation pattern 138a, the barrier layer 152, the second upper insulation pattern 124a and the first upper insulation pattern 122a. The cell contact plugs 174 are electrically connected to respective ones of the landing sidewall portions LSP, and the bit line contact plugs 172 are electrically connected to respective ones of the drain regions 133 of the semiconductor pillars 130. Conductive interconnection lines 184 and bit lines 182 are disposed on the capping insulation pattern 138a. The conductive interconnection lines 184 are electrically connected to the cell contact plugs 174, and the bit lines 182 are electrically connected to the bit line contact plugs 172.

A peripheral isolation pattern ISO is disposed in the substrate 100 of the peripheral region B. The peripheral isolation pattern ISO defines a peripheral active region in the substrate 100 of the peripheral region B. The peripheral active region is a portion of the substrate 100, which is surrounded by the peripheral isolation pattern ISO. The peripheral active region includes a channel region, and a channel is formed in the channel region when a transistor formed at the peripheral active region operates.

A peripheral gate insulation layer 101 is disposed on the peripheral active region. The peripheral gate insulation layer 101 includes a silicon oxide layer. A peripheral gate pattern PG is disposed on the peripheral gate insulation layer 101. The peripheral gate pattern PG includes a peripheral gate electrode 102 on the peripheral gate insulation layer 101, a peripheral gate capping pattern 103 on the peripheral gate electrode 102, and a peripheral spacer 104 on a sidewall of the peripheral gate electrode 102. A peripheral source S/D and a peripheral drain S/D are disposed in the peripheral active region at two sides of the peripheral gate pattern PG, respectively. The peripheral source S/D and the peripheral drain S/D are doped with dopants of a second conductivity type different from the first conductivity type.

A peripheral etch stop layer 105, a peripheral interlayer insulation layer 106, a peripheral upper insulation layer 137 and a peripheral capping insulation layer 139 are sequentially stacked on the peripheral gate pattern PG, the peripheral source, the peripheral drain S/D and the peripheral isolation pattern ISO. The peripheral etch stop layer 105 and the peripheral upper insulation layer 137 are formed of the same material, and the peripheral interlayer insulation layer 106 and the peripheral capping insulation layer 139 are formed of the same material. For example, the peripheral etch stop layer 105 and the peripheral upper insulation layer 137 are formed to include a silicon nitride layer or a silicon oxynitride layer, and the peripheral interlayer insulation layer 106 and the peripheral capping insulation layer 139 are formed to include a silicon oxide layer.

At least one peripheral contact plug is disposed to penetrate the peripheral material layers 103, 105, 106, 137 and 139 on the peripheral gate electrode 102. The peripheral contact plug is electrically connected to the peripheral gate electrode 102. A peripheral conductive interconnection line 186 is disposed on the peripheral capping insulation layer 139. The peripheral conductive interconnection line 186 is electrically connected to the peripheral contact plug.

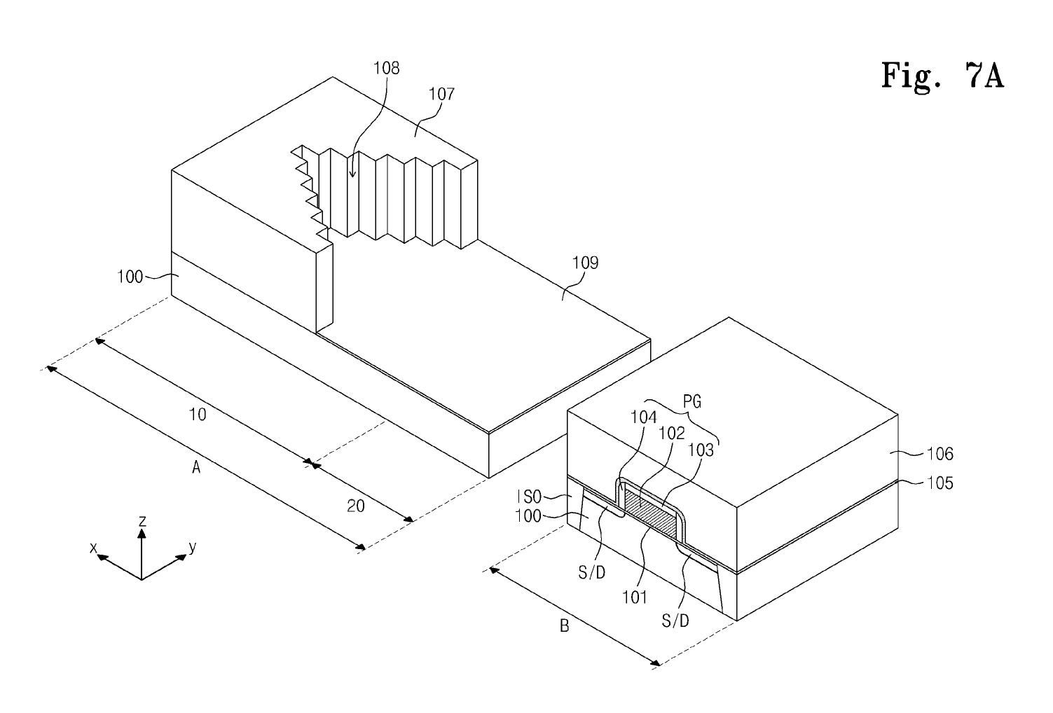

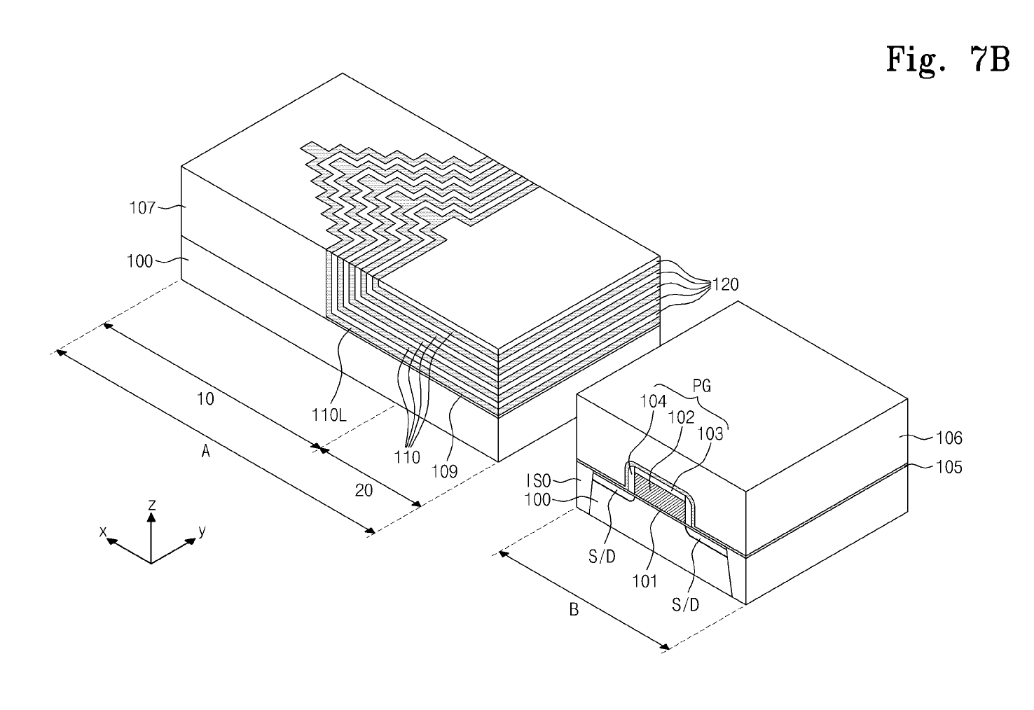

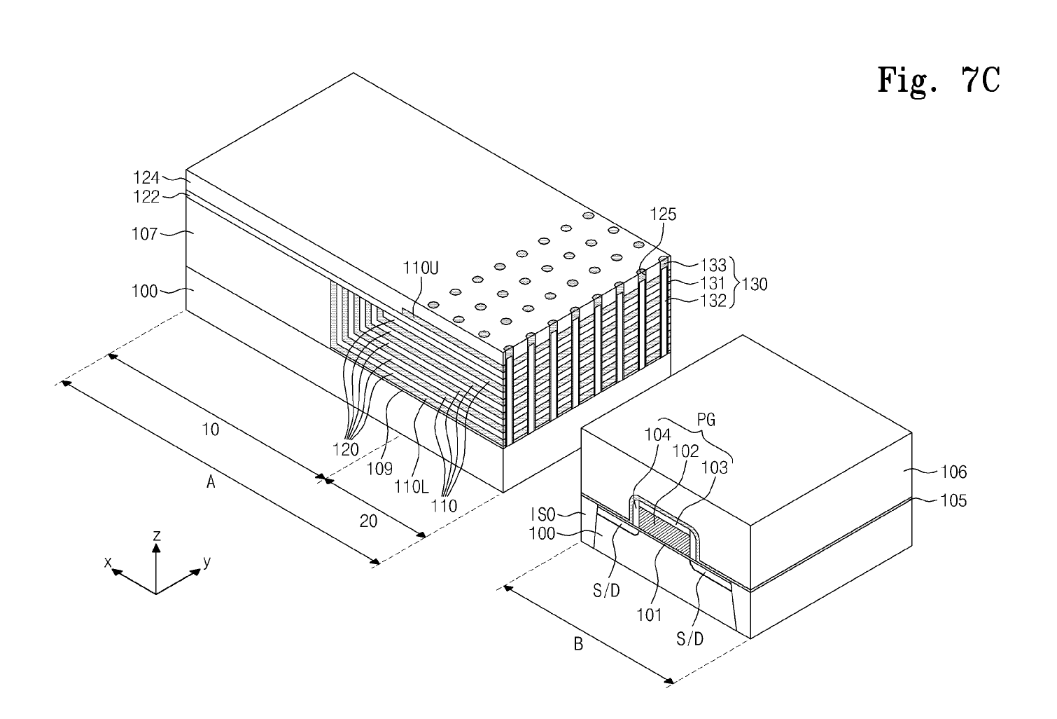

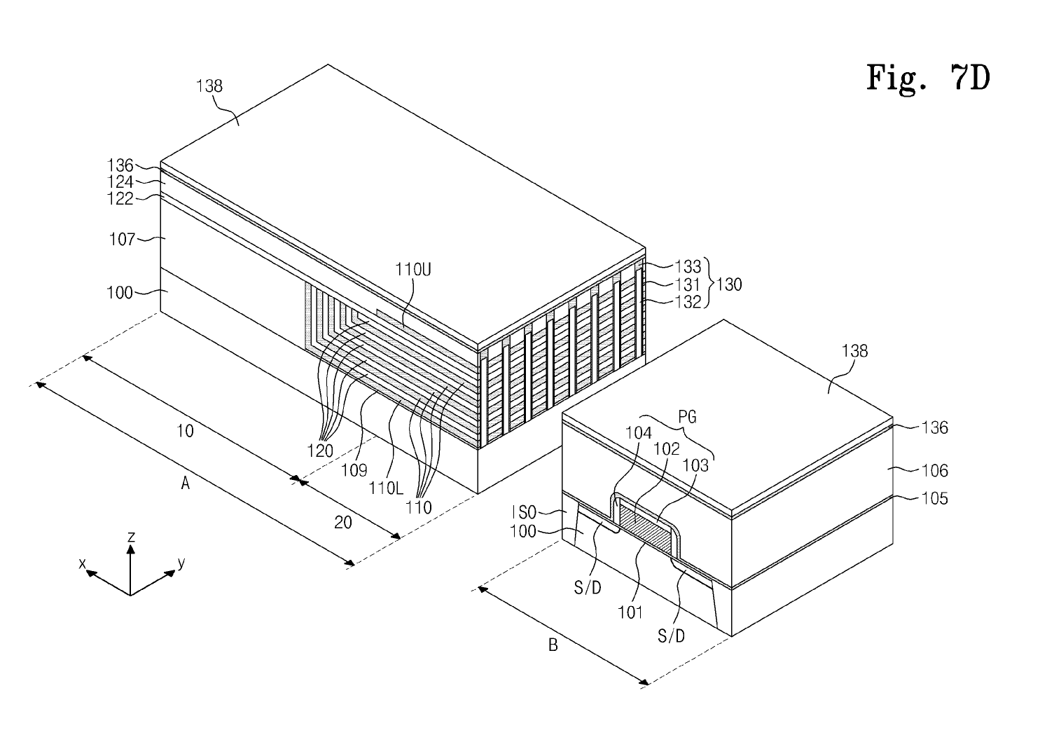

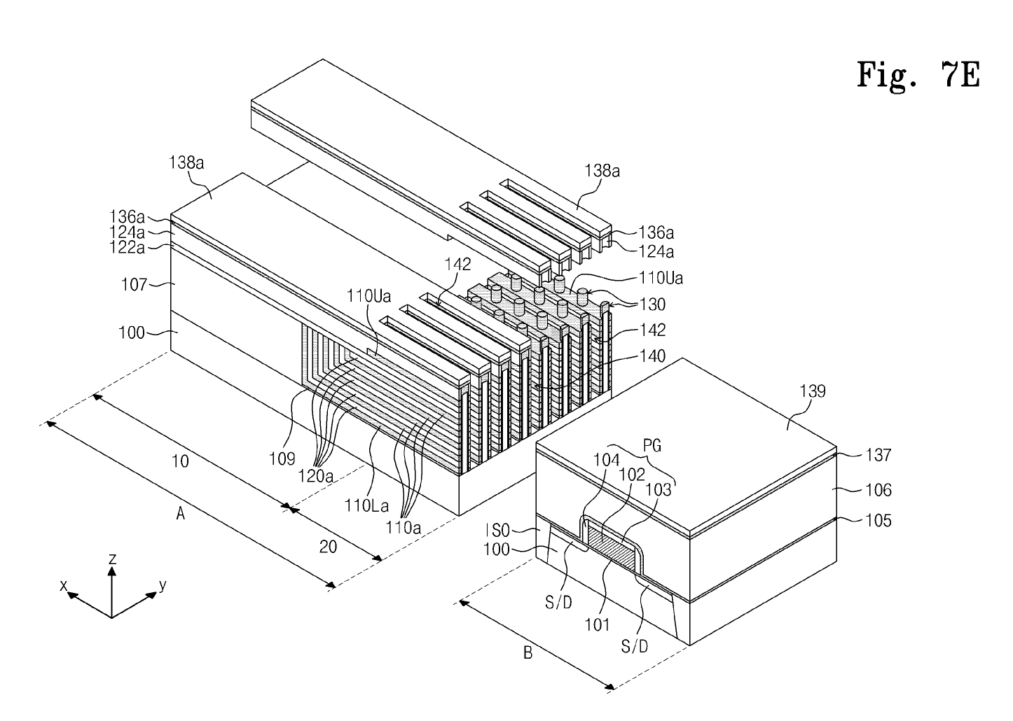

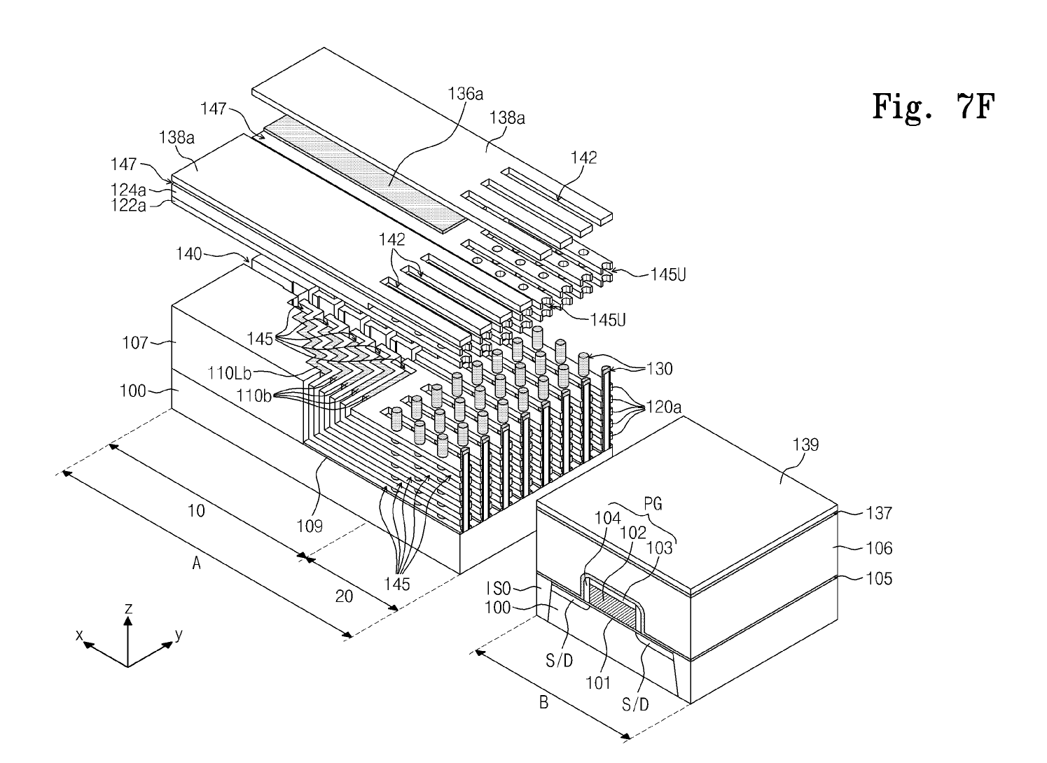

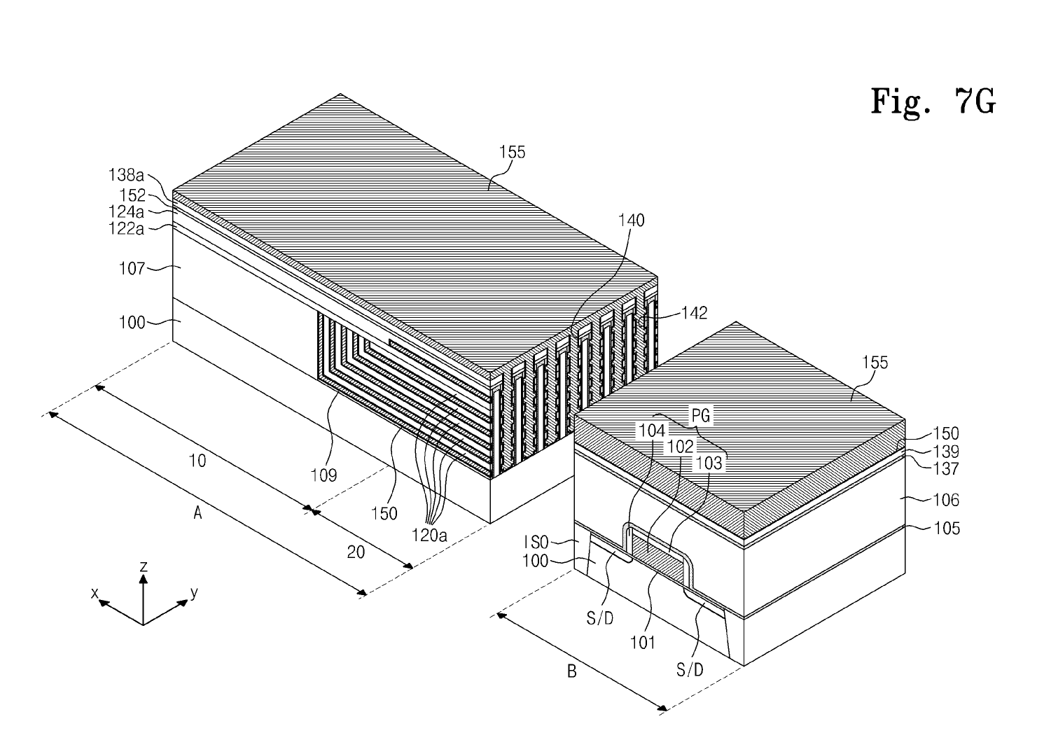

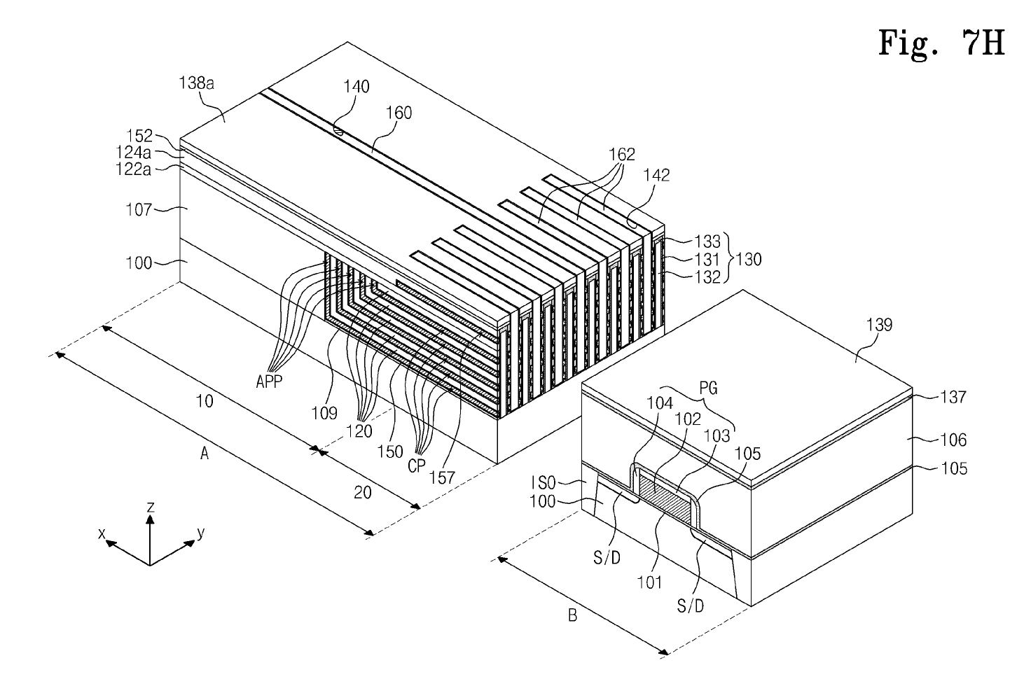

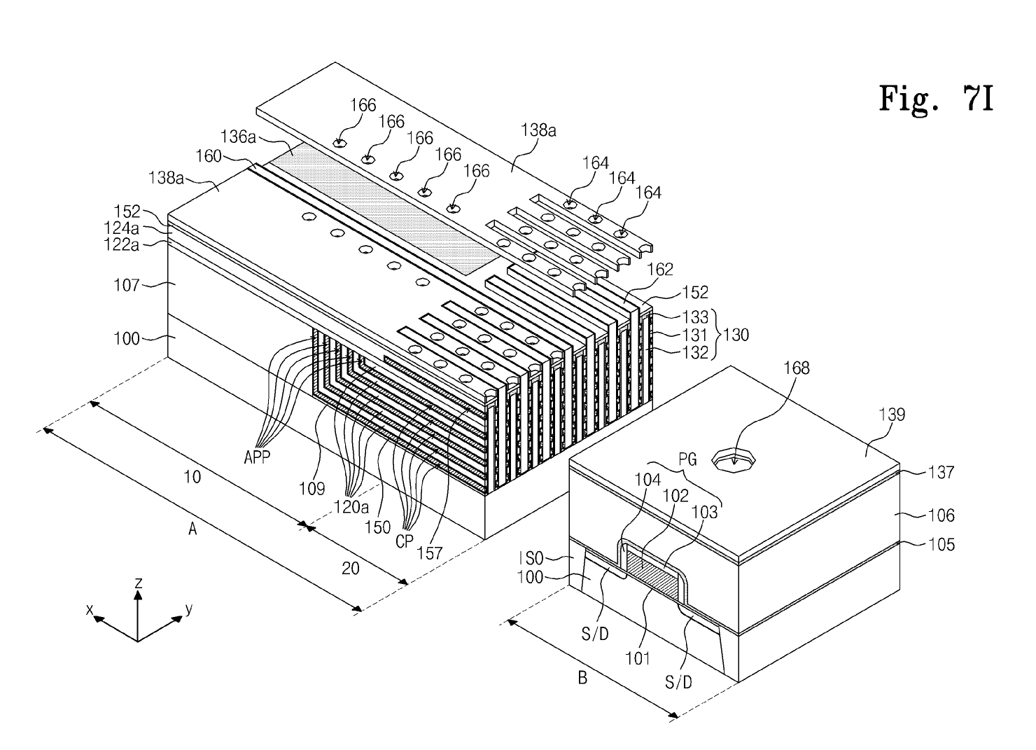

A method of fabricating a semiconductor device according to a second exemplary embodiment is now described. FIGS. 7A to 7I are perspective views illustrating a method of fabricating a semiconductor device according to an exemplary embodiment.

Referring to FIG. 7A, a substrate 100 having a cell region A and a peripheral region B is provided. The cell region A includes a first region 10 and a second region 20. A peripheral isolation pattern ISO is formed in the substrate 100 of the peripheral region B and defines a peripheral active region in the substrate 100 of the peripheral region B. The peripheral isolation pattern ISO is formed by etching the substrate 100 to form a trench and filling the trench with an insulation material. A peripheral gate insulation layer 101 is formed on the peripheral active region. For example, the peripheral gate insulation layer 101 is formed of a thermal silicon oxide layer by a thermal oxidation process. A peripheral gate pattern PG is formed on the peripheral gate insulation layer 101. The peripheral gate pattern PG is formed to include a peripheral gate electrode 102 on the peripheral gate insulation layer 101, a peripheral gate capping pattern 103 on the peripheral gate electrode 102, and a peripheral spacer 104 on a sidewall of the peripheral gate electrode 102. A peripheral source S/D and a peripheral drain S/D are formed in the peripheral active region at two sides of the peripheral gate pattern PG, respectively. An etch stop layer 105 is formed to cover the peripheral gate pattern PG.

An insulation layer is formed on the substrate 100 in the cell region A and on the peripheral etch stop layer 105 in the peripheral region B. The insulation layer in the cell region A is patterned to form the pattern structure 107 described with reference to FIG. 4A on the substrate 100 in the first region 10 and to form a peripheral interlayer insulation layer 106 remaining on the peripheral etch stop layer 105 of the peripheral region B. A top surface of the pattern structure 107 is coplanar with a top surface of the peripheral interlayer insulation layer 106. Alternatively, the pattern structure 107 is formed by etching the substrate 100 in the cell region A. In the event that the pattern structure 107 is formed by etching the substrate 100, the pattern structure 107 and the substrate 100 constitute a single unified body without any junction between the pattern structure 107 and the substrate 100, as described with reference to FIG. 4A.

After formation of the pattern structure 107, a buffer dielectric layer 109 is formed on the substrate 100 in the call region A.

Referring to FIG. 7B, first material layers and second material layers different from the first material layers are alternately and repeatedly stacked on a top surface of the substrate including the pattern structure 107. The first material layers correspond to sacrificial layers 110L and 110, and the second material layers correspond to insulation layers 120. The sacrificial layers 110L and 110 and the insulation layers 120 are planarized until a top surface of the pattern structure 107 and/or a top surface of the peripheral interlayer insulation layer 106 is exposed. The sacrificial layers 110L and 110 and the insulation layers 120 correspond to the sacrificial layers 110L and 110 and the insulation layers 120 described with reference to FIG. 4B.

Referring to FIG. 7C, after planarization of the sacrificial layers 110L and 110 and the insulation layers 120, a first upper insulation layer 122, an uppermost sacrificial layer 110U and a second upper insulation layer 124 are sequentially formed on the substrate in the cell region A. As described with reference to FIG. 4C, the uppermost sacrificial layer 110U is formed by depositing a material layer on the first upper insulation layer 122 and patterning the material layer so that a remaining portion of the material layer is located over the flat portions of the sacrificial layers 110L and 110. The peripheral interlayer insulation layer 106 further includes the first upper insulation layer 122 and the second upper insulation layer 124 which are formed in the peripheral region B.

After formation of the second upper insulation layer 124, channel openings 125 penetrating the insulation layers 120, 122 and 124, the sacrificial layers 110L, 110 and 110U, and the buffer dielectric layer 109 are formed by the same method as described with reference to FIG. 4D. Further, semiconductor pillars 130 filling the channel openings 125 are formed by the same method as described with reference to FIG. 4E.

Referring to FIG. 7D, an additional sacrificial layer 136 and a capping insulation layer 138 are sequentially formed on a top surface of the substrate including the semiconductor pillars 130. The additional sacrificial layer 136 is formed of a different material from the capping insulation layer 138. For example, the additional sacrificial layer 136 is formed of the same material as the sacrificial layers 110L, 110 and 110U, and the capping insulation layer 138 is formed of the same material as the insulation layers 120, 122 and 124.

Referring to FIG. 7E, the capping insulation layer 138, the additional sacrificial layer 136, the insulation layers 124, 122 and 120, the pattern structure 107, and the sacrificial layers 110U, 110 and 110L are patterned to form the main trench 140 and the sub-trenches 142 described with reference to FIG. 4F. The main trench 140 and the sub-trenches 142 are formed by an anisotropic etching process, for example, an anisotropic dry etching process.

At least two separate preliminary stack structures are defined by the main trench 140. Each of the preliminary stack structures includes sacrificial patterns 110La, 110a and 110Ua, and insulation patterns 120a, 122a and 124a which are alternately and repeatedly stacked. The preliminary stack structure has the same configuration as the preliminary stack structure described with reference to FIG. 4F.

As described with reference to FIG. 4F, each of the sacrificial patterns 110La and 110a disposed under the uppermost sacrificial pattern 110Ua includes a flat portion AA and a sidewall portion BB upwardly extending from an end of the flat portion AA. Each of the uppermost sacrificial patterns 110Ua has a line shape extending in a first direction parallel with an x-axis direction.

The main trench 140 splits the additional sacrificial layer 136 into two additional sacrificial patterns 136a which are respectively disposed on the two preliminary sack structures in the cell region A. Similarly, the main trench 140 also splits the capping insulation layer 138 into two capping insulation patterns 138a which are respectively disposed on the additional sacrificial patterns 136a in the cell region A. According to an embodiment, the additional sacrificial layer 136 and the capping insulation layer 138 in the peripheral region B are not patterned but left as a peripheral upper insulation layer 137 and a peripheral capping insulation layer 139, respectively.

Sidewalls of the sacrificial patterns 110La, 110a and 110Ub, the insulation patterns 120a, 122a and 124a, the additional sacrificial patterns 136a, and the capping insulation patterns 138a are exposed by the main trench 140 and the sub-trenches 142.

Referring to FIG. 7F, using a selective etching process, the uppermost sacrificial patterns 110Ua exposed by the main trench 140 and the sub-trenches 142 are completely removed to form uppermost recessed regions 145U. During removal of the uppermost sacrificial patterns 110Ua, the sacrificial patterns 110La and 110a under the uppermost sacrificial patterns 110Ua are partially removed to form recessed regions 145.

During removal of the uppermost sacrificial patterns 110Ua, at least the outermost first and second portions BB1 and BB2 of the sidewall portions BB of the sacrificial patterns 110La and 110a are removed. After the selective etching process for removal of the uppermost sacrificial patterns 110Ua, sacrificial patterns 110Lb and 110b remain in the first region 10.

During the selective etching process, the additional sacrificial patterns 136a between the second upper insulation patterns 124a and the capping insulation patterns 138a are partially removed to form additional recessed regions 147. According to an embodiment, the additional recessed regions 147 are formed on portions of the recessed regions 145 formed by removal of the outermost first portions BB1 of the sidewall portions BB of the sacrificial patterns 110La and 110a. After the selective etching process, the additional sacrificial patterns 136a remain between the second upper insulation patterns 124a and the capping insulation patterns 138a.

The selective etching process is the same process as the selective etching process described with reference to FIG. 4G. According to an embodiment, the recessed regions 145, 145U expose portions of a sidewall of each of the semiconductor pillars 130 which contact the sacrificial patterns 110La, 110a and 110Ua.

Referring to FIG. 7G, a data storage layer 150 is formed on the substrate including the recessed regions 145, 145U and 147. The data storage layer 150 is formed in the additional recessed regions 147 to form a barrier layer 152. The barrier layer 152 includes the same material as the data storage layer 150, as described with reference to FIG. 6. The data storage layer 150 is formed in the same manner as described with reference to FIG. 4G.

After formation of the data storage layer 150, a gate conductive layer 155 is formed on the data storage layer 150, as described with reference to FIG. 4G. The gate conductive layer 155 is formed to fill the recessed regions 145 and 145U. The gate conductive layer 155 is formed to partially or fully fill the main trench 140 and the sub-trenches 142.

The data storage layer 150 and the gate conductive layer 155 are also formed on the peripheral capping insulation layer 139 in the peripheral region B.

Referring to FIG. 7H, after the gate conductive layer 155 is formed, the gate conductive layer 155 positioned outside the recessed regions 145 and 145U is removed to form the conductive patterns CP, the pad patterns PP, the auxiliary pad patterns APP, and the string selection lines 157, which are described with reference to FIGS. 1, 2A and 2B, in the recessed regions 145 and 145U. The gate conductive layer 155 positioned outside the recessed regions 145 and 145U is removed in the same manner as described with reference to FIG. 4I.

The stacked conductive patterns CP, the string selection lines 157 on the stacked conductive patterns CP, and the insulation patterns 120a, 122a and 124a, which are located at a side of the main trench 140 constitute a stack structure. The stack structure has the same configuration as the stack structure described with reference to FIG. 41. Common source regions are formed in the substrate 100 under the main trench 140 and the sub-trenches 142 by the same processes as described with reference to FIG. 41. As described with reference to FIG. 41, a main isolation pattern 160 and sub-isolation patterns 162 are formed to fill the main trench 140 and the sub-trenches 142, respectively.

Referring to FIG. 7I, a peripheral contact hole 168 is formed to penetrate the peripheral material layers 103, 105, 106, 137 and 139 on the peripheral gate pattern PG, and preliminary bit line contact holes 164 and preliminary cell contact holes 166 are formed to penetrate the capping insulation patterns 138a. The peripheral contact hole 168 is formed to expose the peripheral gate electrode 102. The preliminary cell contact holes 166 are formed over the landing sidewall portions (LSP of FIG. 2A), and the preliminary bit line contact holes 164 are formed over drain regions 133 of the semiconductor pillars 130. The preliminary contact holes 164 and 166 are formed by etching the capping insulation patterns 138a using the barrier layer 152 as an etch stop layer. The preliminary contact holes 164 and 166 expose portions of the barrier layer 152. In the event that an additional insulation layer is formed on the capping insulation patterns 138a, the preliminary contact holes 164 and 166 are formed by patterning the additional insulation layer and the capping insulation patterns 138a using the barrier layer 152 as an etch stop layer.

When contact holes exposing the landing sidewall portions (LSP of FIG. 2A) and the drain regions 133 and the peripheral contact hole 168 exposing the peripheral gate electrode 102 are formed without formation of the barrier layer 152, the landing sidewall portions LSP and the drain regions 133 are over-etched due to a depth difference between the contact holes and the peripheral contact hole 168, thus degrading the reliability of a semiconductor device.

However, according to an embodiment, the barrier layer 152 is formed of a material different from the peripheral material layers 103, 105, 106, 137 and 139. Thus, the barrier layer 152 prevents the landing sidewall portions LSP and the drain regions 133 from being over-etched while the preliminary contact holes 164 and 166 and the peripheral contact hole 168 are formed. As a result, a high reliable semiconductor device can be realized.

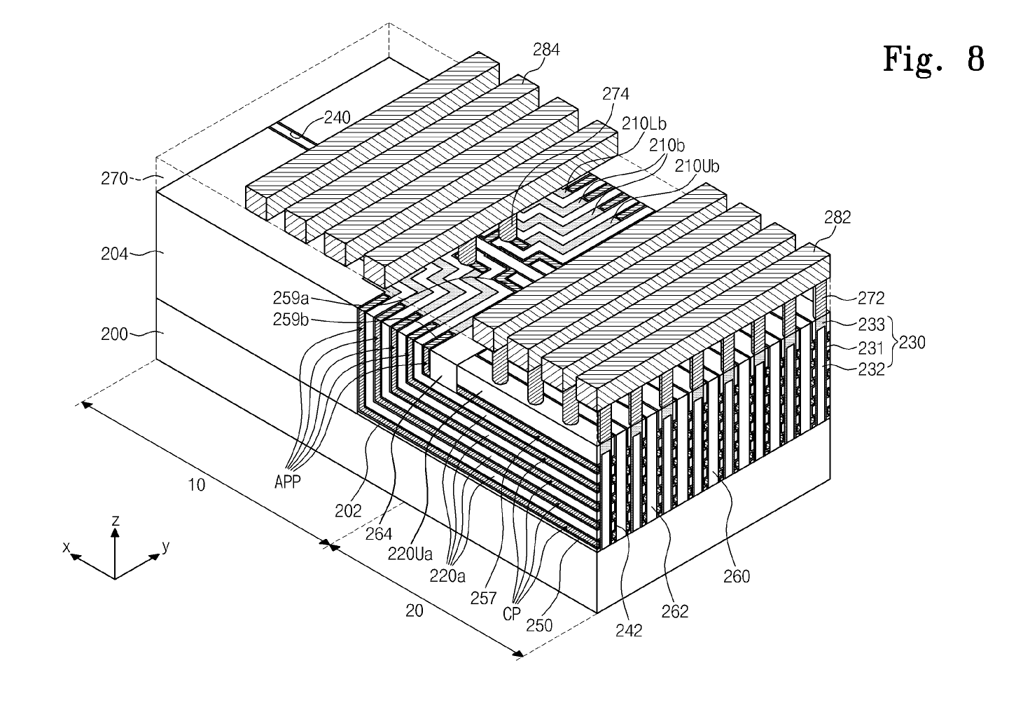

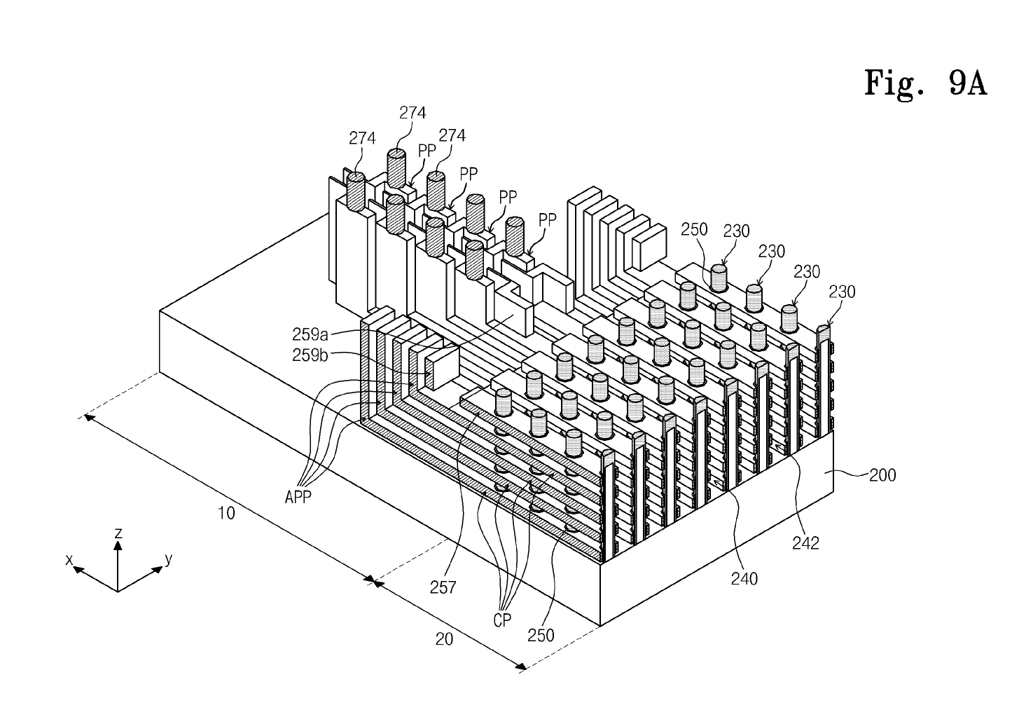

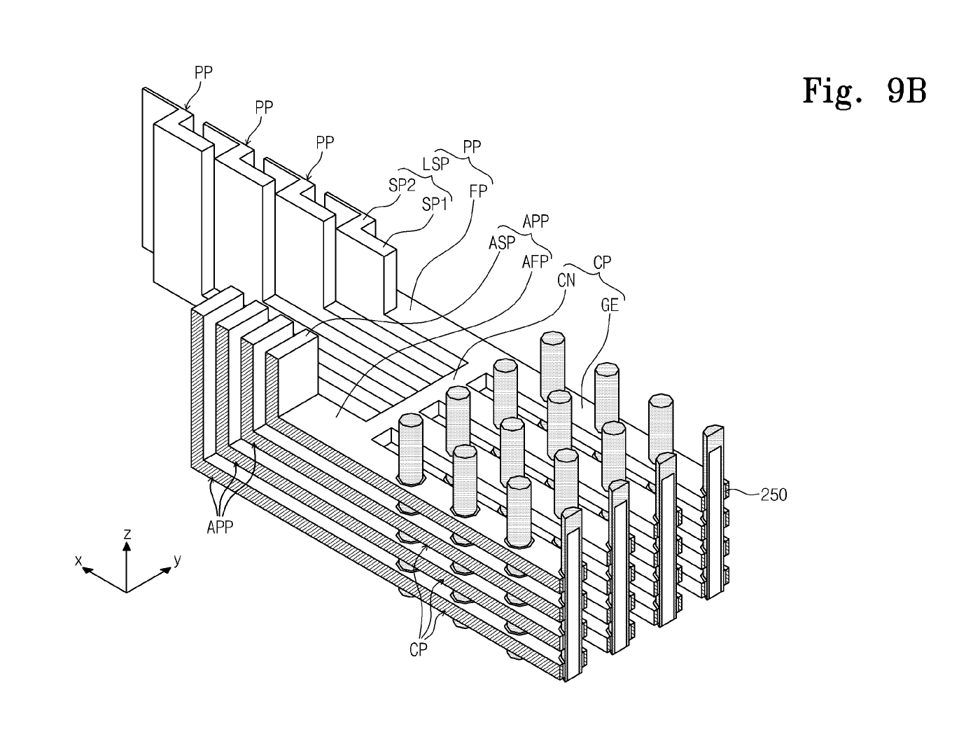

A semiconductor device according to an exemplary embodiment is now described. FIGS. 8, 9A and 9B are perspective views illustrating a semiconductor device according to an exemplary embodiment.

For convenience of description, FIG. 9A illustrates a substrate 200, semiconductor pillars 230, conductive patterns CP, pad patterns PP, auxiliary pad patterns APP, string selection lines 257, first and second floating conductive patterns 259a and 259b, cell contact plugs 274, conductive interconnection lines 284, and bit lines 282, and FIG. 9B illustrates the semiconductor pillars 230, the conductive patterns CP included in one stack structure, the pad patterns PP connected to the conductive patterns CP, and the auxiliary pad patterns APP connected to the conductive patterns CP. For convenience of recognition, portions of the conductive patterns CP, the pad patterns PP, the auxiliary pad patterns APP and the floating conductive patterns 259a and 259b are hatched as shown in FIGS. 9A and 9B.

Referring to FIG. 8, 9A and 9B, the substrate 200 includes a first region 10 and a second region 20. The first region 10 is a pad region in which pad patterns are disposed, and the second region 20 is a cell region in which three-dimensional cells are disposed. The substrate 200 is the same substrate as the substrate 100 described with reference to FIGS. 1, 2A and 2B. A pattern structure 204 is disposed on the substrate 200 in the first region 10. The pattern structure 204 has the same configuration as the pattern structure 107 described with reference to FIGS. 1, 2A and 2B.

Conductive patterns CP are stacked on the substrate 200 in the second region 20 and are spaced apart from each other. Each of the conductive patterns CP includes a plurality of gate electrodes GE and a connector CN, as described with reference to FIGS. 1, 2A and 2B. Each of the plurality of gate electrodes GE has a line shape extending in a first direction. Sub-isolation patterns 262 are disposed between the gate electrodes GE that are spaced apart from each other in a second direction intersecting the first direction. The sub-isolation patterns 262 fill respective ones of sub-trenches 242 between the gate electrodes GE spaced apart from each other in the second direction. The first direction and the second direction are parallel to a top surface of the substrate 100 and cross each other. In the drawings, the first direction is an x-axis direction and the second direction is a y-axis direction.

Each of the pad patterns PP extends from an end of any one of the conductive patterns CP in the first direction. The pad patterns PP are disposed in the first region 10. Each of the pad patterns PP includes a flat portion FP and a landing sidewall portion LSP, as described with reference to FIGS. 1, 2A and 2B.

Each of the auxiliary pad patterns APP extends from an end of any one of the conductive patterns CP in the first direction. The auxiliary pad patterns APP are disposed in the first region 10. The auxiliary pad patterns APP are spaced apart from the pad patterns PP. Each of the auxiliary pad patterns APP includes an auxiliary flat portion AFP and an auxiliary sidewall portion ASP, as described with reference to FIGS. 1, 2A and 2B.

Insulation patterns 220a and 200Ua are disposed between the stacked conductive patterns CP. Each of the insulation patterns 220a under the uppermost insulation pattern 220Ua includes an insulation flat portion and an insulation sidewall portion, as described with reference to FIGS. 1, 2A and 2B.

The string selection lines 257 are disposed between the uppermost insulation pattern 220Ua and the insulation pattern 220a directly under the uppermost insulation pattern 220Ua. Each of the string selection lines 257 has a line shape extending in the first direction. The string selection lines 257 are disposed to be spaced apart from each other in the second direction. The string selection lines 257 are disposed to be parallel with the gate electrodes GE. The number of the string selection lines 257 is equal to the number of the gate electrodes GE included in each of the conductive patterns CP. The string selection lines 257 are positioned at the same level from the top surface of the substrate 200.

The stacked conductive patterns CP, the string selection lines 257 on the stacked conductive patterns CP, and the insulation patterns 220a and 220Ua constitute a single stack structure. In an embodiment, two or more stack structures are provided on the substrate 200. A main isolation pattern 260 is disposed between the two stack structures adjacent to each other. The two adjacent stack structures are symmetric to each other with respect to the main isolation pattern 260. The main isolation pattern 260 is disposed in a main trench 240 between the two adjacent stack structures. The main isolation pattern 260 is disposed on the top surface of the substrate 200. The main isolation pattern 260 includes a silicon oxide layer. The stack structures are disposed to be spaced apart from each other in the second direction.

The first floating conductive pattern 259a is disposed between the string selection line 257 and the landing sidewall portion LSP, and the second floating conductive pattern 259b is disposed between the string selection line 257 and the auxiliary sidewall portion ASP. The floating conductive patterns 259a and 259b are electrically insulated from the conductive patterns CP, the pad patterns PP, the auxiliary pad patterns APP and the string selection lines 257. The floating conductive patterns 259a and 259b and the string selection lines 257 are simultaneously formed at the same process stage. Thus, the floating conductive patterns 259a and 259b include the same material as the string selection lines 257.

Bottom surfaces of the floating conductive patterns 259a and 259b are positioned at the same level as bottom surfaces of the string selection lines 257 from the top surface of the substrate 200. The bottom surfaces of the floating conductive patterns 259a and 259b and the string selection lines 257 are located at the same distance from the substrate 200 in a third direction. In the drawings, the third direction is parallel with a z-axis direction.

The first floating conductive pattern 259a is adjacent to the main isolation pattern 260. A top surface of the first floating conductive pattern 259a is positioned at the same level as the top surfaces of the landing sidewall portions LSP from the top surface of the substrate 200. A top surface of the second floating conductive pattern 259b is positioned at the same level as a top surface of the auxiliary sidewall portion ASP from the top surface of the substrate 200.

Sacrificial patterns 210Lb, 210b and 210Ub are disposed between the pad patterns PP and the auxiliary pad patterns APP and between the first floating conductive pattern 259a and the second floating conductive pattern 259b.

The insulation patterns 220a and 220Ua and the sacrificial patterns 210Lb, 210b, and 210Ub include the same material as the insulation patterns 120a and the sacrificial patterns 110Lb and 110b described with reference to FIGS. 1, 2A and 2B, respectively.

The semiconductor pillars 230 penetrate the stacked gate electrodes GE and the stacked insulation patterns 220a and 220Ua. The semiconductor pillars 230 extend in the third direction. According to an embodiment, the semiconductor pillars 230 contact the substrate 200. The number of the semiconductor pillars 230 is two or more. The plurality of semiconductor pillars 230 are two-dimensionally arrayed along the first and second directions in a plan view. The plurality of semiconductor pillars 230 penetrate each of the stack structures.

Each of the semiconductor pillars 230 includes a semiconductor portion 231, a filling insulation material 232, and a drain region 233. The semiconductor portion 231, the filling insulation material 232 and the drain region 233 respectively correspond to the semiconductor portion 131, the filling insulation material 132 and the drain region 133 described with reference to FIGS. 1, 2A and 2B.

A data storage layer 250 is disposed between the semiconductor pillars 230 and the gate electrodes GE. The data storage layer 250 is a multi-layered film including the tunnel insulation layer 150a, the charge storage layer 150b and the blocking layer 150c described with reference to FIG. 3.

Common source regions are disposed in the substrate 200 under the main isolation pattern 260 and the sub-isolation patterns 262. Each of the common source regions has a line shape extending in the first direction. In the event that the substrate 200 has a first conductivity type, the common source regions and the drain regions 233 are doped with dopants of a second conductivity type different from the first conductivity type.

Cell contact plugs 274 are provided on respective ones of the first portions SP1 of the landing sidewall portions LSP of the pad patterns PP. The cell contact plugs 274 contact respective ones of the first portions SP1 of the landing sidewall portions LSP. The cell contact plugs 274 penetrate an interlayer insulation layer 270 on the stack structures. Widths of each of the cell contact plugs 274 in the first and second directions are greater than a width of each of the first portions SP1 in the second direction. Conductive interconnection lines 284 are disposed to be parallel with the second direction on the interlayer insulation layer 270. The conductive interconnection lines 284 are connected to the cell contact plugs 274.

Bit lines 282 are also disposed on the interlayer insulation layer 270. The bit lines 282 are electrically connected to the drain regions 233 of the semiconductor pillars 230 through bit line contact plugs 272 penetrating the interlayer insulation layer 270. The bit lines 282 extend in the second direction. The bit lines 282 cross the gate electrodes GE. The number of the bit lines 282 is two or more. The bit lines 282 are parallel with each other. Each of the bit lines 282 is electrically connected to the drain regions 233 of the plurality of semiconductor pillars 230 which are arrayed in the second direction to constitute a single column.

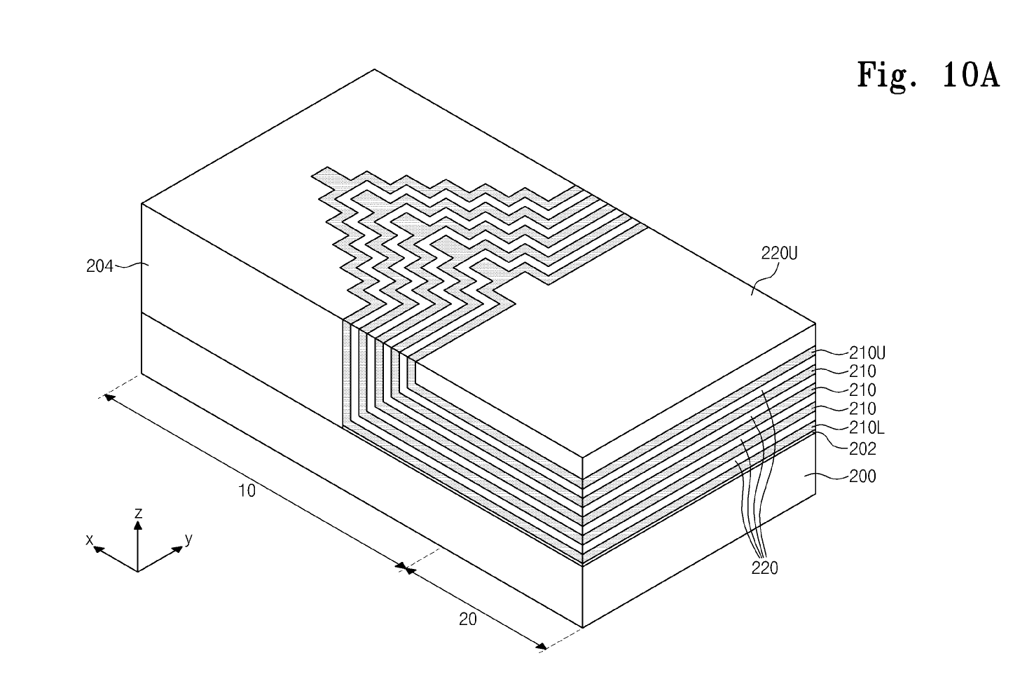

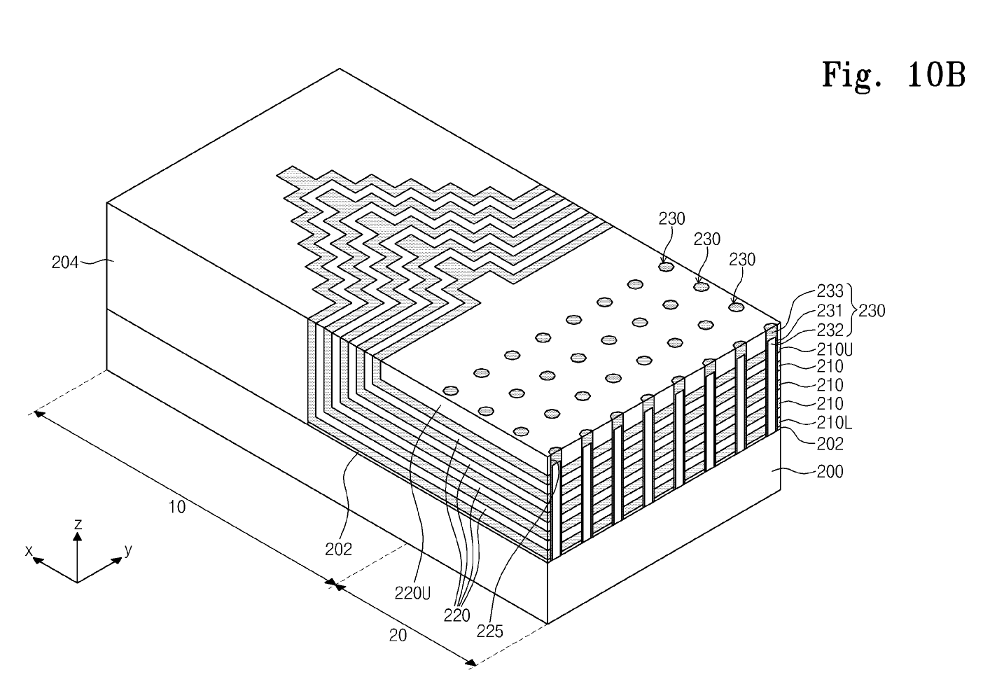

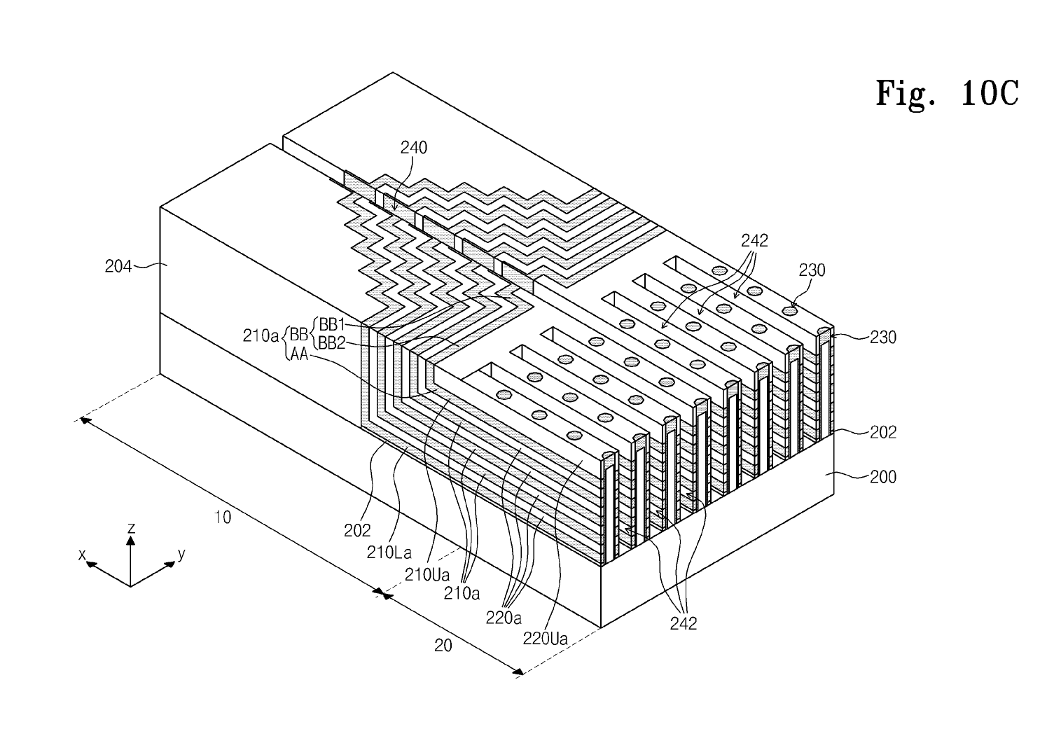

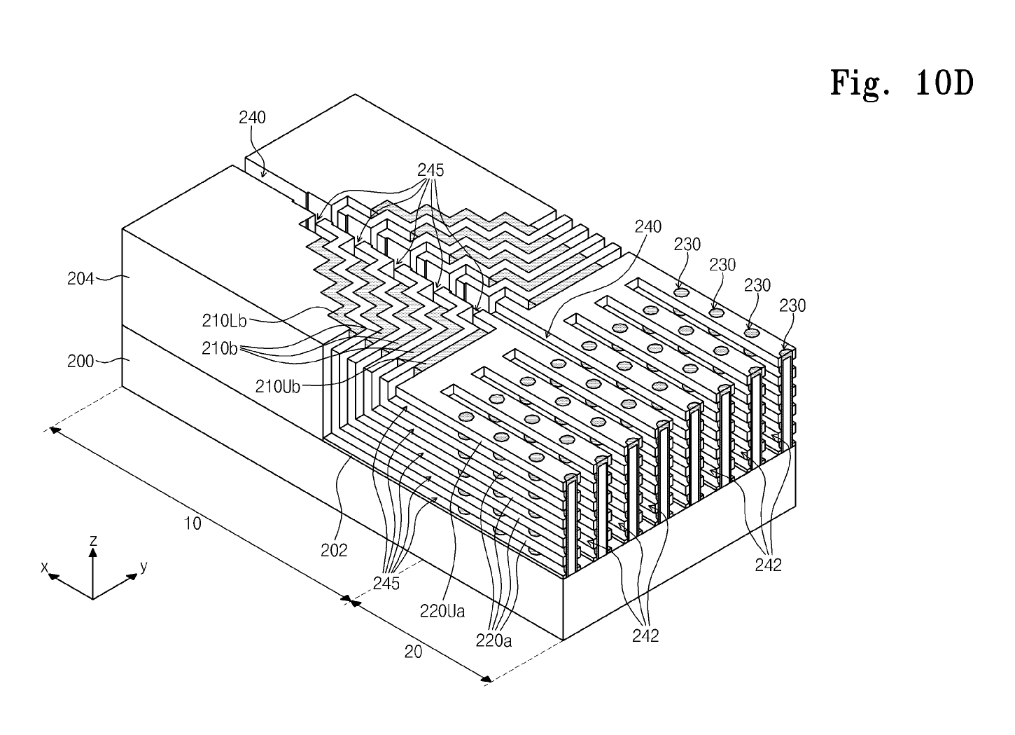

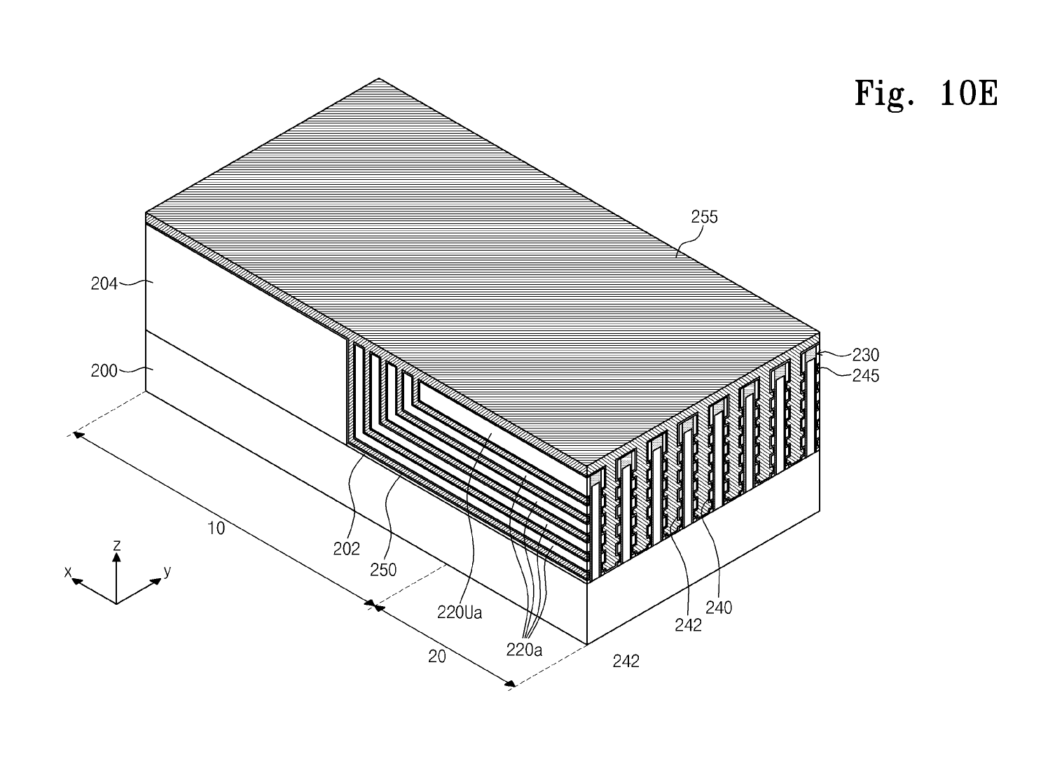

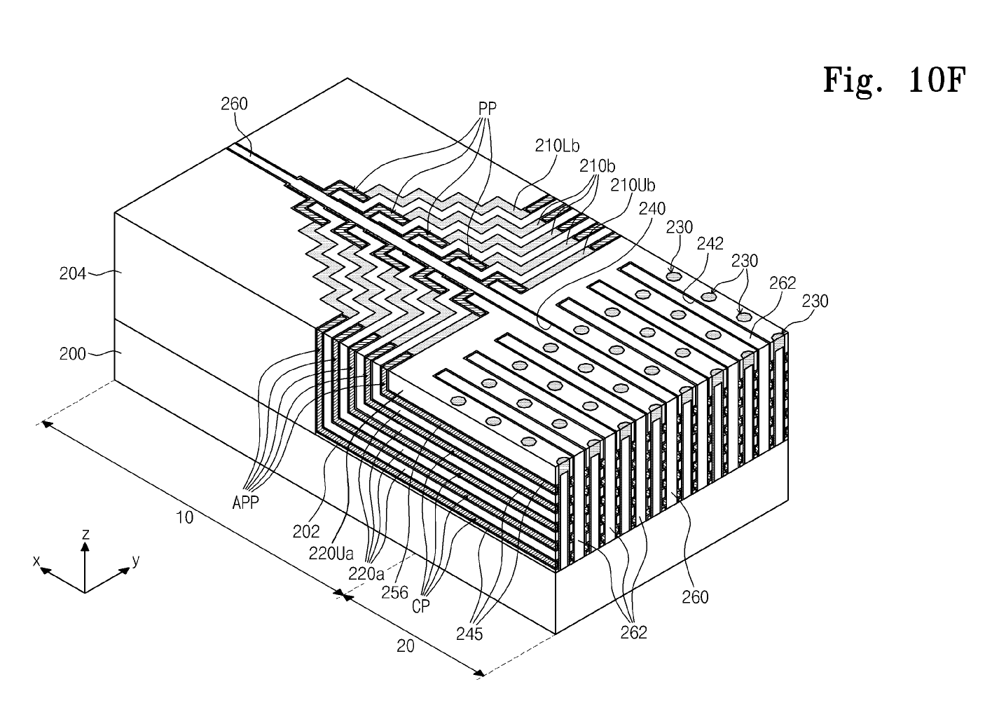

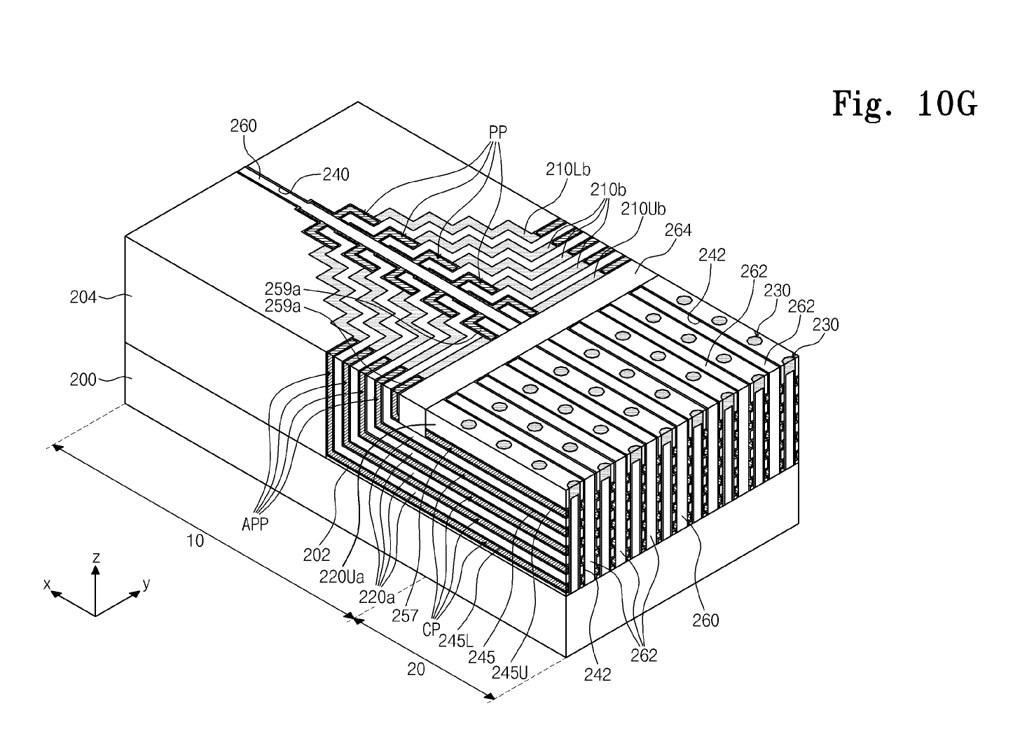

A method of fabricating a semiconductor device according to an exemplary embodiment will now be described. FIGS. 10A to 10G are perspective views illustrating a method of fabricating a semiconductor device according to an exemplary embodiment.

Referring to FIG. 10A, a substrate 200 including a first region 10 and a second region 20 is provided. A pattern structure 204 is formed on the substrate 200 in the first region 10. The pattern structure 204 is formed in the same manner as the processes of forming the pattern structure 107 described with reference to FIG. 4A. A buffer dielectric layer 202 is formed to cover a top surface of the substrate 200. For example, the buffer dielectric layer 202 is formed to include a silicon oxide layer using a thermal oxidation process.

First material layers and second material layers different from the first material layers are alternately and repeatedly stacked on the substrate 200 including the pattern structure 204. The first material layers are sacrificial layers 210L, 210 and 210U, and the second material layers are insulation layers 220 and 220U. After formation of the sacrificial layers 210L, 210 and 210U and the insulation layers 220 and 220U, the sacrificial layers 210L, 210 and 210U and the insulation layers 220 and 220U are planarized using the pattern structure 204 as an etch stop layer. The sacrificial layers 210L, 210 and 210U and the insulation layers 220 and 220U are formed of the same materials as the sacrificial layers 110L and 110 and the insulation layers 120, respectively, described with reference to FIGS. 1, 2A and 2B.

The sacrificial layers 210L, 210 and 210U are formed to have the same thickness. Alternatively, the lowermost and uppermost sacrificial layers 210L and 210U are formed to be thicker than the sacrificial layers 210 disposed between the lowermost sacrificial layer 210L and the uppermost sacrificial layer 210U. According to an embodiment, the sacrificial layers 210 disposed between the lowermost sacrificial layer 210L and the uppermost sacrificial layer 210U are formed to have the same thickness. The insulation layers 220 under the uppermost insulation layer 220U are formed to have the same thickness. In an embodiment, the uppermost insulation layer 220U is formed to be thicker than the insulation layers 220 under the uppermost insulation layer 220U.

As described with reference to FIG. 4B, each of the sacrificial layers 210L, 210 and 210U includes a flat portion parallel with the top surface of the substrate 200 and a sidewall portion upwardly extending from an end of the flat portion. As described with reference to FIG. 4B, each of the insulation layers 220 under the uppermost insulation layer 220U includes a flat portion parallel to the top surface of the substrate 200 and a sidewall portion upwardly extending from an end of the flat portion.

Referring to FIG. 10B, the buffer dielectric layer 202, the insulation layers 220 and 220U and the sacrificial layers 210L, 210 and 210U are patterned to form channel openings 225 exposing the top surface of the substrate 200. The channel openings 225 penetrate the flat portions of the sacrificial layers 210L, 210, 210U and the insulation layers 220 and 220U. The channel openings 225 are formed in the same manner as described with reference to FIG. 4D.

Semiconductor pillars 230 are formed to fill respective ones of the channel openings 225. Each of the semiconductor pillars 230 includes a semiconductor portion 231 covering a sidewall of the channel opening 225, a filling insulation material 232 filling an empty space surrounded by the semiconductor portion 231, and a drain region 233 filling an upper portion of the channel opening 225.

Referring to FIG. 10C, the pattern structure 204, the insulation layers 220 and 220U and the sacrificial layers 210L, 210 and 210U are patterned to form at least one main trench 240 and sub-trenches 242. The main trench 240 and the sub-trenches 242 are formed in the same manner as described with reference to FIG. 4F. Prior to formation of the main trench 240 and the sub-trenches 242, a capping insulation layer (not shown) is formed to cover the pattern structure 204, the insulation layers 220 and 220U and the sacrificial layers 210L, 210 and 210U.

At least two separate preliminary stack structures are defined by the main trench 240. Each of the preliminary stack structures includes sacrificial patterns 210La, 210a and 210Ua and insulation patterns 220a and 220Ua which are alternately and repeatedly stacked. The main trench 240 extends in the first direction, and the preliminary stack structures are symmetric to each other with respect to the main trench 240.

The sub-trenches 242 extend in the first direction and split a portion of each of the preliminary stack structures, through which the semiconductor pillars 230 pass, into a plurality of line-shaped sections extending in the first direction.

Each of the sacrificial patterns 210La, 210a and 210Ua includes a flat portion AA parallel with the substrate 100 and a sidewall portion BB upwardly extending from an end of the flat portion AA. The sidewall portion BB of each of the sacrificial patterns 210La, 210a and 210Ua includes at least one first portion BB1 extending in the first direction and at least one second portion BB2 extending in the second direction.

Sidewalls of the sacrificial patterns 210La, 210a and 210Ua and sidewalls of the insulation patterns 220a and 220Ua are exposed by the main trench 240 and the sub-trenches 242.

Referring to FIG. 10D, by a selective etching process, the sacrificial patterns 210La, 201a and 210Ua exposed by the main trench 240 and the sub-trenches 242 are partially removed to form recessed regions 245.

During the selective etching process, at least the outermost first and second portions BB1 and BB2 of the sidewall portions BB of the sacrificial patterns 210La, 210a and 210Ua are removed. After the selective etching process, sacrificial patterns 210Lb, 210b and 210Ub remain in the first region 10. The selective etching process is the same as the selective etching process described with reference to FIG. 4G. In an embodiment, the buffer dielectric layer 202 is formed to be thinner than the insulation patterns 220a and 220Ua. Thus, the buffer dielectric layer 202 is removed during the selective etching process. Alternatively, the buffer dielectric layer 202 remains after the selective etching process. Hereinafter, for the purpose of description, the buffer dielectric layer 202 remains during the selective etching process.

According to an embodiment, the recessed regions 245 expose portions of a sidewall of each of the semiconductor pillars 130, which contact the sacrificial patterns 210La, 210a and 210Ua.

Referring to FIG. 10E, after formation of the recessed regions 245, a data storage layer 250 is formed on the substrate including the recessed regions 245. The data storage layer 250 is formed in the same manner as described with reference to FIG. 4G. The data storage layer 250 is formed to substantially a uniform thickness along inner surfaces of the recessed regions 245. The data storage layer 150 is conformally formed in the recessed regions 245. The data storage layer 250 is formed by sequentially stacking the tunnel insulation layer 150a, the charge storage layer 150b and the blocking layer 150c described with reference to FIG. 3.

After formation of the data storage layer 250, a gate conductive layer 255 is formed on the data storage layer 250, as described with reference to FIG. 4G. The gate conductive layer 255 is formed to fill the recessed regions 245. The gate conductive layer 155 is formed to partially or fully fill the main trench 240 and the sub-trenches 242. The gate conductive layer 155 is electrically insulated from the semiconductor pillars 230 and the substrate 200 by the data storage layer 250.

Referring to FIG. 10F, after the gate conductive layer 255 is formed, the gate conductive layer 255 positioned outside the recessed regions 245 is removed to form conductive patterns CP, pad patterns PP, auxiliary pad patterns APP and preliminary string selection lines 256 that remain in the recessed regions 245. The gate conductive layer 255 positioned outside the recessed regions 245 is selectively removed by a wet etching process or a dry etching process. Common source regions are formed in the substrate 100 under the main trench 240 and the sub-trenches 242 by the same processes as described with reference to FIG. 41. A main isolation pattern 260 and sub-isolation patterns 262 are formed to fill the main trench 240 and the sub-trenches 242, respectively. The main isolation pattern 260 and the sub-isolation patterns 262 are formed in the same manner as described with reference to FIG. 4I.

Referring to FIG. 10G, the uppermost insulation pattern 220Ua and the preliminary string selection line 256 in each of the preliminary stack structures are patterned to form string selection lines 257 extending in the first direction and to form floating conductive patterns 259a and 259b. An insulation material 264 is formed between the floating conductive patterns 259a and 259b and the string selection lines 257.

The stacked conductive patterns CP, the string selection lines 257 on the stacked conductive patterns CP, and the insulation patterns 220a and 220Ua, which are located at a side of the main isolation pattern 260, constitute a single stack structure.

Subsequently, referring again to FIGS. 8, 9A and 9B, an interlayer insulation layer 270 is formed on the stack structures. Bit line contact plugs 272 and cell contact plugs 274 are formed to penetrate the interlayer insulation layer 270. The bit line contact plugs 272 are connected to respective ones of the drain regions 233 of the semiconductor pillars 230. The cell contact plugs 274 are connected to respective corresponding first portions of the first portions SP1 of the landing sidewall portions LSP of the pad patterns PP. The bit line contact plugs 272 and the cell contact plugs 274 are formed by forming contact holes penetrating the interlayer insulation layer 270 to expose the drain regions 233 and the first portions SP1 of the landing sidewall portions LSP and by filling the contact holes with a conductive layer. Bit lines 282 and conductive interconnection lines 284 are formed on the interlayer insulation layer 270 to extend in the second direction. The bit lines 282 are connected to the bit line contact plugs 272, and the conductive interconnection lines 284 are connected to the cell contact plugs 274.

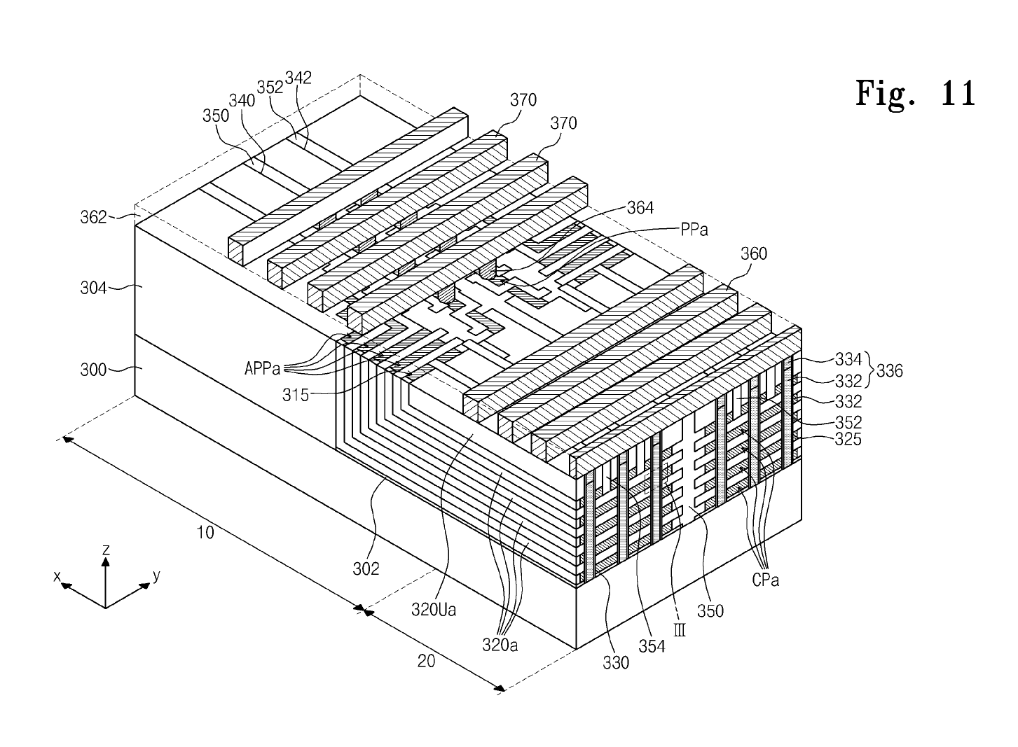

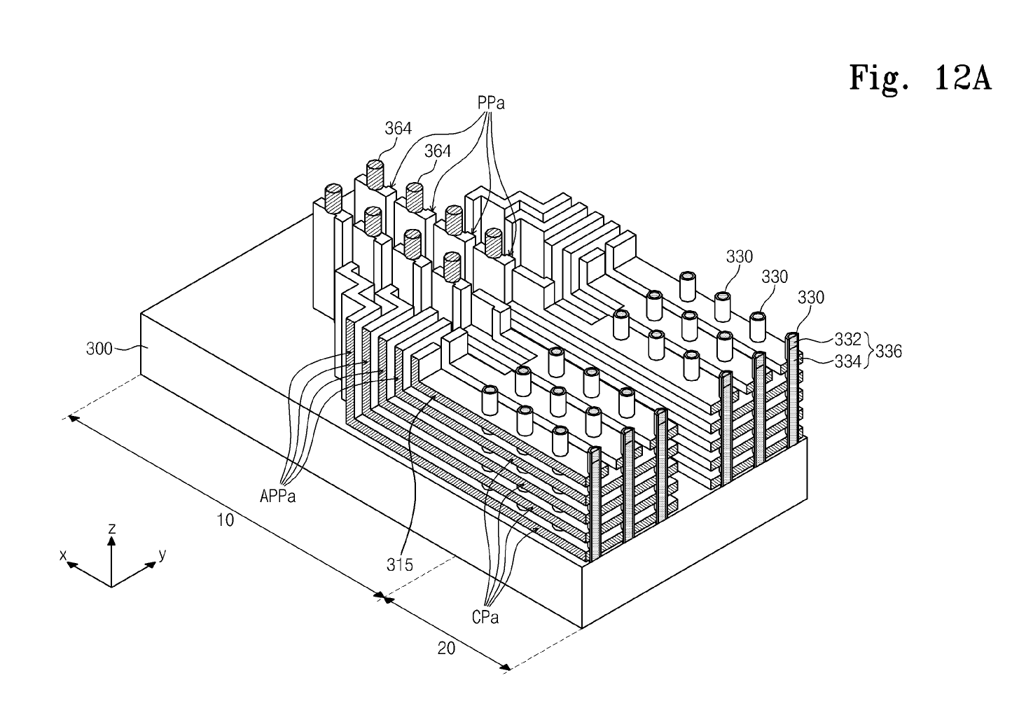

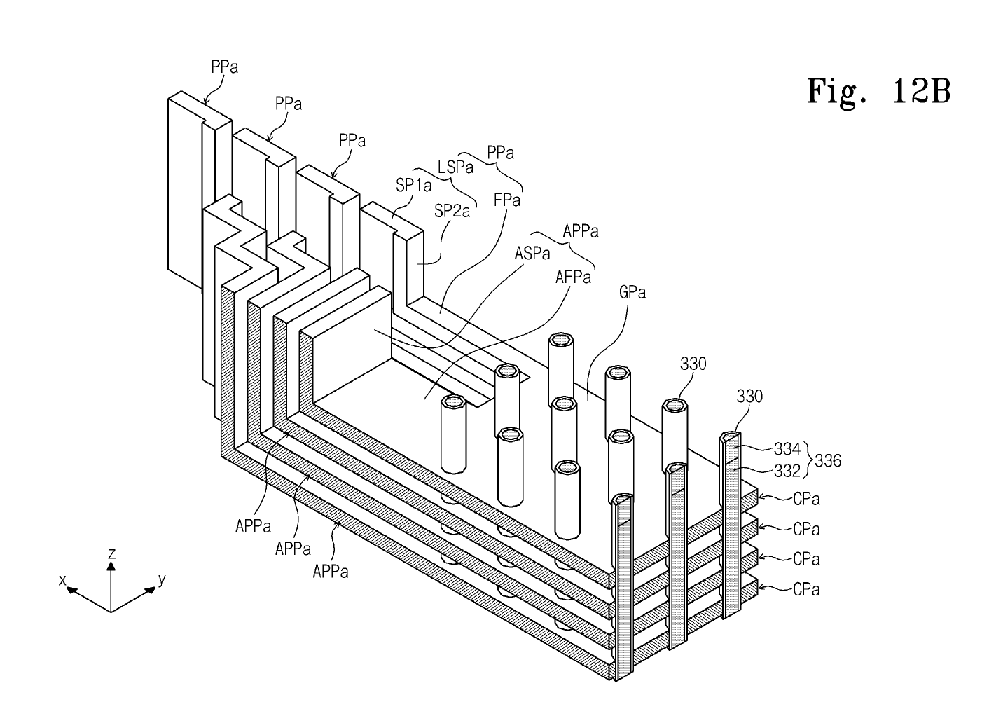

A semiconductor device according to an exemplary embodiment is now described. FIGS. 11, 12A and 12B are perspective views illustrating a semiconductor device according to an exemplary embodiment. For convenience of description, FIGS. 11 and 12A illustrate conductive patterns CPa, pad patterns PPa, auxiliary pad patterns APPa, string selection lines 315, a substrate 300, semiconductor pillars 336, cell contact plugs 364, conductive interconnection lines 370 and bit lines 360, and FIG. 12B illustrates semiconductor pillars 336, conductive patterns CPa, pad patterns PPa connected to the conductive patterns CPa, and auxiliary pad patterns APPa connected to the conductive patterns CPa, which are included in a single stack structure. For convenience of recognition, portions of the conductive patterns CPa, the pad patterns PPa and the auxiliary pad patterns APPa of FIGS. 11, 12A and 12B are hatched.

Referring to FIGS. 11, 12A and 12B, the substrate 300 includes a first region 10 and a second region 20. The first region 10 corresponds to a pad region on which the pad patterns PPa are disposed, and the second region 20 corresponds to a cell region on which three-dimensional cells are disposed. The substrate 300 is the same substrate as the substrate 100 described with reference to FIGS. 1, 2A and 2B. A pattern structure 304 is disposed on the substrate 300 in the first region 10. The pattern structure 304 has the same configuration as the pattern structure 107 described with reference to FIGS. 1, 2A and 2B.

Conductive patterns CPa are vertically stacked on the substrate 300 in the second region 20 and are spaced apart from each other. Each of the conductive patterns CPa has a flat plate shape extending in first and second directions. The first direction and the second direction are parallel with a top surface of the substrate 300 and cross each other. In the drawings, the first direction is an x-axis direction and the second direction is a y-axis direction.

The pad patterns PPa extend from respective ones of sidewalls of the conductive patterns CPa in the first direction. The pad pattern PPa connected to the conductive pattern CPa located at a relatively lower level extends in the first direction to be longer than the pad pattern PPa connected to the conductive pattern CPa located at a relatively higher level. The pad patterns PPa are disposed on the substrate 300 in the first region 10.

Each of the pad patterns PPa includes a flat portion FPa and a landing sidewall portion LSPa upwardly extending from a top surface of the flat portion FPa. The flat portion FPa of each of the pad patterns PPa and the conductive pattern CPa connected to the flat portion FPa are located at the same level from the top surface of the substrate 300 and have the same thickness. The flat portion FPa connected to the conductive pattern CPa located at a relatively lower level extends in the first direction to be longer than the flat portion FPa connected to the conductive pattern CPa located at a relatively higher level. Thus, the flat portions FPa connected to respective ones of the conductive patterns CPa have a step shape. A length of the flat portion FPa in the first direction is reduced in a direction away from the top surface of the substrate 300. Thus, the flap portions FPa vertically stacked have a downward step structure in the first direction (e.g., a positive x-axis direction).

Top surfaces of all the landing sidewall portions LSPa are located at substantially the same level from the substrate 100. A landing sidewall portion LSPa extending from a flat portion FPa connected to a conductive pattern CPa located at a relatively lower level has a greater length in a third direction than a landing sidewall portion LSPa extending from a flat portion FPa connected to a conductive pattern CPa located at a relatively higher level. The third direction corresponds to a z-axis direction which is perpendicular to the x-axis direction and the y-axis direction.

Each of the landing sidewall portion LSPa includes a first portion SP1a extending in the first direction and a second portion SP2a extending in the second direction. A width of the first portion SP1a of the landing sidewall portion LSPa in the first direction is less than a width of the flat portion FPa in the first direction and is greater than a thickness of the conductive pattern CPa in the third direction. A width of the first portion SP1a of the landing sidewall portion LSPa in the second direction is less than a width of the flat portion FPa in the second direction. A width of the second portion SP2a of the landing sidewall portion LSPa in the second direction is equal to a width of the flat portion FPa in the second direction. In each of the pad patterns PPa, a distance between the first portion SP 1 a and the flat portion FPa is less than a distance between the second portion SP2a and the flat portion FPa.

When viewed from a plan view parallel with an x-y plane, top surfaces of the first portions SP1a of the landing sidewall portions LSPa connected to the conductive patterns CPa are arrayed along the first direction to constitute a row which is parallel with the x-axis direction. The first portions SP1a arrayed in the row are spaced apart from each other. Each of top surfaces of the first portions SP1a has two long sides which are parallel with the first direction. Each of the top surfaces of the first portions SP1a has a rectangular shape. Distances between the first portions SP1a adjacent to each other along the first direction are less than a length of the long sides of the top surfaces of the first portions SP1a. An area of each of the top surfaces of the first portions SP1a is greater than an area of each of top surfaces of the second portions SP2a. Top surfaces of the landing sidewall portions LSPa have substantially the same area. A length of short sides of the top surfaces of the first portions SP1a is substantially equal to the thickness of the conductive patterns CPa in the third direction. In each of the pad patterns PPa, a width of the first portion SP1a in the second direction is equal to a width of the second portion SP2a in the first direction.

The auxiliary pad patterns APPa extend from respective ones of sidewalls of the conductive patterns CPa in the first direction. The auxiliary pad patterns APPa are spaced apart from the pad patterns PPa. In each stack structure, a sub-trench 342 is defined between the pad patterns PPa and the auxiliary pad patterns APPa. A sub-isolation pattern 352 is disposed in the sub-trench 342. The sub-isolation pattern 352 is formed of an insulation material. The sub-isolation pattern 352 is disposed between the pad patterns PPa and the auxiliary pad patterns APPa. The auxiliary pad pattern APPa connected to the conductive pattern CPa located at a relatively lower level extends in the first direction to be longer than the auxiliary pad pattern APPa connected to the conductive pattern CPa located at a relatively higher level. The auxiliary pad patterns APPa are disposed on the substrate 300 in the first region 10.

Each of the auxiliary pad patterns APPa includes an auxiliary flat portion AFPa extending from any one of the conductive patterns CPa in the first direction and an auxiliary sidewall portion ASPa upwardly extending from an end of the auxiliary flat portion AFPa. The auxiliary flat portion AFPa extends from a portion of the sidewall of the conductive pattern CPa in the first direction. The auxiliary flat portion AFPa connected to the conductive pattern CPa located at a relatively lower level extends in the first direction to be longer than the auxiliary flat portion AFPa connected to the conductive pattern CPa located at a relatively higher level. Thus, the auxiliary flat portions AFPa connected to respective ones of the conductive patterns CPa have a step shape. A length of the auxiliary flat portion AFPa in the first direction is reduced in a direction away from the top surface of the substrate 300. Thus, the auxiliary flap portions AFPa vertically stacked have a downward step structure in the first direction (e.g., a positive x-axis direction). Top surfaces of all the auxiliary sidewall portions ASPa are located at substantially the same level from the substrate 300. At least one of the auxiliary sidewall portions ASPa includes a first portion extending in the first direction and a second portion extending in the second portion.

Any one of the conductive patterns CPa, the pad pattern PPa connected to the conductive pattern, and the auxiliary pad pattern APPa connected to the conductive pattern constitute a single unified body without any junction between the conductive pattern CP, the pad pattern PPa, and the auxiliary pad pattern APPa.

Insulation patterns 320a and 320Ua are disposed in respective ones of spaces between the conductive patterns CPa vertically stacked. Each of the insulation patterns 320a under the uppermost insulation pattern 320a includes an insulation flat portion and an insulation sidewall portion. The insulation flat portion is parallel with the substrate 300, and the insulation sidewall portion upwardly extends from an end of the insulation flat portion. The insulation flat portions of the insulation patterns 320a are disposed in respective ones of spaces between the conductive patterns CPa. The insulation flat portions extend and intervene between the flat portions FPa and between the auxiliary flat portions AFPa. The insulation sidewall portions of the insulation patterns 320a are disposed in respective ones of spaces between the landing sidewall portions LSPa. Further, the insulation sidewall portions of the insulation patterns 320a are disposed in respective ones of spaces between the auxiliary sidewall portions ASPa.

The string selection lines 315 are disposed on the uppermost conductive patterns CPa. The string selection lines 315 are disposed to be spaced apart from each other in the second direction. The string selection lines 315 are located at the same level from the substrate 300. The string selection lines 315 adjacent to each other in the second direction are separated from each other by insulation materials 354 which are disposed between the string selection lines 315. The insulation materials 354 are disposed on the insulation pattern 320a which is disposed directly under the string selection lines 315. Each of the string selection lines 315 includes a flat portion parallel with the substrate 300 and a sidewall portion upwardly extending from an end of the flat portion. Each of the flat portions of the string selection lines 315 has a line shape extending in the first direction.

Each of the insulation patterns 320a and 320Ua includes an oxide material. For example, each of the insulation patterns 320a and 320Ua includes a silicon oxide layer. Each of the conductive patterns CPa, the pad patterns PPa, the auxiliary pad patterns APPa and the string selection lines 315 includes a conductive material. For example, each of the conductive patterns CPa, the pad patterns PPa, the auxiliary pad patterns APPa and the string selection lines 315 includes at least one of a metal layer (e.g., a tungsten layer, an aluminum layer, a titanium layer or a tantalum layer), a conductive metal nitride layer (e.g., a titanium nitride layer or a tantalum nitride layer) and a doped semiconductor layer (e.g., a doped silicon layer, a doped germanium layer or a doped silicon-germanium layer).

The single stack structure includes the vertically stacked conductive patterns CPa, the string selection lines 315 on the vertically stacked conductive patterns CPa, and the insulation patterns 320a and 320Ua between the conductive patterns CPa and the string selection lines 315. In an embodiment, the number of the stack structures disposed on the substrate 100 is two or more. A main isolation pattern 350 is disposed between the two adjacent stack structures. The two adjacent stack structures have a symmetrical to each other with respect to the main isolation pattern 350. The main isolation pattern 350 is disposed in a main trench 340 between the two adjacent stack structures. The main isolation pattern 350 is disposed on the substrate 300 at a side of each of the stack structures. The main isolation pattern 350 includes an insulation material, for example, a silicon oxide layer. The stack structures are disposed to be spaced apart from each other in the second direction.

A data storage layer 330 is formed to cover sidewalls of channel openings 325 penetrating the string selection lines 315, the conductive patterns CPa and insulation patterns 320a and 320Ua. The channel openings 325 surrounded by the data storage layer 330 are filled with respective ones of semiconductor pillars 336. Accordingly, the data storage layer 330 is disposed between the semiconductor pillars 336 and the conductive patterns CPa.

The number of the channel openings 325 is two or more, and the number of the semiconductor pillars 336 is two or more. Each of the semiconductor pillars 336 extends in the third direction. The third direction is parallel with the z-axis, as described above. According to an embodiment, the semiconductor pillars 336 contact the substrate 300. The semiconductor pillars 336 are two-dimensionally arrayed along the first and second directions in a plan view. Each of the semiconductor pillars 336 includes a semiconductor portion 332 filling the channel opening 325 and a drain region 334. The drain region 334 corresponds to an upper portion of the semiconductor pillar 336. When the substrate 300 has a first conductivity type, the drain region 334 has a second conductivity type different from the first conductivity type. The semiconductor pillars 336 include a single crystalline semiconductor or a poly crystalline semiconductor. In an embodiment, each of the semiconductor pillars 336 is formed to have a cylindrical shape that includes a semiconductor portion conformally covering a sidewall of the channel opening 325 and a filling insulation material filling a space surrounded by the semiconductor portion.

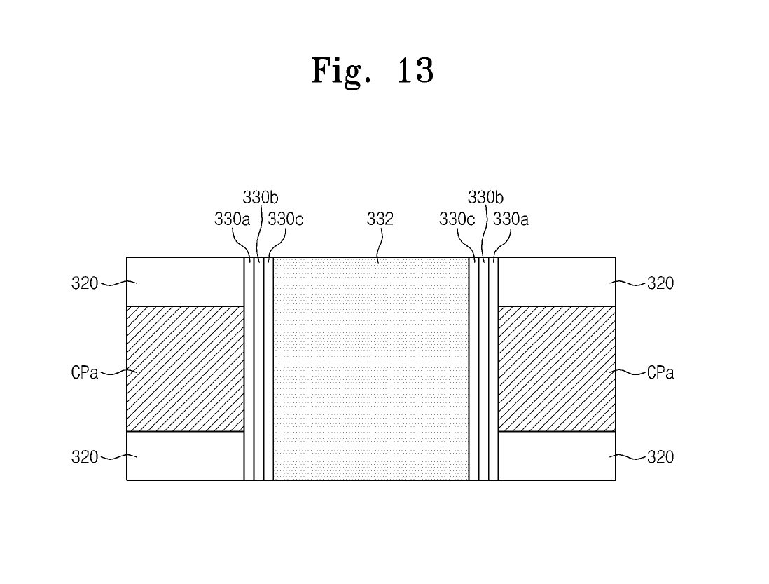

The data storage layer 330 is formed of a multi-layered film. Detailed configurations of the data storage layer 330 are described with reference to FIG. 13. FIG. 13 is an enlarged view illustrating a portion ‘III’ of FIG. 11 to describe a data storage layer of a semiconductor device according to an exemplary embodiment.

Referring to FIGS. 11, 12A, 12B and 13, the data storage layer 330 includes a blocking layer 330a, a charge storage layer 330b and a tunnel insulation layer 330c. The blocking layer 330a is disposed to cover sidewalls of the channel openings 325. The charge storage layer 330b is disposed between the blocking layer 330a and the semiconductor pillars 336. The tunnel insulation layer 330c is disposed between the charge storage layer 330b and the semiconductor pillars 336. The blocking layer 330a, the charge storage layer 330b and the tunnel insulation layer 330c are formed of the same materials as the blocking layer 150c, the charge storage layer 150b and the tunnel insulation layer 150a described with reference to FIG. 3, respectively.

Common source regions are disposed in the substrate 300 under the stack structures. The common source regions include impurity regions that are doped with dopants of the second conductivity type. In each of the stack structures, an electrical bias applied to the lowermost conductive pattern CPa controls electrical connections between the semiconductor pillars 336 and the common source region under the lowermost conductive pattern CPa. The common source regions are disposed to have a plate shape in the substrate 300.

Cell contact plugs 364 are provided on respective ones of the first portions SP1a of the landing sidewall portions LSPa. The cell contact plugs 364 contact respective ones of the first portions SP1a of the landing sidewall portions LSPa. The cell contact plugs 364 penetrate an interlayer insulation layer 362 covering the stack structures. Widths of each of the cell contact plugs 364 in the first and second directions are greater than a width of each of the first portions SP1a in the second direction. Conductive interconnection lines 370 are disposed on the interlayer insulation layer 362. The conductive interconnection lines 370 are electrically connected to the cell contact plugs 364.

Bit lines 360 are disposed on the uppermost insulation pattern 320Ua. The bit lines 360 are electrically connected to the drain regions 334 of the semiconductor pillars 336. In each of the stack structures, an electrical bias applied to one selected from the string selection lines 315 controls electrical connections between the bit lines 360 and the semiconductor pillars 336 surrounded by the selected string selection line 315. The bit lines 360 extend in the second direction. The number of the bit lines 360 is two or more. The bit lines 360 are parallel to each other. Each of the bit lines 360 is electrically connected to the plurality of drain regions 334 formed in the plurality of semiconductor pillars 336 which are arrayed in a column parallel to the second direction. In an embodiment, the bit lines 360 are disposed on the interlayer insulation layer 362. According to an embodiment, the bit lines 360 are electrically connected to the drain regions 334 through plugs penetrating the interlayer insulation layer 362.

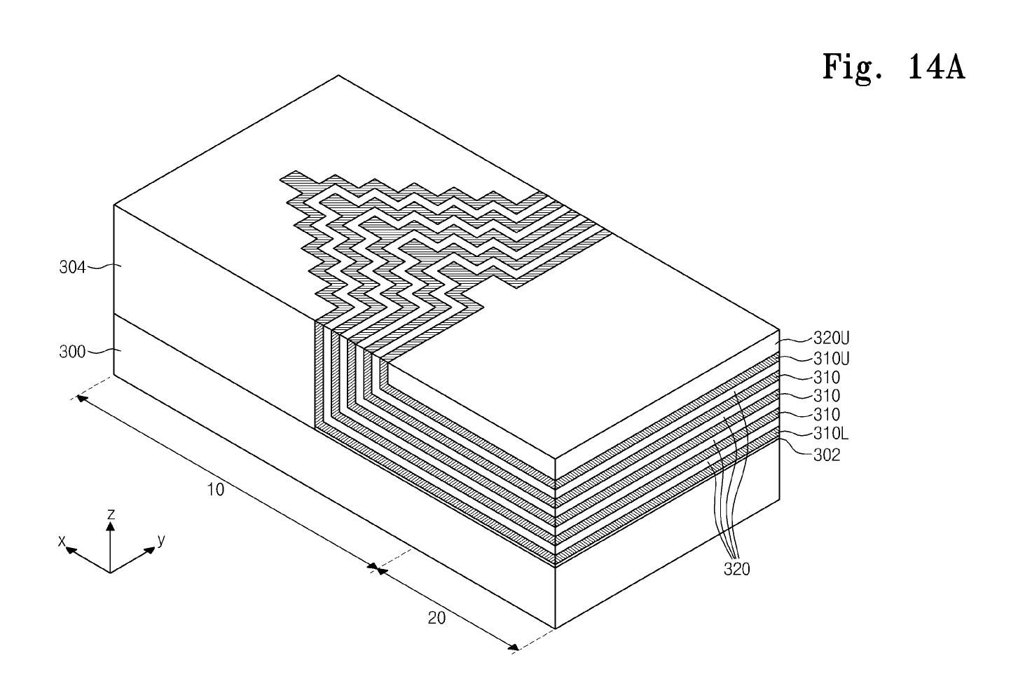

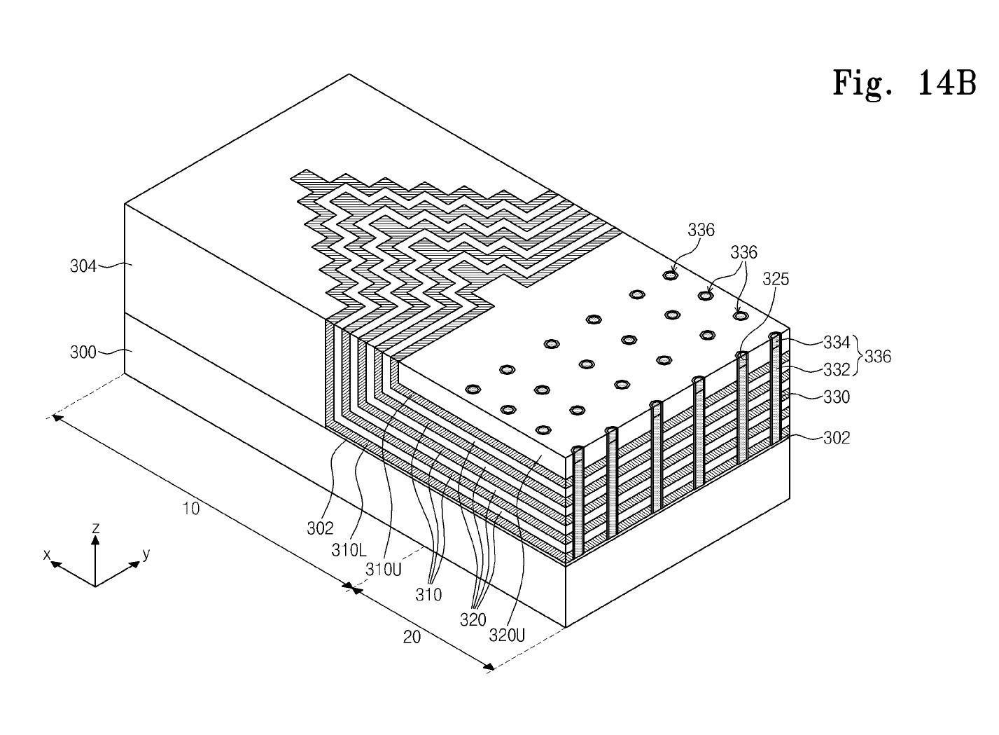

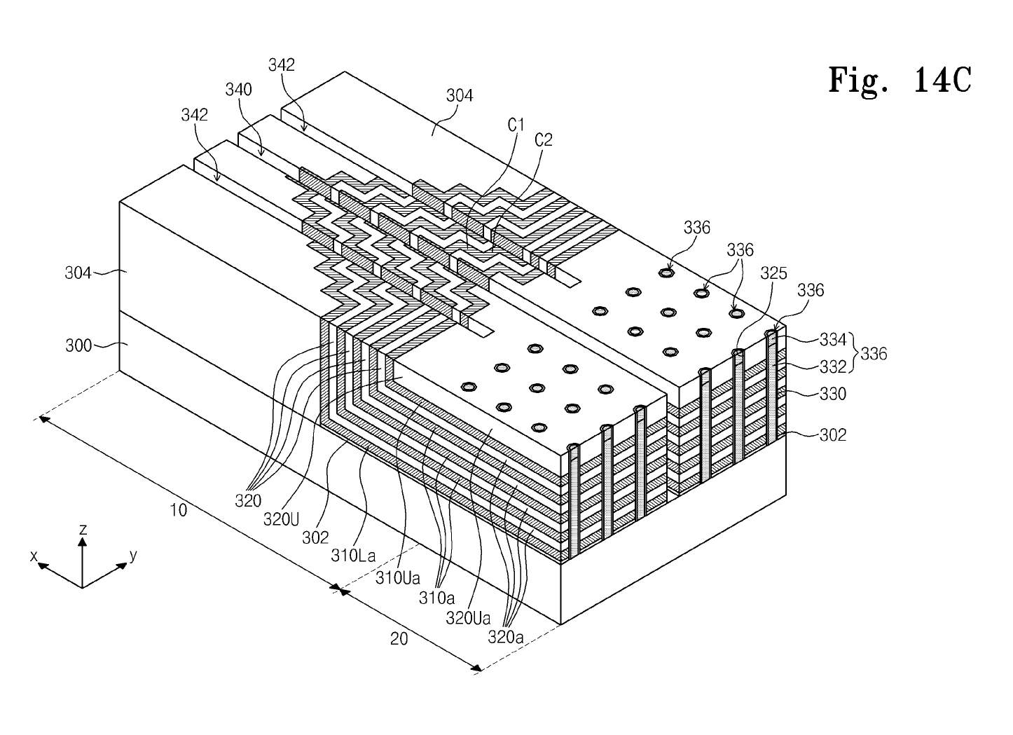

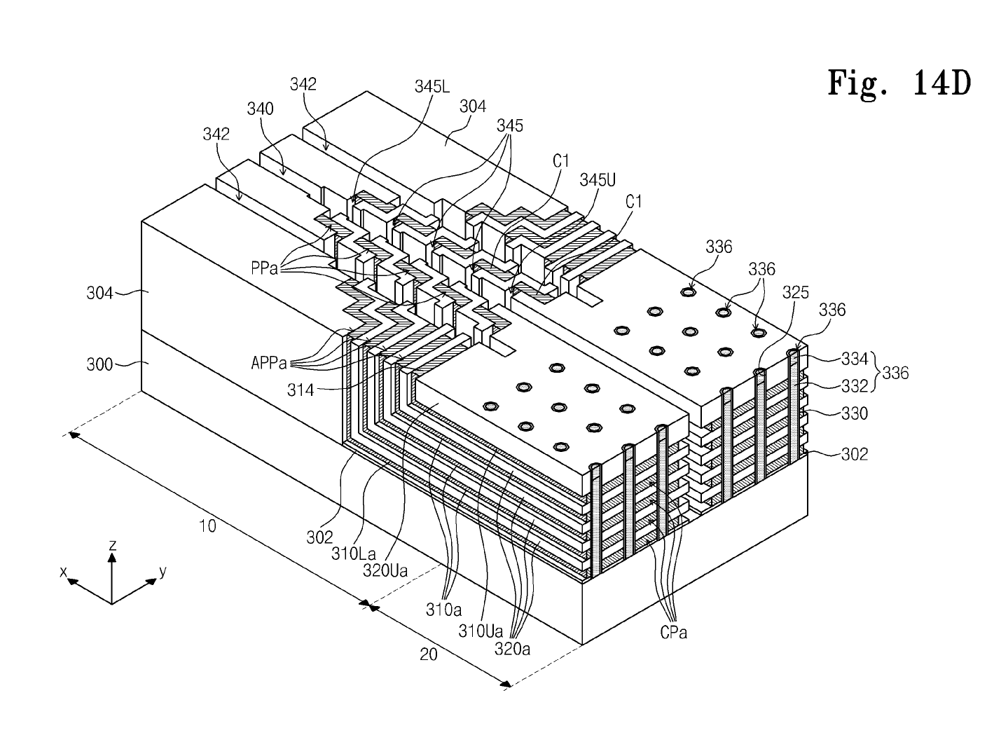

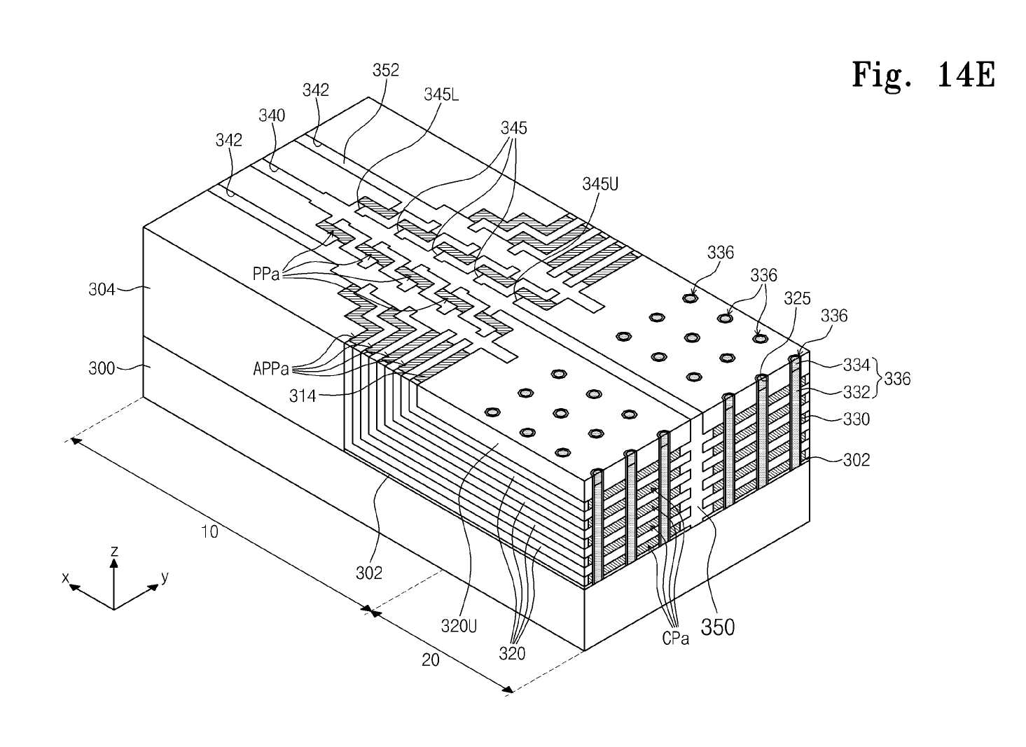

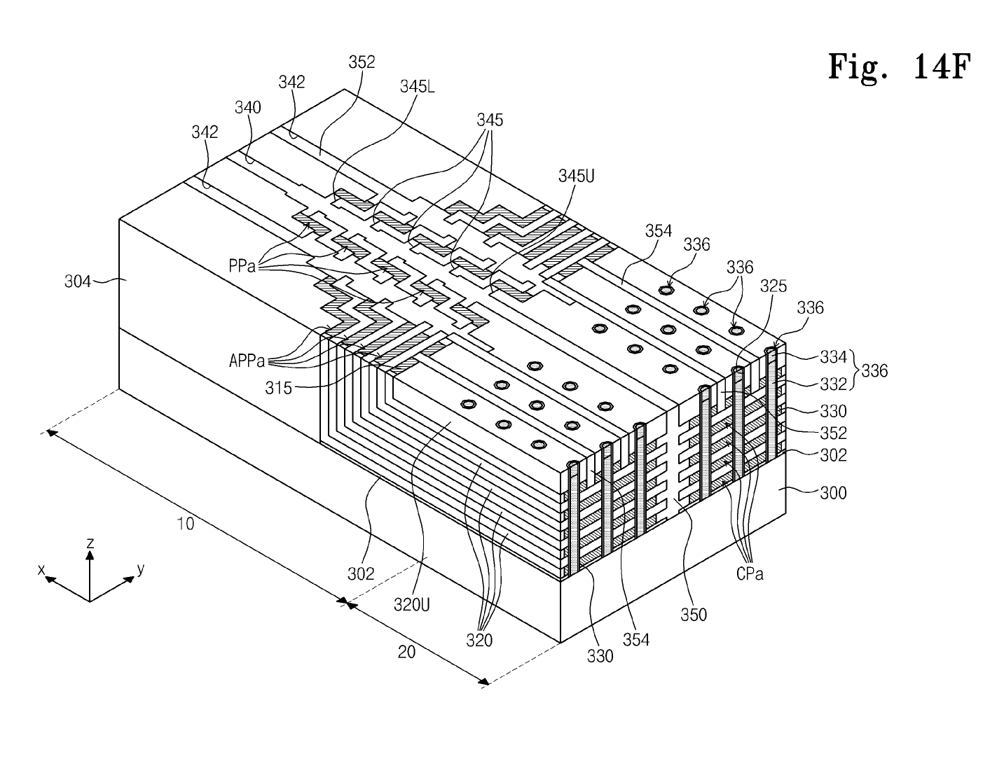

A method of fabricating a semiconductor device according to an exemplary embodiment is now described. FIGS. 14A to 14F are perspective views illustrating a method of fabricating a semiconductor device according to an exemplary embodiment.

Referring to FIG. 14A, a substrate 300 including a first region 10 and a second region 20 is provided. A pattern structure 304 is formed on the substrate 300 in the first region 10. The pattern structure 304 is formed in the same manner as the processes of forming the pattern structure 107 described with reference to FIG. 4A. A buffer dielectric layer 302 is formed to cover a top surface of the substrate 300. For example, the buffer dielectric layer 302 is formed of a silicon oxide layer by a thermal oxidation process. A common source region is formed in the substrate 300 using the buffer dielectric layer 302 as an ion implantation buffer layer. While the substrate 300 has a first conductivity type, the common source region is doped with dopants of a second conductivity type different from the first conductivity type. The common source region is formed to have a flat plate shape under the top surface of the substrate 300.

After the pattern structure 304 is formed, first material layers and second material layers different from the first material layers are alternately and repeatedly stacked on the substrate 300. The first material layers are conductive layers 310L, 310 and 310U, and the second material layers are insulation layers 320 and 320U. After the conductive layers 310L, 310 and 310U and the insulation layers 320 and 320U are stacked, the conductive layers 310L, 310 and 310U and the insulation layers 320 and 320U are planarized using the pattern structure 304 as an etch stop layer.

The conductive layers 310L, 310 and 310U are formed of the same material. The lowermost and uppermost conductive layers 310L and 310U are formed to be thicker than the conductive layers 310 between the lowermost and uppermost conductive layers 310L and 310U. The conductive layers 310 between the lowermost and uppermost conductive layers 310L and 310U are formed to have the same thickness. The insulation layers 320 and 320U are formed of the same material. Among the insulation layers 320 and 320U, the uppermost insulation layer 320U is formed to be thicker than the insulation layers 320 under the uppermost insulation layer 320U. The insulation layers 320 under the uppermost insulation layer 320U are formed to have the same thickness.

After planarization of the conductive layers 310L, 310 and 310U and the insulation layers 320 and 320U, each of the conductive layers 310L, 310 and 310U includes a flat portion parallel to the top surface of the substrate 300 and a sidewall portion upwardly extending from an end of the flat portion. The sidewall portion includes at least one first portion extending in a first direction and at least one second portion extending in a second direction intersecting the first direction. In the drawings, the first direction is parallel with an x-axis direction, and the second direction is parallel with a y-axis direction. The number of the first and second portions of the conductive layer located at a relatively lower level is greater than the number of the first and second portions of the conductive layer located at a relatively higher level.

Each of the insulation layers 320 and 320U under the uppermost insulation layer 320U includes a flat portion parallel to the top surface of the substrate 300 and a sidewall portion upwardly extending from an end of the flat portion. The sidewall portion of the insulation layer 320 or 320U includes at least one first portion extending in the first direction and at least one second portion extending in the second direction. The number of the first and second portions of an insulation layer located at a relatively lower level is greater than the number of the first and second portions of an insulation layer located at a relatively higher level.

Referring to FIG. 14B, the insulation layers 320 and 320U, the conductive layers 310L, 310 and 310U, and the buffer dielectric layer 302 are patterned to form channel openings 325 that expose the top surface of the substrate 300. The channel openings 325 are formed by patterning the flat portions of the insulation layers 320 and 320U and the flat portions of the conductive layers 310L, 310 and 310U. The channel openings 325 are formed by an anisotropic etching process. The channel openings 325 are formed to have a hole shape. The channel openings 325 are formed to be spaced apart from each other. The channel openings 325 are two-dimensionally arrayed along the first and second directions. The channel openings 325 have a circular, oval or polygonal shape in a plan view.

A data storage layer 330 is formed to conformally cover sidewalls of the channel openings 325. The data storage layer 330 is formed by forming a preliminary data storage layer covering the sidewalls and bottoms of the channel openings 325, forming spacers on respective ones of inner sidewalls of the preliminary data storage layer in the channel openings 325, and etching the preliminary data storage layer using the spacers as etch stoppers to expose the bottoms of the channel openings 325. The spacers are formed by conformally forming a spacer layer on the preliminary data storage layer 325, and ansotropically etching the spacer layer. The spacer layer is formed of a semiconductor layer. The preliminary data storage layer is formed by sequentially stacking the blocking layer 330a, the charge storage layer 330b and the tunnel insulation layer 330c described with reference to FIG. 13.

Semiconductor pillars 336 are formed to fill respective ones of inner spaces surrounded by the spacers in the channel openings 325. The semiconductor pillars 336 are formed by forming semiconductor portions 332 filling the inner space and implanting dopants of the second conductivity type into upper portions of the semiconductor portions 332 to form drain regions 334.

Referring to FIG. 14C, the pattern structure 304, the insulation layers 320 and 320U and the conductive layers 310L, 310 and 310U are patterned to form a main trench 340 and sub-trenches 342. A length of the main-trench 320 in the first direction is greater than lengths of the sub-trenches 342 in the first direction. The main-trench 340 and the sub-trenches 342 are formed by an anisotropic etching process, for example, an anisotropic dry etching process. In the event that the semiconductor pillars 336 one-dimensionally arrayed along the first direction constitute a single row, the main trench 340 is disposed between the two rows adjacent to each other. According to an embodiment, the main trench 340 is formed across the first and second regions 10 and 20, and the sub-trenches 342 are formed in first region 10.

At least two separate preliminary stack structures are defined by the main trench 340. Each of the preliminary stack structures includes preliminary conductive patterns 310La, 310a and 310Ua and insulation patterns 320a and 320Ua which are alternately and repeatedly stacked. The main trench 340 extends in the first direction, and the preliminary stack structures are symmetrical to each other with respect to the main trench 140. In each of the preliminary stack structures, each of the preliminary conductive patterns 310La, 310a and 310Ua and the insulation patterns 320a includes a flat portion parallel with the top surface of the substrate 300 and a sidewall portion upwardly extending from an end of the flat portion.

Each of sidewall portions of the preliminary conductive patterns 310La, 310a and 310Ua, which is adjacent to the main trench 340, includes a first portion C1 extending in the first direction and a second portion C2 extending in the second direction. In a plan view, each of top surfaces of the first portions C1 has substantially a rectangular shape having two long sides parallel with the first direction. A length of each of the long sides of the top surfaces of the first portions C1 is greater than distances between the top surfaces of the first portions C1 adjacent to each other.

Sidewalls of the preliminary conductive patterns 310La, 310a and 310Ua and the insulation patterns 320a and 320Ua are exposed by the main trench 340 and the sub-trenches 342. Before the main trench 340 and the sub-trenches 342 are formed, a capping insulation layer (not shown) is formed to cover the conductive layers 310L, 310 and 310U and the insulation layers 320 and 320U.

Referring to FIG. 14D, by a selective etching process, the preliminary conductive patterns 310La, 310a and 310Ua are partially etched to form recessed regions 345L, 345 and 345U. Even after the selective etching process, at least the first portions Cl of the preliminary conductive patterns 310La, 310a and 310Ua, which are adjacent to the main trench 340, remain. The preliminary conductive patterns 310La and 310a under the uppermost preliminary conductive pattern 310Ua include the conductive patterns CPa, the pad patterns PPa and the auxiliary pad patterns APPa described with reference to FIGS. 11, 12A and 12B. The uppermost preliminary conductive pattern 310Ua is defined as a preliminary string selection line 314.

According to an embodiment, the selective etching process is performed by an isotropic etching technique. The selective etching process is performed by a wet etching technique and/or an isotropic dry etching technique. When the preliminary conductive patterns 310La, 310a and 310Ua and the insulation patterns 320a and 320Ua are exposed to the selective etching process, an etch rate of the preliminary conductive patterns 310La, 310a and 310Ua is greater than an etch rate of the insulation patterns 320a and 320Ua. Thus, even after the selective etching process is performed, the insulation patterns 320a and 32Ua remain. After the selective etching process, the semiconductor pillars 336 are covered with the data storage layer 330 without exposure.

Referring to FIG. 14E, the main trench 340, the sub-trenches 342 and the recessed regions 345L, 345 and 345U are filled with an insulation material. The main trench 340 and the recessed regions 345L, 345 and 345U spatially connected to the main trench 340 are filled with a main isolation pattern 350. The sub-trenches 342 and the recessed regions 345L, 345 and 345U spatially connected to the sub-trenches 342 are filled with sub-isolation patterns 352. The main isolation pattern 350 and the sub-isolation patterns 352 are formed of a silicon oxide layer.

Referring to FIG. 14F, the preliminary string selection line 314 and the uppermost insulation pattern 320Ua in each of the preliminary stack structures are patterned to form a plurality of string selection lines 315 extending in the first direction. In each of the preliminary stack structure, an insulation material 354 is disposed between the string selection lines 315 spaced apart from each other in the second direction. Thus, the stacked conductive patterns CPa, the string selection lines 315 on the stacked conductive patterns CPa, and the insulation patterns 320a and 320Ua between the stacked conductive patterns CPa and the string selection lines 315 constitute a single stack structure.

Subsequently, referring again to FIGS. 11, 12A and 12B, bit lines 360 are formed on the stack structures. The bit lines 360 are electrically connected to the drain regions 334 and extend in the second direction. The number of the bit line 360 is two or more. Each of the bit lines 360 is electrically connected to the plurality of drain regions 334 of the semiconductor pillars 336 which are one-dimensionally arrayed in the second direction to constitute a column.

An interlayer insulation layer 362 is formed on the stack structures and the bit lines 360. The interlayer insulation layer 362 is formed of a silicon oxide layer. Contact holes are formed to penetrate the interlayer insulation layer 362 and to expose the first portions SP1 of the landing sidewall portions LSPa of the pad patterns PPa, and cell contact plugs 364 are formed to fill the contact holes. Conductive interconnection lines 370 are formed on the interlayer insulation layer 362 in the first region 10. The conductive interconnection lines 370 are electrically connected to the cell contact plugs 364.

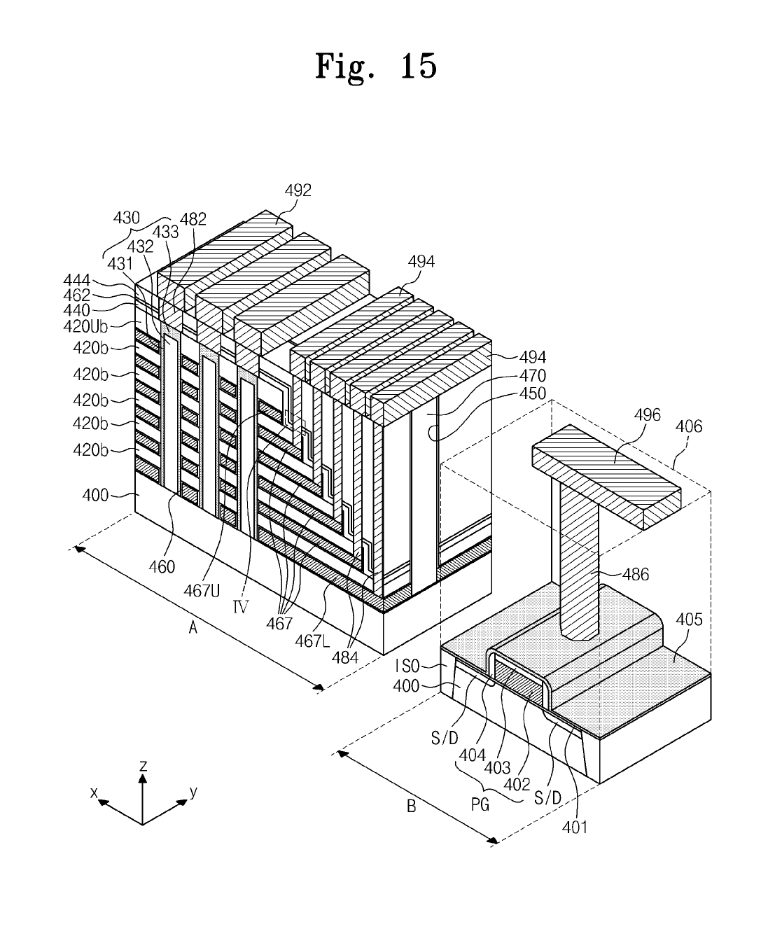

A semiconductor device according to an exemplary embodiment is now described. FIG. 15 is a perspective view illustrating a semiconductor device according to an exemplary embodiment.

Referring to FIG. 15, a substrate 400 includes a cell region A and a peripheral region B. Cells are three-dimensionally arrayed in the cell region A, and a peripheral circuit is formed in the peripheral region B. The substrate 400 includes a semiconductor substrate.

Conductive patterns 467L, 467 and 467U and insulation patterns 420b and 420Ub are alternately and repeatedly stacked on the substrate 100 in the cell region A. The conductive patterns 467L, 467 and 467U and the insulation patterns 420b and 420Ub, which are alternately stacked, constitute a stack structure. In an embodiment, a plurality of stack structures are provided on the substrate 400. Each of the stack structures extends in a first direction parallel with a top surface of the substrate 400. The stack structures are spaced apart from each other in a second direction. The first direction and the second direction are parallel with the top surface of the substrate 400 and intersect each other. The first direction is an x-axis direction and the second direction is a y-axis direction.

Semiconductor pillars 430 penetrate the conductive patterns 467L, 467 and 467U and the insulation patterns 420b and 420Ub which are alternately and repeatedly stacked. The semiconductor pillars 430 extend in a third direction perpendicular to the substrate 400. The third direction is a z-axis direction. The semiconductor pillars 430 contact the substrate 400. The number of the semiconductor pillars 430 is two or more. The plurality of semiconductor pillars 430 are two-dimensionally arrayed in the first and second directions in a plan view. The semiconductor pillars 430 penetrate the stack structures. The semiconductor pillars 430 penetrating the stack structures are spaced apart from each other. Each of the semiconductor pillars 430 includes a semiconductor portion 431 covering a sidewall of a channel opening 425 that penetrate the stack structure, a filling insulation material 432 filling a region surrounded by the semiconductor portion 431, and a drain region 433 filling an upper region of the channel opening 425. The semiconductor portion 431 and the drain region 433 include a single crystalline semiconductor or a polycrystalline semiconductor. When the substrate 400 has a first conductivity type, the drain region 433 is an impurity region that is doped with dopants of a second conductivity type different from the first conductivity type.

A data storage layer 460 is disposed between the semiconductor pillars 430 and the conductive patterns 467L, 467 and 467U. The data storage layer 460 is a multi-layered film including the tunnel insulation layer 150a, the charge storage layer 150b and the blocking layer 150c as described with reference to FIG. 3.

An isolation pattern 470 including an insulation material is disposed between the plurality of stack structures. A common source region is disposed in the substrate 400 under the isolation pattern 470 between the stack structures. The common source region has a line shape extending in the first direction. The common source region is an impurity region that is doped with dopants of the second conductivity type. An electrical bias applied to the lowermost conductive pattern 467L controls electrical connections between the common source region and the semiconductor pillars 430 in each of the stack structures.

The conductive patterns 467L, 467 and 467U and the insulation patterns 420b, 420Ub are stacked to have a step structure. For example, a conductive pattern located at a relatively lower level extends in the first direction to be longer than a conductive pattern located at a relatively higher level. Similarly, an insulation pattern located at a relatively lower level extends in the first direction to be longer than an insulation pattern located at a relatively higher level. A conductive pattern located at a relatively lower level includes a portion that does not overlap a conductive pattern located at a relatively higher level, and an insulation pattern located at a relatively lower level includes a portion that does not overlap an insulation pattern located at a relatively higher level.

Each of the conductive patterns 467L and 467 under the uppermost conductive pattern 467U includes a contact extension that is not covered with the conductive pattern disposed thereon.

Each of the conductive patterns 467L, 467 and 467U includes at least one of metal (e.g., tungsten, aluminum, titanium, tantalum or the like), conductive metal nitride (e.g., titanium nitride, tantalum nitride or the like) and doped semiconductor (e.g., doped silicon, doped germanium, doped silicon-germanium or the like). Each of the insulation patterns 420b and 420Ub includes silicon oxide, silicon nitride and/or silicon oxynitride.

A capping insulation layer 440, a barrier layer 462 and an interlayer insulation layer 444 are sequentially stacked on the stack structures including the conductive patterns 467L, 467 and 467U and the insulation patterns 420b and 420Ub which are stacked to have a step structure. The capping insulation layer 440 and the barrier layer 462 conformally cover the conductive patterns 467L, 467 and 467U and the insulation patterns 420b and 420Ub having a step structure. Therefore, the capping insulation layer 440 and the barrier layer 462 also have a step structure in a vertical cross sectional view taken along the first direction. The interlayer insulation layer 444 has a top surface parallel with the top surface of the substrate 100.

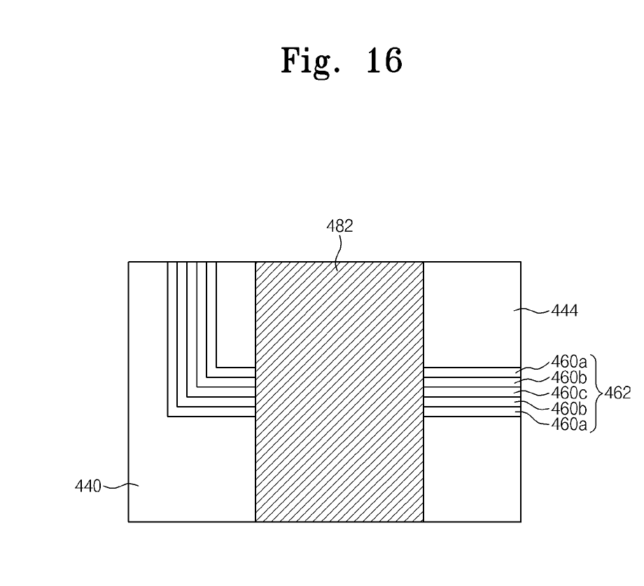

The barrier layer 462 includes the same material as the data storage layer 460. The barrier layer 462 is described in detail with reference to FIG. 16. FIG. 16 is an enlarged view illustrating a portion ‘IV’ of FIG. 15 to describe the barrier layer included in a semiconductor device according to an exemplary embodiment.

Referring to FIG. 16, the barrier layer 462 includes a tunnel insulation layer 460a, a charge storage layer 460b, a blocking layer 460c, a charge storage layer 460b and a tunnel insulation layer 460a which are sequentially stacked on the capping insulation layer 440. The tunnel insulation layer 460a, the charge storage layer 460b and the blocking layer 460c include the same materials as the tunnel insulation layer 150a, the charge storage layer 150b and the blocking layer 150c, respectively, which are described with reference to FIG. 3.

Referring again to FIG. 15, bit line contact plugs 482 are formed to penetrate the interlayer insulation layer 444, the barrier layer 462 and the capping insulation layer 440. The bit line contact plugs 482 are connected to respective ones of the drain regions 433. Bit lines 492 extending in the second direction are disposed on the interlayer insulation layer 444. The bit lines 492 are connected to the bit line contact plugs 482. Each of the bit lines 492 is electrically connected to the drain regions 433 of the plurality of semiconductor pillars 430 which are arrayed in the second direction to constitute a single column.

Cell contact plugs 482 penetrate the interlayer insulation layer 444, the barrier layer 462, the capping insulation layer 440, the insulation patterns 420b and the data storage layer 460. The cell contact plugs 482 are connected to the conductive patterns 467L and 467. The cell contact plug 484 connected to the conductive pattern located at a relatively lower level has a greater length in the third direction than the cell contact plug 484 connected to the conductive pattern located at a relatively higher level. Conductive interconnection lines 494 connected to the cell contact plugs 484 are provided.

A peripheral isolation pattern ISO is disposed in the substrate 400 of the peripheral region B to define a peripheral active region in the peripheral region B. The peripheral active region is a portion of the substrate 400, which is surrounded by the peripheral isolation pattern ISO. The peripheral active region includes a channel region, and a channel is formed in the channel region while a semiconductor device operates.

A peripheral gate insulation layer 401 is disposed on the peripheral active region. The peripheral gate insulation layer 401 includes a silicon oxide layer. A peripheral gate pattern PG is disposed on the peripheral gate insulation layer 401. The peripheral gate pattern PG includes a peripheral gate electrode 402 on the peripheral gate insulation layer 401, a peripheral gate gapping pattern 403 on the peripheral gate electrode 402, and a peripheral spacer 404 on two sidewalls of the peripheral gate electrode 402. Peripheral source/drain regions S/D are disposed in the peripheral active region at two sides of the peripheral gate pattern PG. The peripheral source/drain regions S/D are doped with dopants of the second conductivity type.

A peripheral etch stop layer 405 and a peripheral interlayer insulation layer 406 are sequentially stacked on the peripheral gate pattern PG. The peripheral etch stop layer 405 is formed of a different material from the peripheral interlayer insulation layer 406. For example, the peripheral etch stop layer 405 includes a silicon nitride layer, and the peripheral interlayer insulation layer 406 includes a silicon oxide layer.

A peripheral contact plug 486 penetrates the peripheral etch stop layer 405 and the peripheral interlayer insulation layer 406 on the peripheral gate pattern PG. The peripheral contact plug 486 is connected to the peripheral gate electrode 402 of the peripheral gate pattern PG. A peripheral conductive interconnection line 496 is disposed on the peripheral interlayer insulation layer 406 and is connected to the peripheral contact plug 486.

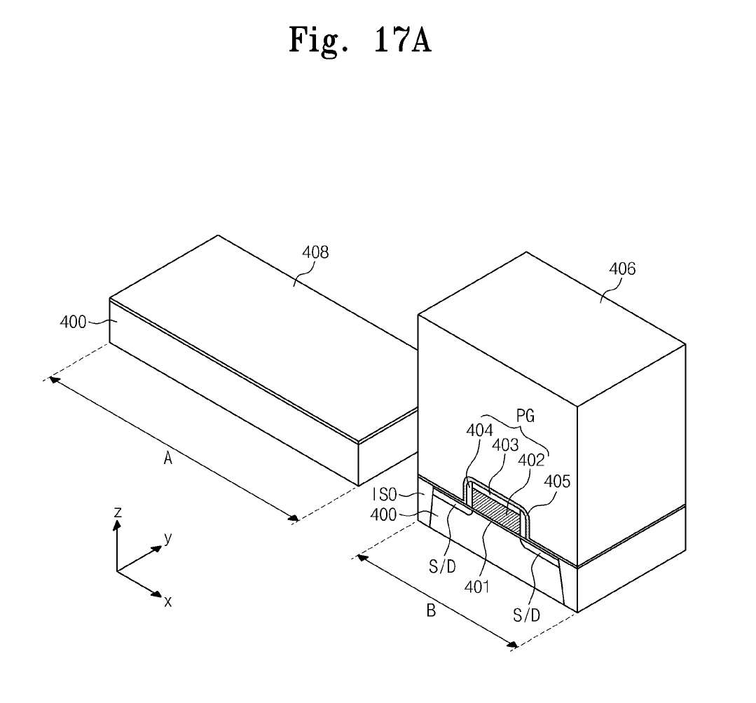

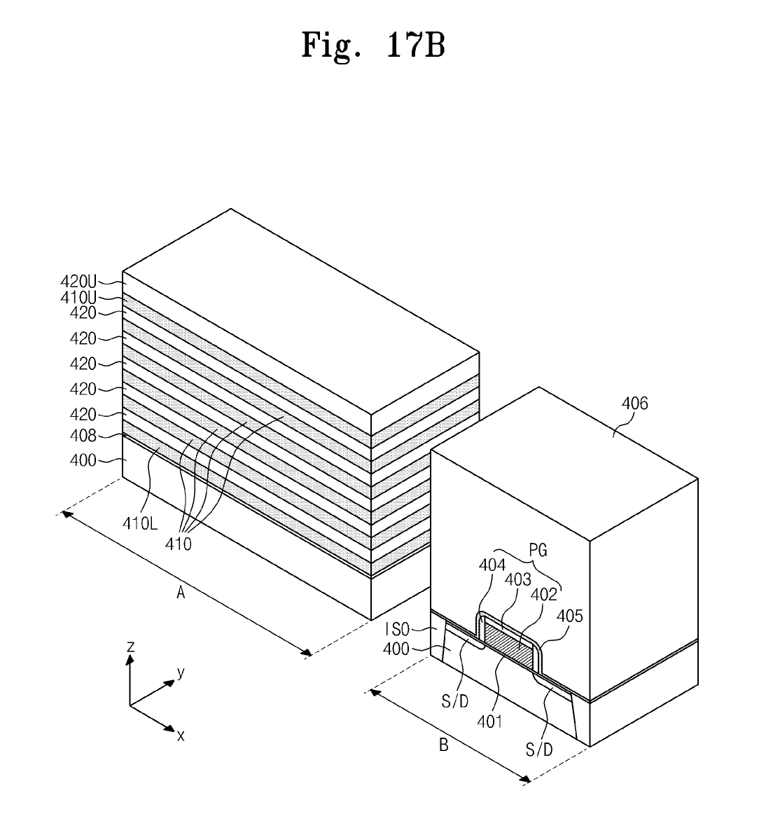

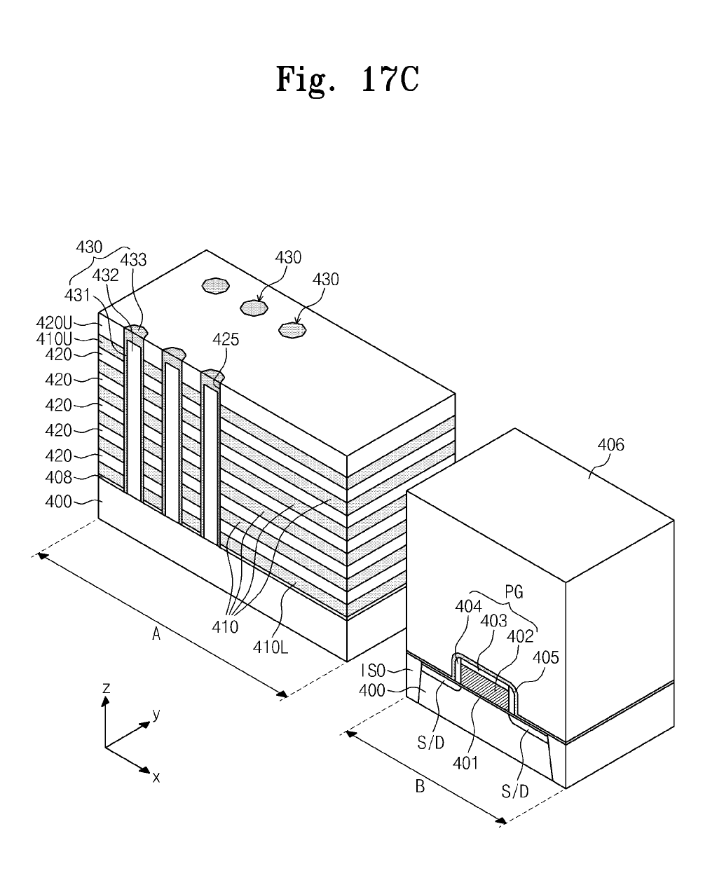

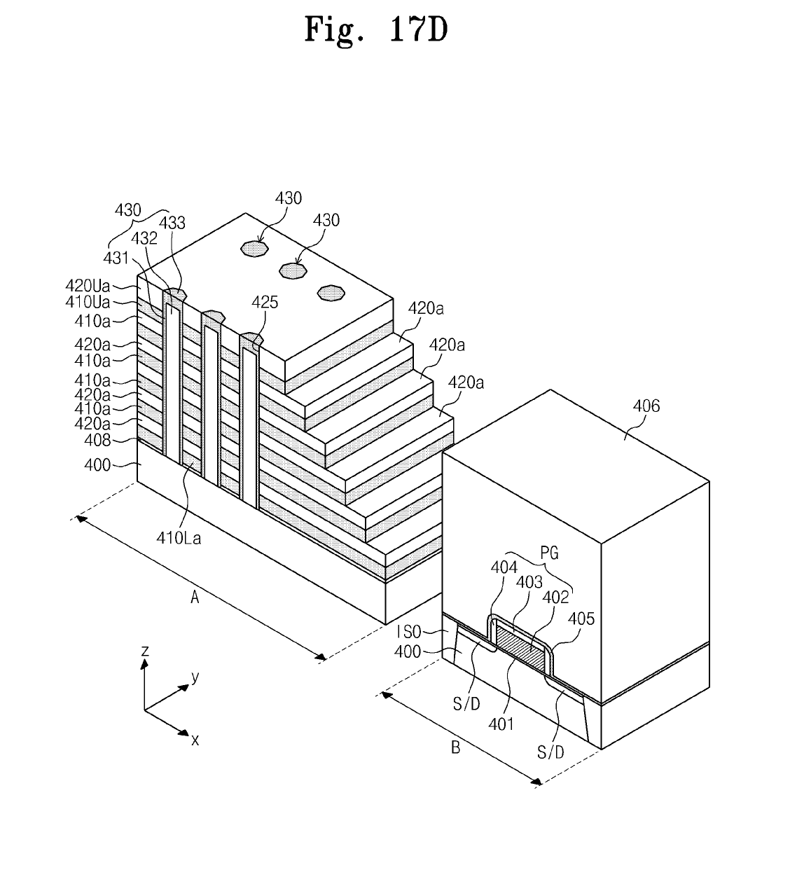

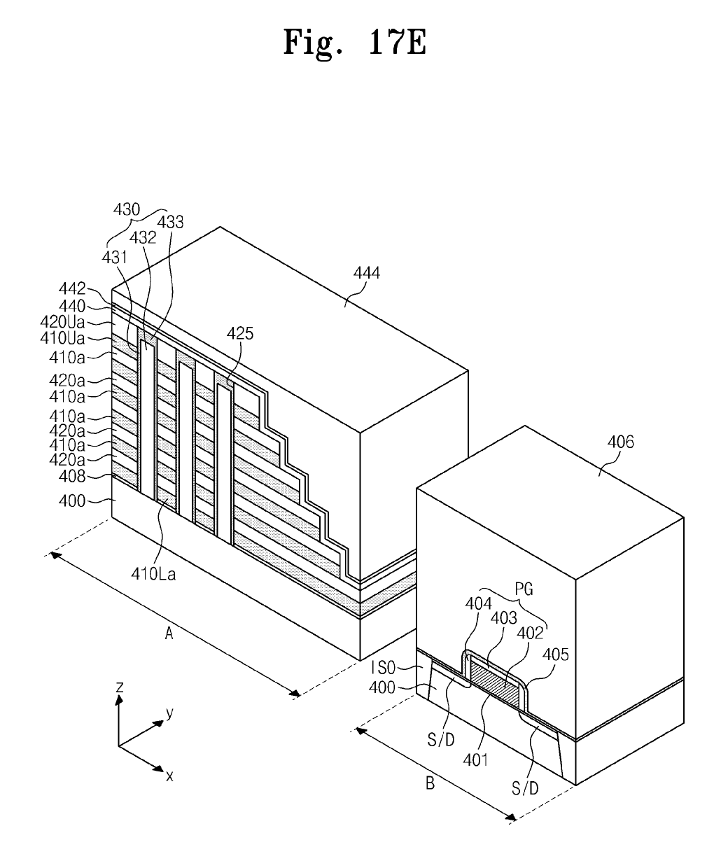

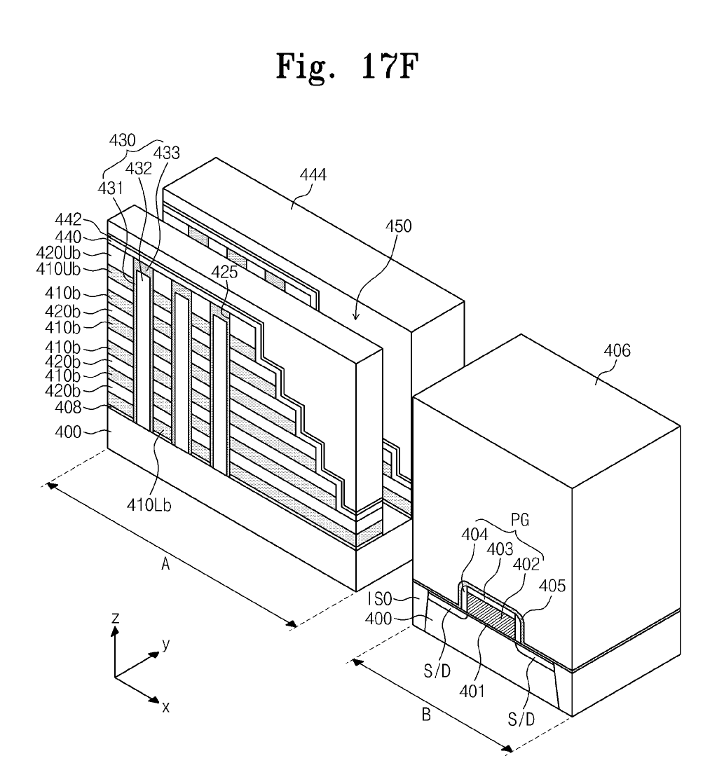

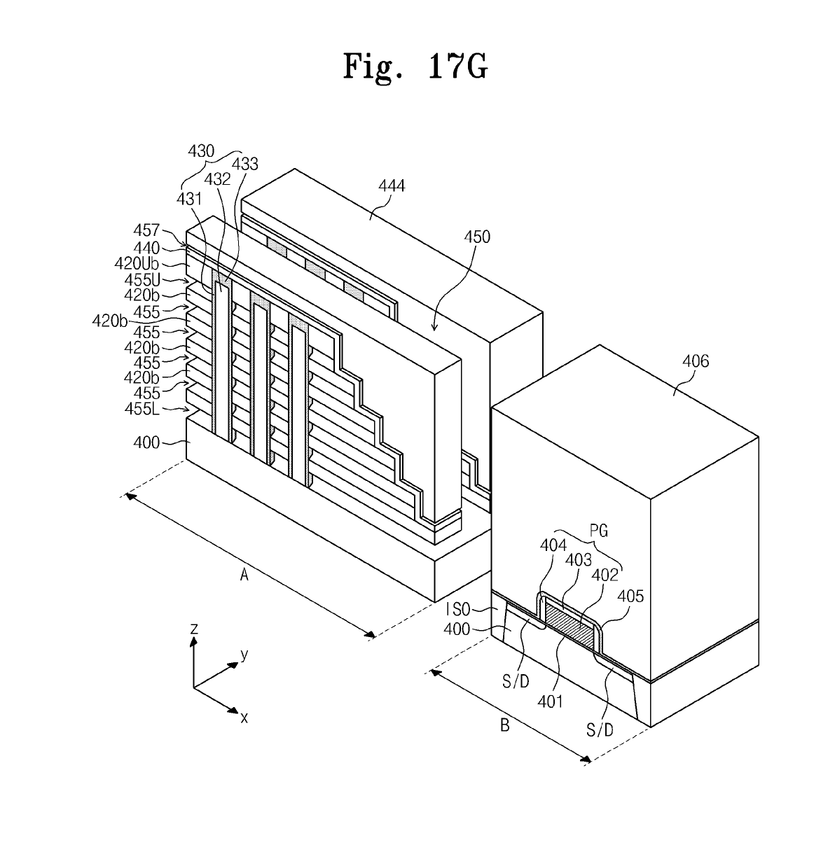

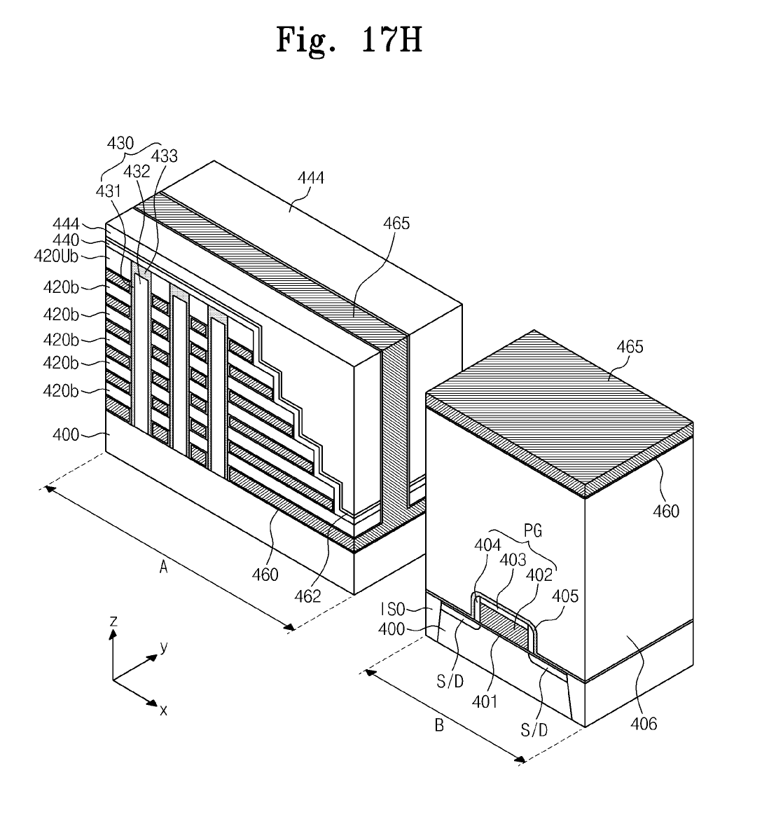

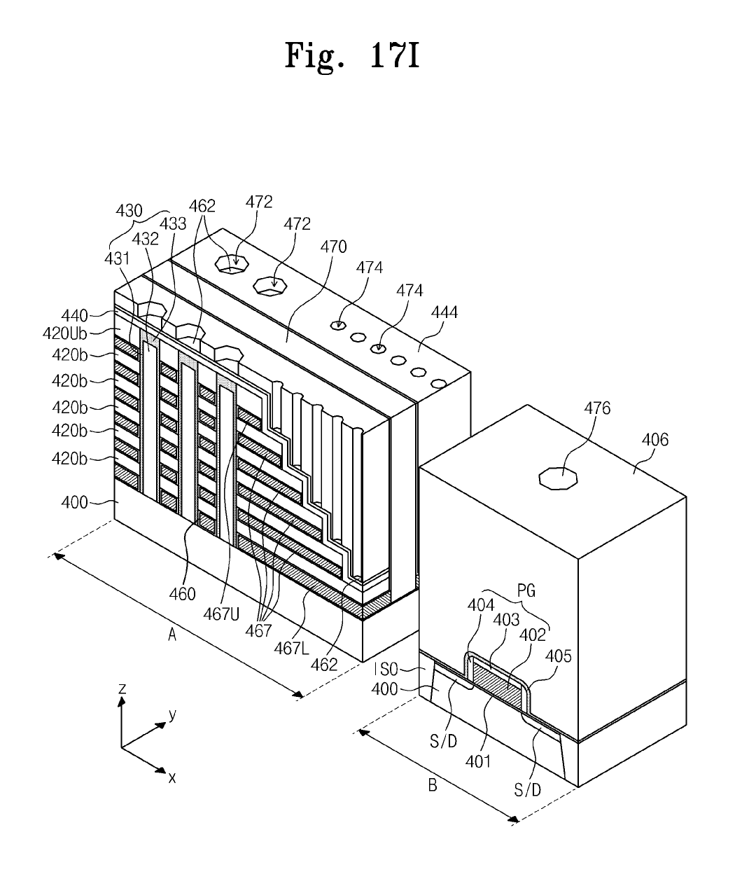

A method of fabricating a semiconductor device according to an exemplary embodiment will be described hereinafter. FIGS. 17A to 17G are perspective views illustrating a method of fabricating a semiconductor device according to an exemplary embodiment.

Referring to FIG. 17A, a substrate 400 including a cell region A and a peripheral region B spaced apart from each other is provided. A peripheral isolation pattern ISO is formed in the substrate 400 of the peripheral region B and defines a peripheral active region. The peripheral isolation pattern ISO is formed by etching the substrate 400 to form a trench and filling the trench with an insulation material. A peripheral gate insulation layer 401 is formed on the peripheral active region. For example, the peripheral gate insulation layer 401 is formed of a silicon oxide layer by a thermal oxidation process. A peripheral gate pattern PG is formed on the peripheral gate insulation layer 401. The peripheral gate pattern PG includes a peripheral gate electrode 402, a peripheral gate capping pattern 403 and a peripheral spacer 404. A peripheral etch stop layer 405 and a peripheral interlayer insulation layer 406 are sequentially formed on the peripheral gate pattern PG. The peripheral etch stop layer 405 and the peripheral interlayer insulation layer 406 are formed in the peripheral region B.

A buffer dielectric layer 408 is formed on the substrate 400 in the cell region A. The buffer dielectric layer 408 is formed of a silicon oxide layer by a thermal oxidation process.

Referring to FIG. 17B, first material layers and second material layers different from the first material layers are alternately and repeatedly stacked on the substrate 400 in the cell region A. The first material layers are sacrificial layers 410L, 410 and 410U, and the second material layers are insulation layers 420 and 420U. The sacrificial layers 410L, 410 and 410U and the insulation layers 420 and 420U are the same materials as the sacrificial layers 110L and 110 and the insulation layers 120, respectively, described with reference to FIG. 4B.

The sacrificial layers 410L, 410 and 410U are formed to have the same thickness. Alternatively, the lowermost sacrificial layer 410L and the uppermost sacrificial layer 410U are formed to be thicker than the sacrificial layers 410 between the lowermost and uppermost sacrificial layers 410L and 410U. According to an embodiment, the sacrificial layers 410 between the lowermost sacrificial layer 410L and the uppermost sacrificial layer 410U are formed to have the same thickness. The uppermost insulation layer 420U is formed to be thicker than the insulation layers 420 under the uppermost insulation layer 420U. The insulation layers 420 under the uppermost insulation layer 420U are formed to have the same thickness.

After formation of the sacrificial layers 410L, 410 and 410U and the insulation layers 420 and 420U, the sacrificial layers 410L, 410 and 410U and the insulation layers 420 and 420U are planarized using the peripheral interlayer insulation layer 406 as an etch stop layer.

Referring to FIG. 17C, after planarization of the sacrificial layers 410L, 410 and 410U and the insulation layers 420 and 420U, the sacrificial layers 410L, 410 and 410U and the insulation layers 420 and 420U in the cell region A are patterned to form channel openings 425 exposing the top surface of the substrate 400. The channel openings 425 are formed in the same manner as described with reference to FIG. 4C. Semiconductor pillars 430 are formed to fill respective ones of the channel openings 425. Each of the semiconductor pillars 430 includes a semiconductor portion 431 covering a sidewall of the channel opening 425, a filling insulation material 432 filling a region surrounded by the semiconductor portion 431, and a drain region 433 filling an upper portion of the channel opening 425. The semiconductor portion 431 and the drain region 433 include a single crystalline semiconductor or a polycrystalline semiconductor. When the substrate 400 has a first conductivity type, the drain region 433 is an impurity region that is doped with dopants of a second-type different from the first conductivity type.

Referring to FIG. 17D, the sacrificial layers 410L, 410 and 410U and the insulation layers 420 and 420U are patterned to form sacrificial patterns 410La, 410a and 410Ua and insulation patterns 420a and 420Ua having a step structure. For example, a conductive pattern located at a relatively lower level is formed to extend in the first direction to be longer than a conductive pattern located at a relatively higher level, and an insulation pattern located at a relatively lower level is formed to extend in the first direction to be longer than an insulation pattern located at a relatively higher level. As a result, a top surface of an end portion of each of the insulation patterns 420a and a sidewall of an end portion of each of the sacrificial patterns 410La, 410a and 410Ua are exposed.

Referring to FIG. 17E, a capping insulation layer 440, an additional sacrificial layer 442 and an interlayer insulation layer 444 are sequentially formed on the sacrificial patterns 410La, 410a and 410Ua and the insulation patterns 420a and 420Ua having a step structure, and then the interlayer insulation layer 444 is planarized using the peripheral interlayer insulation layer 406 as an etch stop layer. The additional sacrificial layer 442 includes a material having an etch selectivity with respect to the capping insulation layer 440 and the interlayer insulation layer 444. For example, when the capping insulation layer 440 and the interlayer insulation layer 444 are formed of a silicon oxide layer, the additional sacrificial layer 442 is formed of a silicon nitride layer or a silicon oxynitride layer.

Referring to FIG. 17F, the interlayer insulation layer 444, the additional sacrificial layer 442, the capping insulation layer 440, the sacrificial patterns 410La, 410a and 410Ua and the insulation patterns 420a and 420Ua are patterned to form a trench 450 exposing the top surface of the substrate 100. The trench 450 extends in the first direction. After formation of the trench 450, the sacrificial patterns 410Lb, 410b and 410Ub and the insulation patterns 420b and 420Ub are formed to have a line shape extending in the first direction.

The semiconductor pillars 430 one-dimensionally arrayed in the first direction constitute a single row, and the semiconductor pillars 430 one-dimensionally arrayed in the second direction constitute a single column. The semiconductor pillars 430 are two-dimensionally arrayed along the rows and columns on the substrate 400 when viewed from a plan view. According to an embodiment, the trench 450 is disposed between the two adjacent rows. The plurality of semiconductor pillars 430 arrayed in one row penetrate a single stack structure including the sacrificial patterns 410Lb, 410b and 410Ub and the insulation patterns 420b and 420Ub alternately and repeatedly stacked.

Referring to FIG. 17G, the sacrificial patterns 410Lb, 410b and 410Ub and the additional sacrificial layer 442 exposed by the trench 450 are removed using a selective etching process, thus forming recessed regions 455L, 455 and 455U and an additional recessed region 457 in each of the stack structures. The recessed regions 455L, 455 and 455U are spaces which are provided by removal of the sacrificial patterns 410Lb, 410b and 410Ub. Thus, a recessed region positioned at a relatively lower level has a greater length in the first direction than a recessed region positioned at a relatively higher level. The additional recessed region 457 is a space which is provided by removal of the additional sacrificial pattern 442.

According to an embodiment, the selective etching process includes an isotropic etching process. The selective etching process is performed by a wet etching and/or an isotropic dry etching process. According to an embodiment, when the sacrificial patterns 410Lb, 410b and 410Ub, the insulation patterns 420b and 420Ub, and the semiconductor pillars 430 are exposed to the selective etching process, an etch rate of the sacrificial patterns 410Lb, 410b and 410Ub is greater than etch rates of the insulation patterns 420b and 420Ub and the semiconductor pillars 430. Thus, even after the selective etching process is performed, the insulation patterns 420b and 420Ub and the semiconductor pillars 430 remain. After the selective etching process, according to an embodiment, the recessed regions 455L, 455 and 455U expose some portions of each of the sidewalls of the semiconductor pillars 430, which contact the sacrificial patterns 410Lb, 410b and 410Ub. In the event that the buffer dielectric layer 408 is thinner than the insulation patterns 420b and 420Ub, the buffer dielectric layer 408 is removed during the selective etching process.

Referring to FIG. 17H, a data storage layer 460 is formed on the substrate including the recessed regions 455L, 455 and 455U. The data storage layer 460 is formed to substantially a uniform thickness along inner surfaces of the recessed regions 455L, 455 and 455U. The data storage layer 460 is conformally formed in the recessed regions 455L, 455 and 455U. Forming the data storage layer 460 includes sequentially forming the tunnel insulation layer 150a, the charge storage layer 150b and the blocking layer 150c which are described with reference to FIG. 3.

The data storage layer 460 is formed in the additional recessed region 457 to form a barrier layer 462. The barrier layer 462 is formed of a multi-layered film including a tunnel insulation layer 460a, a charge storage layer 460b and a blocking layer 460c, as described with reference to FIG. 16.

After the data storage layer 460 is formed, a gate conductive layer 465 is formed on the substrate including the data storage layer 460. The gate conductive layer 465 fills the recessed regions 455L, 455 and 455U. The gate conductive layer 465 partially or fully fills the trench 450. The gate conductive layer 465 is electrically insulated from the semiconductor pillars 430 and the substrate 400 by the data storage layer 460. The gate conductive layer 465 is formed in the same manner as described with reference to FIG. 4G.

Referring to FIG. 17I, the gate conductive layer 465 positioned outside the recessed regions 455L, 455 and 455U is removed to form conductive patterns 467L, 467 and 467U in the recessed regions 455L, 455 and 455U. The gate conductive layer 465 positioned outside the recessed regions 455L 455 and 455U is selectively removed using a wet etching process and/or a dry etching process.

The conductive patterns 467L, 467 and 467U and the insulation patterns 420b and 420Ub, which are alternately stacked at a side of the trench 450, constitute a single stack structure. The conductive patterns 467L, 467 and 467U correspond to some portions of the gate conductive layer 465, which are positioned in the recessed regions 455L, 455 and 455U. The lowermost conductive pattern 467L corresponds to a gate of a lower selection transistor, and the uppermost conductive pattern 467U corresponds to a gate of an upper selection transistor. The conductive patterns 467 between the lowermost conductive pattern 467L and the uppermost conductive pattern 467U correspond to control gates of memory cells.

A common source region is formed in the substrate 400 under the trench 450. The common source region is formed in the same manner as described with reference to FIG. 4I.

During formation of the conductive patterns 467L, 467 and 467U, the gate conductive layer 465 in the trench 450 is removed. Thus, after the common source region is formed, an isolation pattern 470 is formed to fill the trench 450. Forming the isolation pattern 470 includes forming an isolation layer on the substrate including the common source region and planarizing the isolation layer using the interlayer insulation layer 444 as an etch stop layer. The isolation pattern 470 includes the same material as the isolation patterns 160 and 162 described with reference to FIG. 4I.

A peripheral contact hole 476, preliminary cell contact holes 474 and preliminary bit line contact holes 472 are formed. The peripheral contact hole 476 is formed to penetrate the peripheral interlayer insulation layer 406 and the peripheral etch stop layer 405 on the peripheral gate pattern PG, and the preliminary bit line contact holes 472 and the preliminary cell contact holes 474 are formed to penetrate the interlayer insulation layer 444 in the cell region A. The peripheral contact hole 476 exposes the peripheral gate electrode 402, the preliminary cell contact holes 474 expose the barrier layer 462 on the contact extensions of the conductive patterns 467L and 467, and the preliminary bit line contact holes 472 expose the barrier layer 462 on the drain regions 433 of the semiconductor pillars 430.

A depth of the preliminary cell contact hole 474 for exposing the contact extension of the conductive pattern located at a relatively lower level is greater than a depth of the preliminary cell contact hole 474 for exposing the contact extension of the conductive pattern located at a relatively higher level.

When contact holes exposing the contact extensions of the conductive patterns 467L and 467, the drain regions 433 of the semiconductor pillars 430 and the peripheral gate electrode 102 are formed without formation of the barrier layer 462, the drain regions 433 is over-etched due to a depth difference between the contact holes, thus degrading the reliability of a semiconductor device.

However, according to an embodiment, the barrier layer 462 is formed of a material different from the layers 406 and 444. Thus, the barrier layer 462 can prevent the drain regions 433 from being over-etched while the preliminary contact holes 472 and 474 are formed. As a result, a high reliable semiconductor device is realized.

Subsequently, referring again to FIG. 15, the barrier layer 462, the capping insulation layer 440, the insulation patterns 420b and the information storage layer 460 are patterned to form cell contact holes exposing the contact extensions of the conductive patterns 467L and 467 and to form bit lines contact holes exposing the drain regions 433. Cell contact plugs 484 and bit line contact plugs 482 are formed to fill the cell contact holes and the bit line contact holes, respectively. Further, a peripheral contact plug 486 is formed to fill the peripheral contact hole 476.

Conductive interconnection lines 494 and bit lines 492 are formed on the interlayer insulation layer 444, and a peripheral conductive interconnection line 496 is formed on the peripheral interlayer insulation layer 406. The conductive interconnection lines 494 are connected to the cell contact plugs 484, and the bit lines 492 are connected to the bit line contact plugs 482. The peripheral conductive interconnection line 496 is connected to the peripheral contact plug 486.

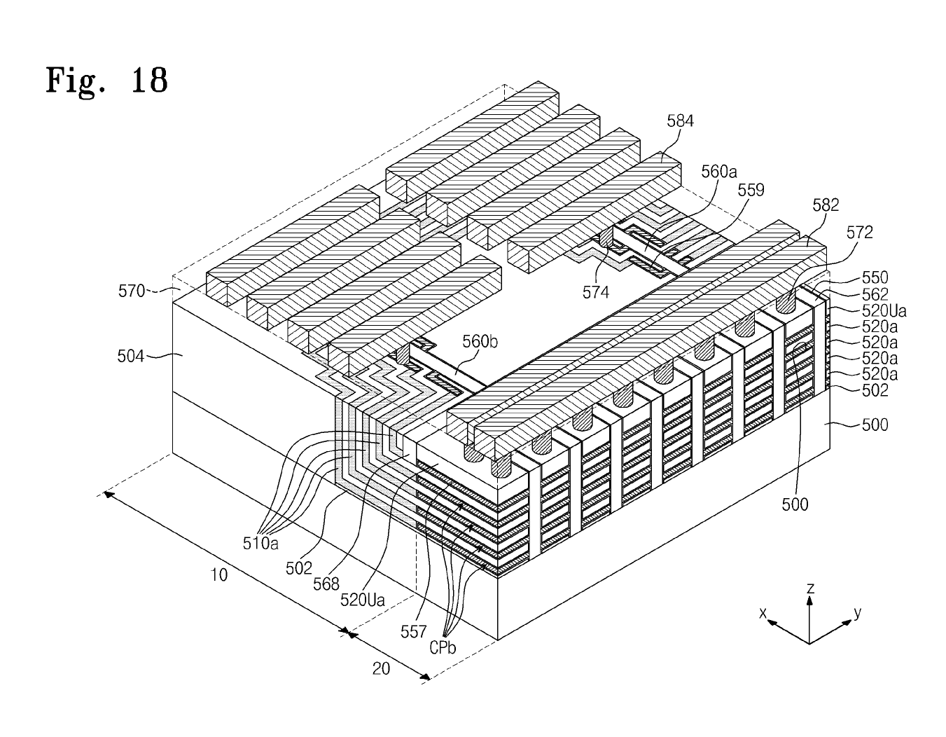

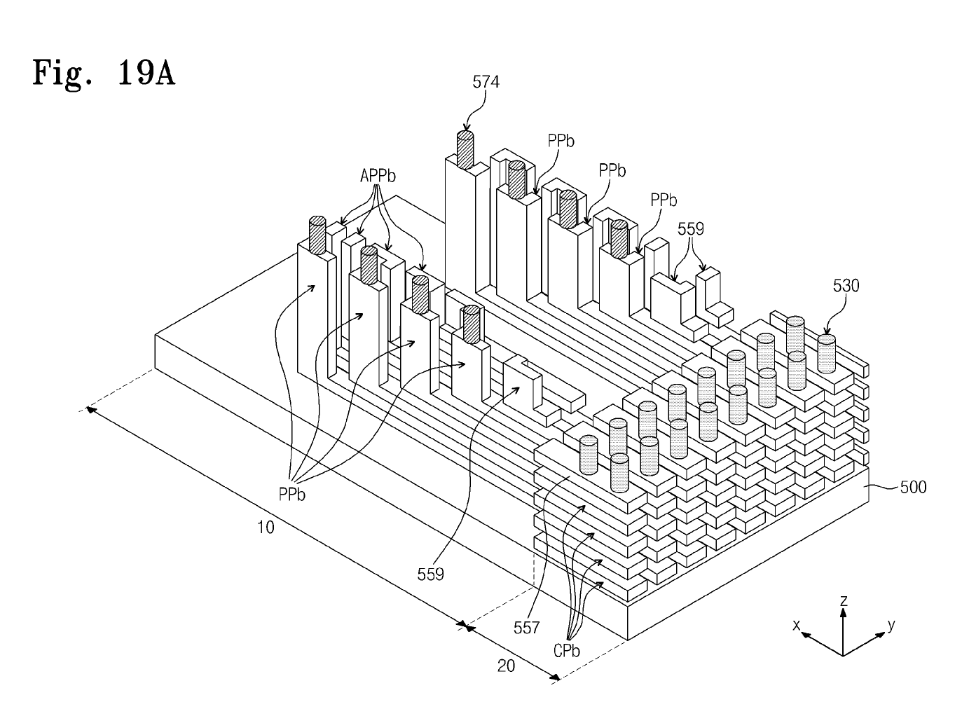

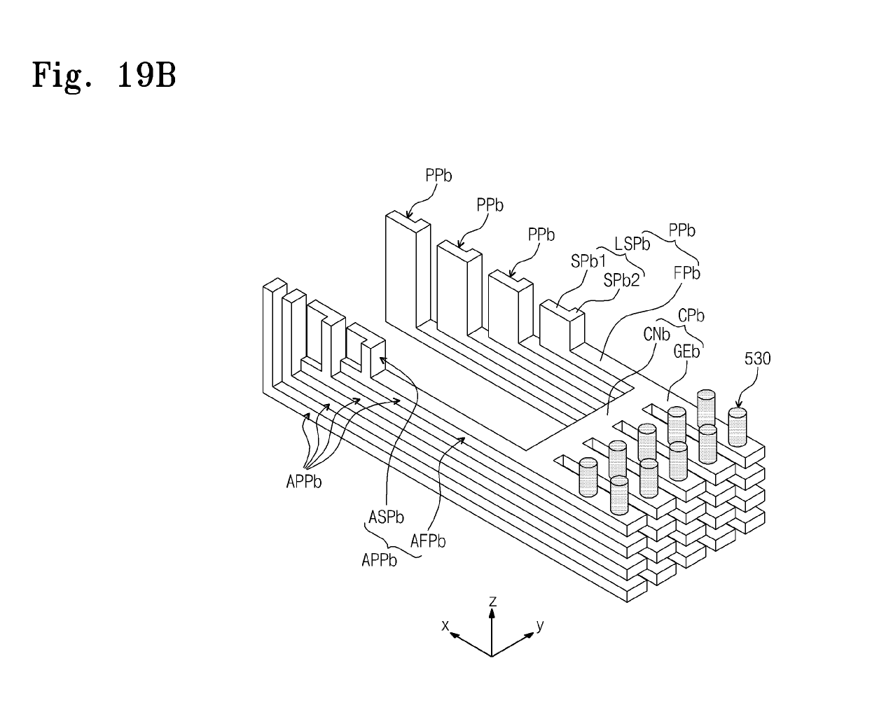

A semiconductor device according to an exemplary embodiment is now described. FIGS. 18, 19A and 19B are perspective views illustrating a semiconductor device according to an exemplary embodiment.

For convenience of description, FIG. 19A illustrates a substrate 500, semiconductor pillars 530, conductive patterns CPb, pad patterns PPb, auxiliary pad patterns APPb, string selection lines 557, floating conductive patterns 559 and cell contact plugs 574, and FIG. 19B illustrates the semiconductor pillars 530, the conductive patterns CPb, the pad patterns PPb and the auxiliary pad patterns APPb.

Referring to FIGS. 18, 19A and 19B, the substrate 500 includes a first region 10 and a second region 20. The first region 10 is a pad region on which the pad patterns PPb are disposed, and the second region 20 is a cell region on which three-dimensional cells are disposed. The substrate 500 is the same substrate as the substrate 100 described with reference to FIGS. 1, 2A and 2B.

The conductive patterns CPb are vertically stacked on the substrate 300 in the second region 20 and are spaced apart from each other. Each of the conductive patterns CPb includes a plurality of gate electrode GEb and a connector CNb connecting first ends of the gate electrodes GEb to each other. Each of the gate electrodes GEb has a line shape extending in a first direction, and the gate electrodes GEb of each conductive pattern CPb are spaced apart from each other in a second direction. Sub-isolation patterns 562 are disposed between the gate electrodes GEb of each of the conductive patterns CPb. The first and second directions are parallel with a top surface of the substrate 500, and the first direction intersects the second direction. In the drawings, the first and second directions correspond to an x-axis direction and a y-axis direction, respectively.

The pad patterns PPb extend from respective ones of first ends of the connectors CNb in the first direction. Each of the pad patterns PPb includes a flat portion FPb extending from the first end of the connector CNb in the first direction and a landing sidewall portion LSPb upwardly extending from a top surface of the flat portion FPb. The landing sidewall portion LSPb includes a first portion SPb1 extending in the first direction and a second portion SPb2 extending in the second direction. A width of the first portions SPb1 in the first direction is greater than a thickness of the conductive patterns CPb in a third direction. The third direction is perpendicular to the top surface of the substrate 500. The third direction is a z-axis direction. A width of the first portion SPb1 in the second direction is less than a width of the flat portion FPb in the second direction.

The auxiliary pad patterns APPb extend from respective ones of second ends of the connectors CNb in the first direction. The auxiliary pad patterns APPb are spaced apart from the pad patterns PPb. Each of the auxiliary pad patterns APPb includes an auxiliary flat portion AFPb parallel with the substrate 500 and an auxiliary sidewall portion ASPb upwardly extending from an end of the auxiliary flat portion AFPb.

Insulation patterns 520a and 520Ua are disposed in respective ones of spaces between the conductive patterns CPb vertically stacked. The insulation patterns 520a and 520Ua extend and intervene between the pad patterns PPb and between the auxiliary pad patterns APPb.

The string selection lines 557 are disposed directly under the uppermost insulation pattern 520Ua. Each of the string selection lines 557 has a line shape extending in the first direction. The string selection lines 557 are disposed to be spaced apart from each other in the second direction. The string selection lines 557 are disposed to be parallel with the gate electrodes GEb. The number of the string selection lines 557 is equal to the number of the gate electrodes GEb included in each of the conductive patterns CPb.

The stacked conductive patterns CPb, the string selection lines 557 on the stacked conductive patterns CPb, and the insulation patterns 520a and 520Ua between the stacked conductive patterns CPb constitute a single stack structure. In an embodiment, the number of the stack structure is two or more. Each of main isolation patterns 560a and 560b is disposed between the two adjacent stack structures.

The floating conductive patterns 559 are disposed between the string selection lines 557 and the pad patterns PPb and between the string selection lines 557 and the auxiliary pad patterns APPb. The auxiliary pad patterns APPb are electrically insulated from the conductive patterns CPb, the pad patterns PPb, the auxiliary pad patterns APPb and the string selection lines 557. An insulation separating pattern 568 is disposed between the floating conductive patterns 559 and the string selection lines 557. The insulation separating pattern 568 penetrates the uppermost insulation pattern 520Ua and is disposed between uppermost sacrificial pattern 510a and the string selection lines 557.

Sacrificial patterns 510a are disposed between the the pad patterns PPb and the auxiliary pad patterns APPb. At least one of the sacrificial patterns 510a includes a first portion extending in the first direction and a second portion extending in the second direction, when viewed from a plan view.

The semiconductor pillars 530 penetrate the stacked gate electrodes GEb and the insulation patterns 520a and 520Ua. The semiconductor pillars 530 are two-dimensionally arrayed in the first and second directions in a plan view. Each of the semiconductor pillars 530 includes the semiconductor portion 131, the filling insulation material 132 and the drain region 133, as described with reference FIG. 1.

A data storage layer 550 is disposed between the semiconductor pillars 530 and the gate electrodes GEb. The data storage layer 550 includes the tunnel insulation layer 150a, the charge storage layer 150b and the blocking layer 150c, as described with reference to FIG. 3.

Cell contact plugs 574 are provided on respective ones of the first portions SPb1 of the landing sidewall portions LSPb. The cell contact plugs 574 penetrate an interlayer insulation layer 570 on the stack structures. Conductive interconnection lines 584 extending in the second direction are disposed on the interlayer insulation layer 570. The conductive interconnection lines 584 are electrically connected to the cell contact plugs 574.

Bit lines 582 are disposed on the interlayer insulation layer 570. The bit lines 582 are electrically connected to the semiconductor pillars 530 through bit line contact plugs 572 penetrating the interlayer insulation layer 570. The bit lines 582 extend in the second direction. Each of the bit lines 582 is electrically connected to the semiconductor pillars 530 which are one-dimensionally arrayed in the second direction to constitute a single column.

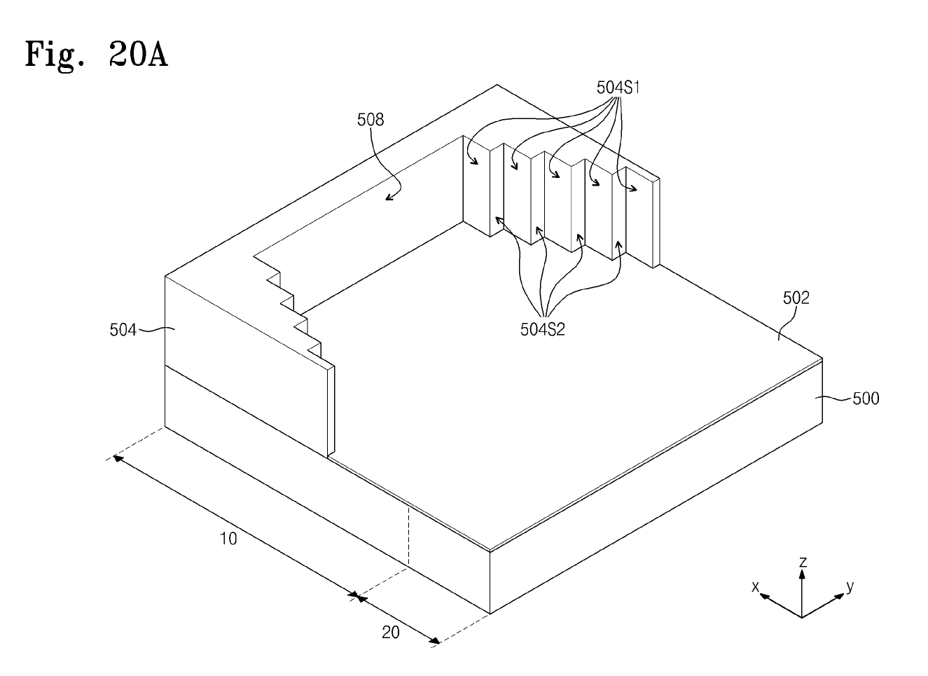

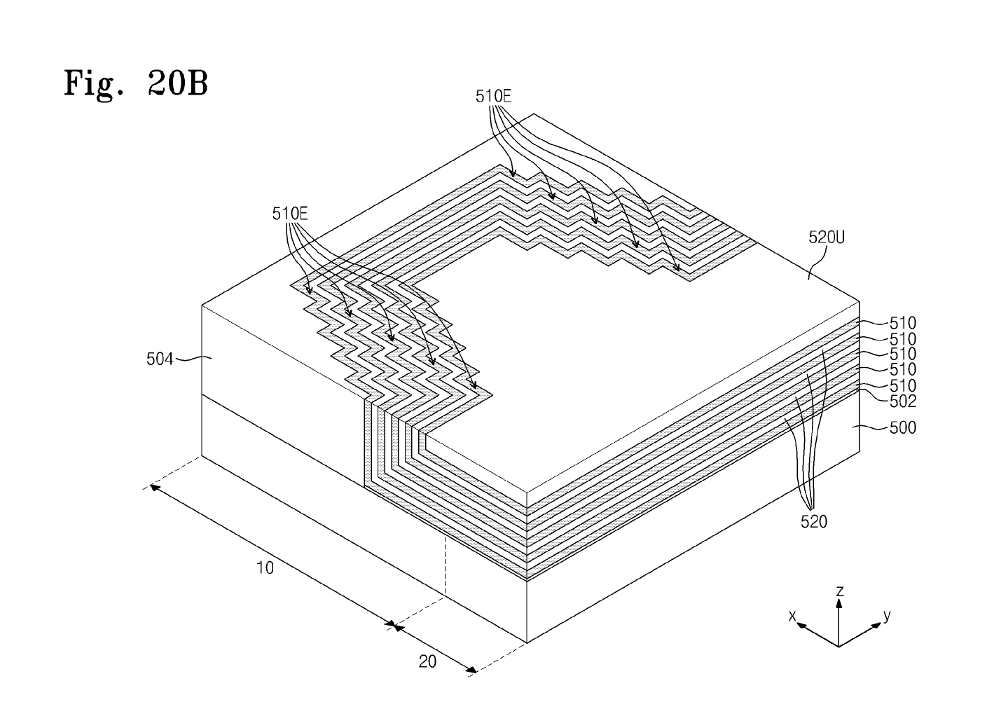

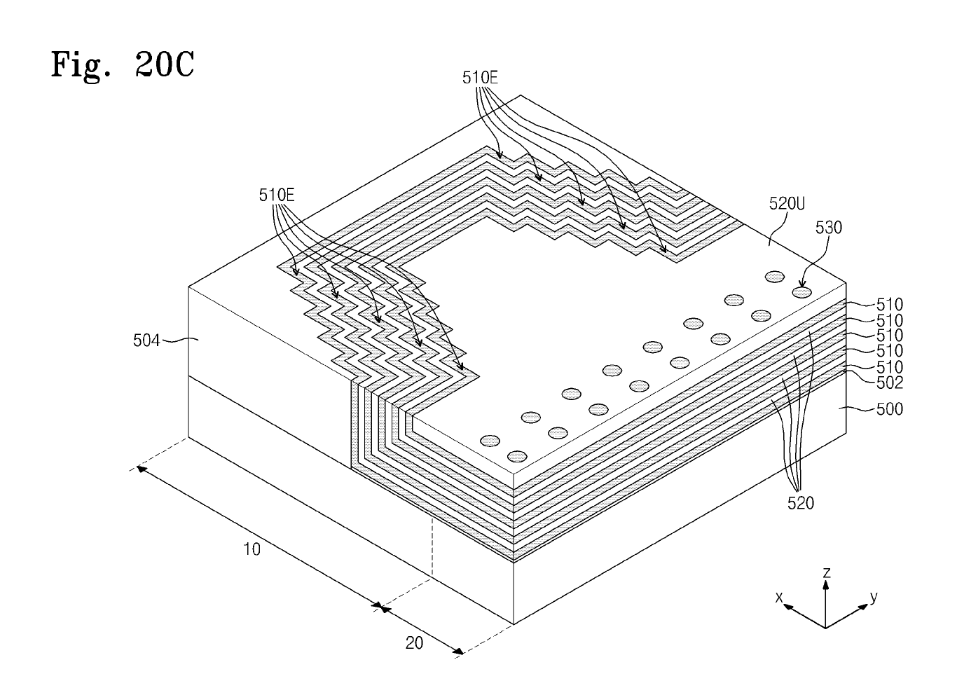

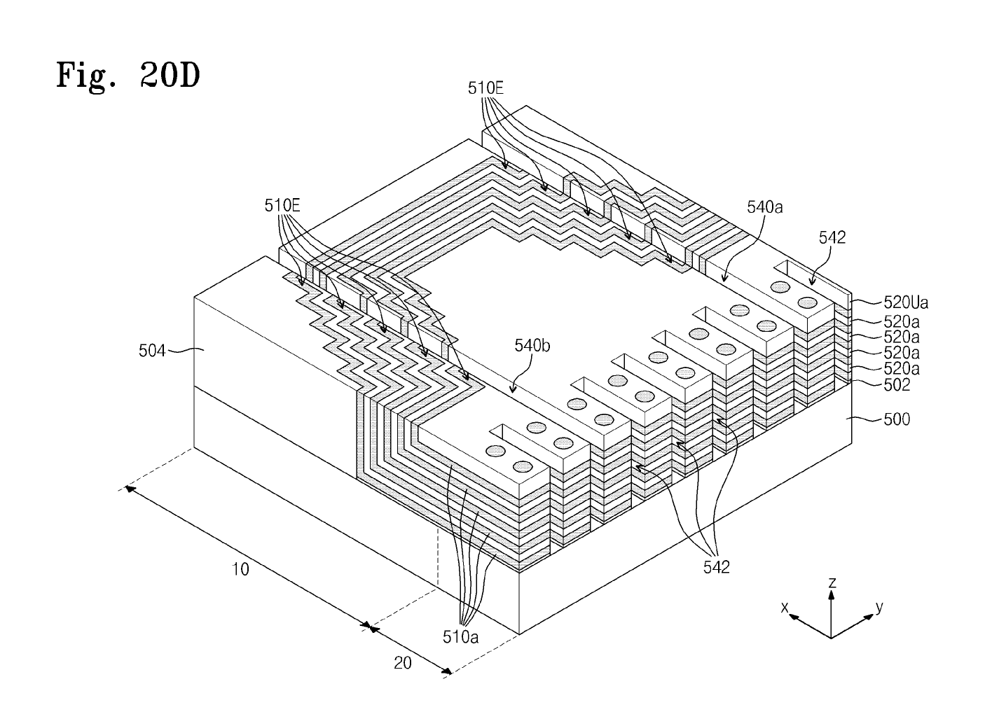

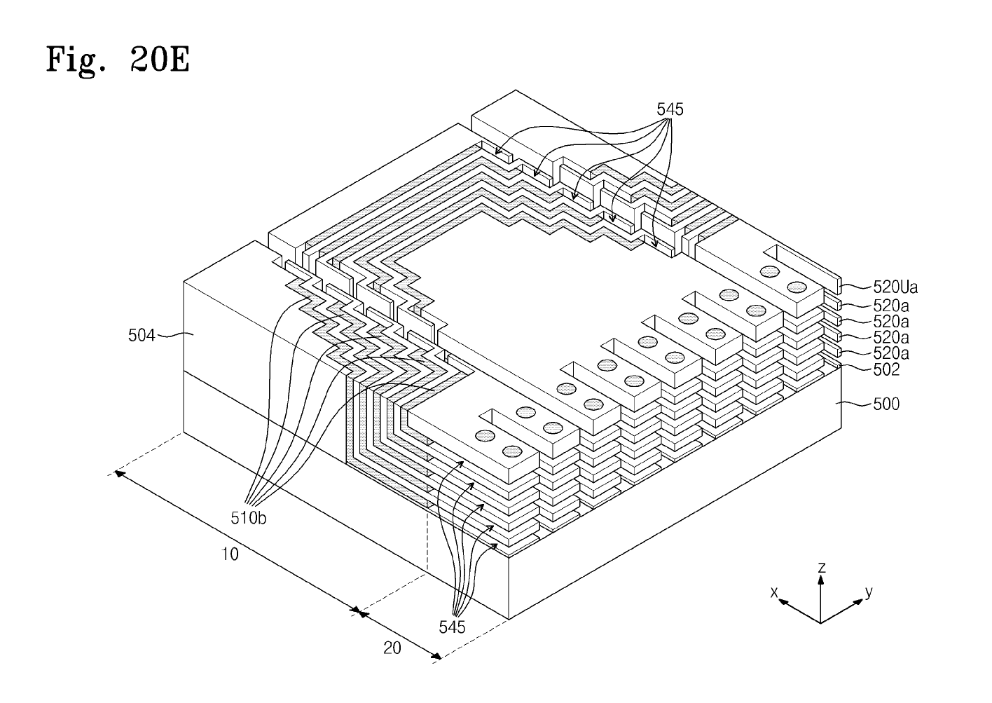

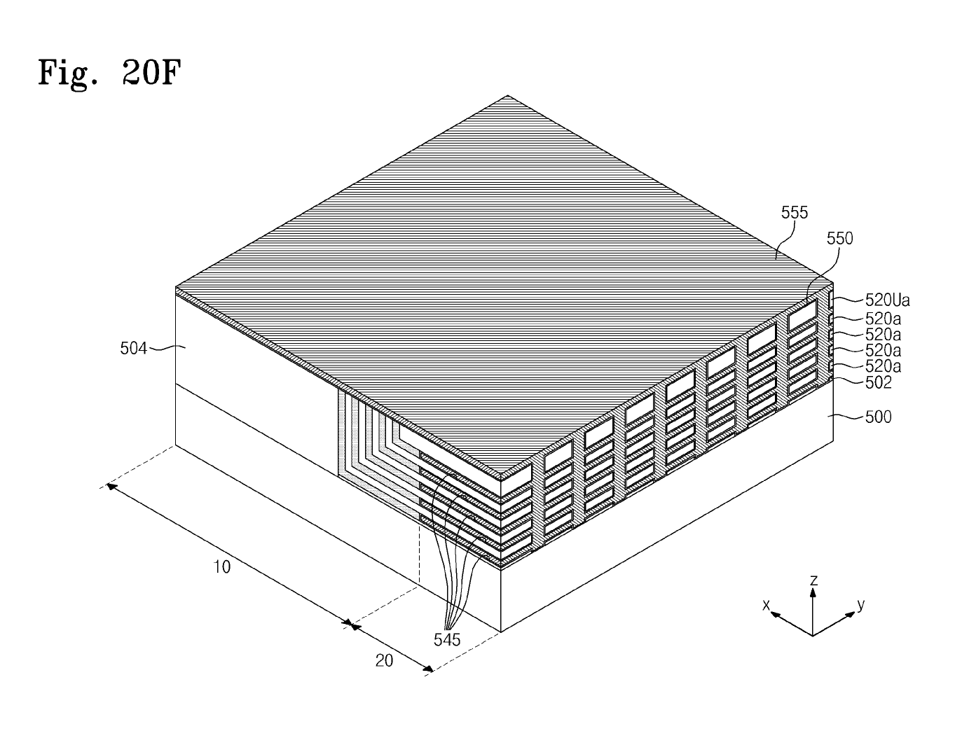

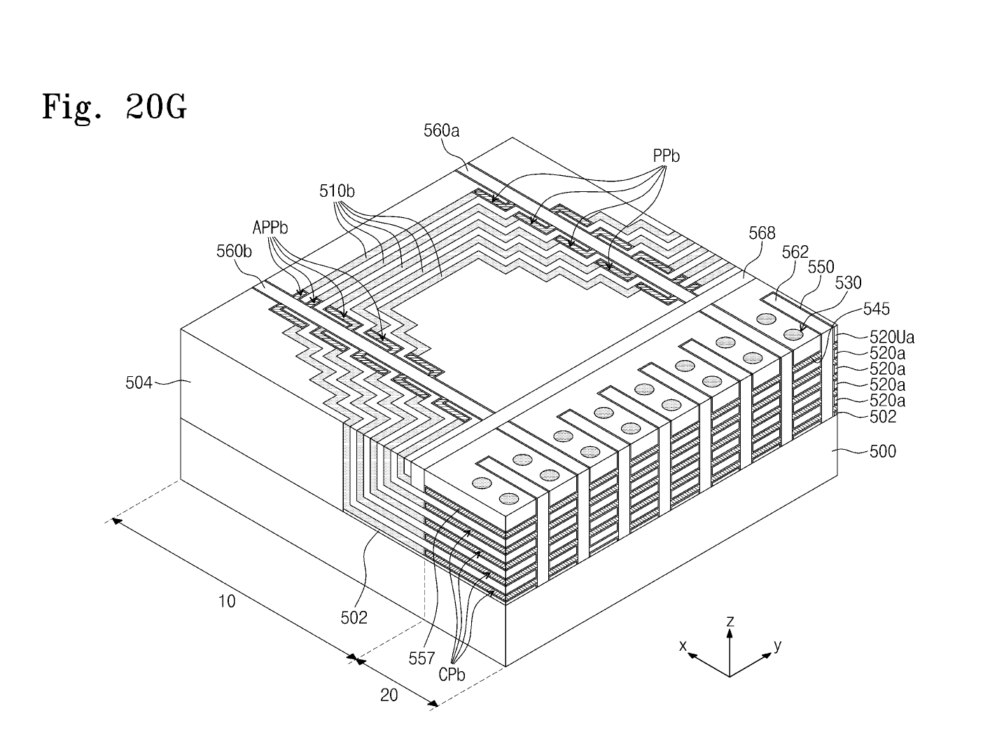

A method of fabricating a semiconductor device according to an exemplary embodiment will be described hereinafter. FIGS. 20A to 20G are perspective views illustrating a method of fabricating a semiconductor device according to an exemplary embodiment.

Referring to FIG. 20A, a substrate 500 including a first region 10 and a second region 20 is provided. A pattern structure 504 is formed on the substrate 500 in the first region 10. The pattern structure 504 is formed to include an empty space defined by an intaglio pattern 508. A width of the intaglio pattern 508 in a second direction is stepwise reduced in a first direction running from an edge of the pattern structure 504 toward a bulk region of the pattern structure 504. The first direction and the second direction are parallel with a top surface of the substrate 500, and the first direction intersects the second direction. In the drawings, the first direction corresponds to an x-axis direction, and the second direction corresponds to a y-axis direction. The pattern structure 504 is formed using the same process as the process of forming the pattern structure 107 described with reference to FIG. 4A.

The intaglio pattern 508 includes first sidewalls 504S1 parallel with the first direction and second sidewalls 504S2 parallel with the second direction. The intaglio pattern 108 includes two first sidewalls 504S1 which are opposite to each other. The two opposing first sidewalls 504S1 are referred to as a first sidewall-pair in the specification. Accordingly, the intaglio pattern 508 includes a plurality of first sidewall-pairs. A distance between the first sidewalls included in the first sidewall-pair located to be relatively closer to the second region 20 is greater than a distance between the first sidewalls included in the first sidewall-pair located to be relatively farther from the second region 20.

A buffer dielectric layer 502 is formed to cover a top surface of the substrate 500. For example, the buffer dielectric layer 502 is formed of a silicon oxide layer by a thermal oxidation process.

Referring to FIG. 20B, first material layers and second material layers different from the first material layers are alternately and repeatedly stacked on the substrate including the buffer dielectric layer 502. The first material layers are sacrificial layers 510, and the second material layers are insulation layers 520 and 520U. Each of the sacrificial layers 510 is formed to include a silicon nitride layer, and each of the insulation layers 520 and 520U is formed to include a silicon oxide layer. The sacrificial layers 510 and the insulation layers 520 and 520U are planarized using the pattern structure 504 as an etch stop layer. The uppermost sacrificial layer 510 and the lowermost sacrificial layer 510 are formed to be thicker than the sacrificial layers 510 between the upper and lower sacrificial layers 510. The uppermost insulation layer 520U is formed to be thicker than the insulation layers 520 under the uppermost insulation layer 520U.

When viewed from a plan view, each of the sacrificial layers 510 includes extensions 510E that correspond to vertical planes which are parallel with the first direction. Some of the extensions 510E are one-dimensionally arrayed along the first direction and constitute a single extension group. Therefore, a plurality of extension groups are provided.

Referring to FIG. 20C, semiconductor pillars 530 are formed to fill the sacrificial layers 510, the insulation layers 520 and 520U, and the buffer dielectric layer 502. The semiconductor pillars 530 are two-dimensionally arrayed along the first and second directions. Each of the semiconductor pillars 530 is formed to include the semiconductor portion 131, the filling insulation material 132 and the drain region 133, which are described with reference to FIG. 1. The semiconductor pillars 530, which are one-dimensionally arrayed in the first direction, constitute a single row, and the semiconductor pillars 530, which are one-dimensionally arrayed in the second direction, constitute a single column. Thus, the semiconductor pillars 530 are two-dimensionally arrayed in the rows and the columns.

Referring to FIG. 20D, the pattern structure 504, the sacrificial layers 510 and the insulation layers 520 and 520U are patterned to form first trenches 540a and 540b. The first trenches 540a and 540b extend in the first direction. The trenches 540a and 540b are formed to be adjacent to the extensions 510E. In an embodiment, one of the plurality of extension groups 510E is disposed between the two adjacent first trenches 540a and 540b.

The sacrificial layers 510 and the insulation layers 520 and 520U in the second region 20 are patterned to form second trenches 542. Each of the second trenches 542 is formed between the two adjacent rows.

According to an embodiment, prior to formation of the first trenches 540a and 540b, a capping insulation layer is formed to cover the pattern structure 504, the sacrificial layers 510, the insulation layers 520 and 520U, and the semiconductor pillars 530. According to an embodiment, the capping insulation layer is patterned while the first and second trenches 540a, 540b and 542 are formed. The first and second trenches 540a, 540b and 542 define insulation patterns 520a and 520Ua and sacrificial patterns 510a.

Referring to FIG. 20E, the sacrificial patterns 510a exposed by the trenches 540a, 540b and 542 are partially removed to form recessed regions 545. In an embodiment, at least the extensions 510E of the sacrificial patterns 510a, which are adjacent to the first trenches 540a and 540b, are removed. The sacrificial patterns 510a between the insulation patterns 520a and 520Ua, which are disposed in the second region 20, are fully removed. Thus, the recessed regions 545 expose sidewalls of the semiconductor pillars 530, which are located between the insulation patterns 520a and 520Ua.

The buffer dielectric layer 502 is also removed while the sacrificial patterns 510a are partially removed. Alternatively, the buffer dielectric layer 502 remains even after the sacrificial patterns 510a are partially removed. Hereinafter, for the purpose of description, the buffer dielectric layer 502 remains even after the sacrificial patterns 510a are partially removed.

The sacrificial patterns 510a are partially removed in the same manner as the selective etching process of removing the sacrificial patterns 110La and 110a described with reference to FIG. 4G.

Referring to FIG. 20F, a data storage layer 550 and a gate conductive layer 555 are sequentially formed on the substrate including the recessed regions 545. The data storage layer 550 is formed to substantially a uniform thickness along inner surfaces of the recessed regions 545. The data storage layer 550 is conformally formed in the recessed regions 545. The data storage layer 550 is formed by sequentially stacking the tunnel insulation layer 150a, the charge storage layer 150b and the blocking layer 150c described with reference to FIG. 3.

The gate conductive layer 555 is formed to fill the recessed regions 545. The gate conductive layer 555 is formed to partially or fully fill the first and second trenches 540a, 540b and 542. The gate conductive layer 555 is electrically insulated from the semiconductor pillars 530 and the substrate 500 by the data storage layer 550.

Referring to FIG. 20G, the gate conductive layer 555 positioned outside the recessed regions 545 is removed to form conductive patterns CPb, pad patterns PPb and auxiliary pad patterns APPb that remain in the recessed regions 545. The gate conductive layer 555 positioned outside the recessed regions 545 is selectively removed by a wet etching process and/or a dry etching process.

First isolation patterns 560a and 560b are formed to fill the first trenches 540a and 540b, respectively. Further, second isolation patterns 562 are formed to fill respective ones of the second trenches 542.

An insulation separating pattern 568 is formed to penetrate the uppermost insulation pattern 520Ua and to extend in the second direction. Further, the insulation separating pattern 568 is formed to penetrate the uppermost conductive pattern CPb that exists at an interface region between the first and second regions 10 and 20. Thus, string selection lines 557 are formed between the uppermost insulation pattern 520Ua and the insulation pattern 520a under the uppermost insulation pattern 520Ua.

Subsequently, referring again to FIG. 18, an interlayer insulation layer 570 is formed on the substrate including the insulation separating pattern 568. Bit line contact plugs 572 and cell contact plugs 574 are formed to penetrate the interlayer insulation layer 570. The bit line contact plugs 572 are connected to respective ones of the semiconductor pillars 530, and the cell contact plugs 574 are connected to respective ones of the landing sidewall portions LSP. Bit lines 582 and conductive interconnection lines 584 are formed on the interlayer insulation layer 570 to extend in the second direction. The bit lines 582 are connected to the bit line contact plugs 572, and the conductive interconnection lines 584 are connected to the cell contact plugs 574.

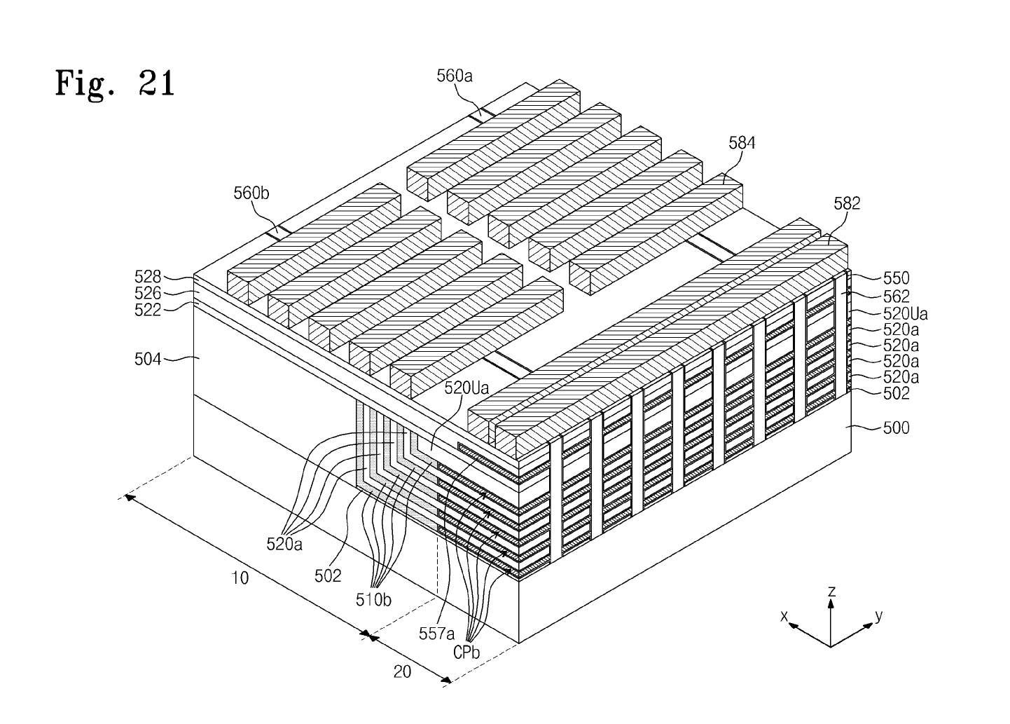

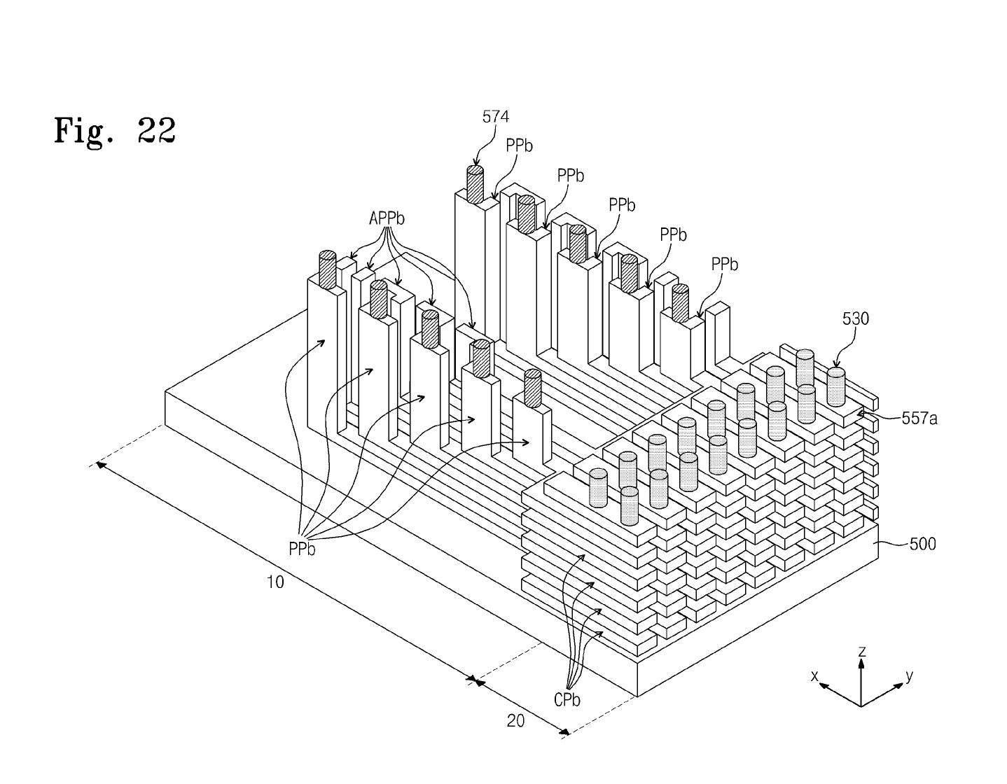

A semiconductor device according to an exemplary embodiment is now described. FIGS. 21 and 22 are perspective views illustrating a semiconductor device according to an exemplary embodiment.

For convenience of description, FIG. 22 illustrates only a substrate 500, semiconductor pillars 530, conductive patterns CPb, pad patterns PPb, auxiliary pad patterns APPb, string selection lines 557a and cell contact plugs 574.

The semiconductor device is similar to the semiconductor device described above in connection with FIGS. 18 to 20G. Thus, differences between the two semiconductor devices are mainly described hereinafter.

Referring to FIGS. 21 and 22, the semiconductor device includes the substrate 500 having the first and second regions 10 and 20, the conductive patterns CPb, the pad patterns PPb, the auxiliary pad patterns APPb, the semiconductor pillars 530, the sacrificial patterns 510b, the insulation patterns 520a and 520Ua, the data storage layer 530 and the pattern structure 504, which are described with reference to FIGS. 18, 19A and 19B. According to an embodiment, the semiconductor device does not include the string selection lines 557, the floating conductive patterns 559 and the insulation separating pattern 568, which are described with reference to FIGS. 18, 19A and 19B.

A first upper insulation layer 522 and a second upper insulation layer 526 are sequentially stacked on the uppermost insulation pattern 520Ua and the pattern structure 504. A capping insulation layer 528 is disposed on the second upper insulation layer 526. String selection lines 557a are disposed between the first upper insulation layer 522 and the second upper insulation layer 526 in the second region 20.

Each of the string selection lines 557a has a line shape extending in a first direction which is parallel with an x-axis direction. The string selection lines 557a are parallel with the conductive patterns CPb (corresponding to gate electrodes GEb), and the number of the string selection lines 557a is equal to the number of the gate electrodes GEb.

The cell contact plugs 574 are provided to penetrate the capping insulation layer 528, the second upper insulation layer 526 and the first upper insulation layer 522. The cell contact plugs 574 are connected to respective ones of the sidewall portions of the pad patterns PPb. Conductive interconnection lines 584 are disposed on the capping insulation layer 528. The conductive interconnection lines 584 are connected to the cell contact plugs 574.

Bit lines 582 are disposed on the capping insulation layer 528. The bit lines 582 are connected to the semiconductor pillars 530 through bit line contact plugs that penetrate the capping insulation layer 528.

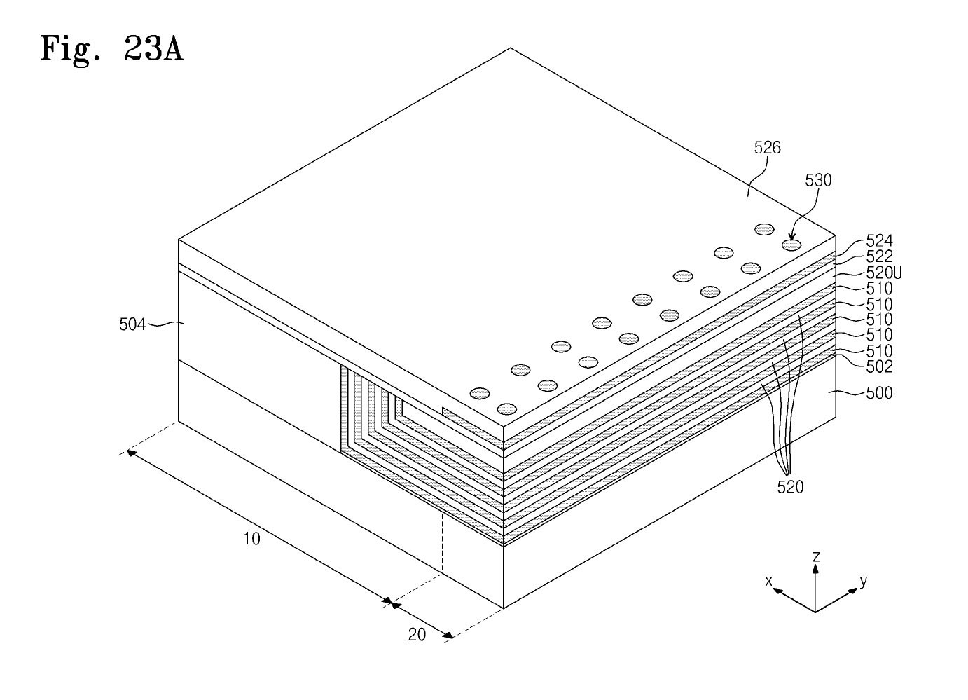

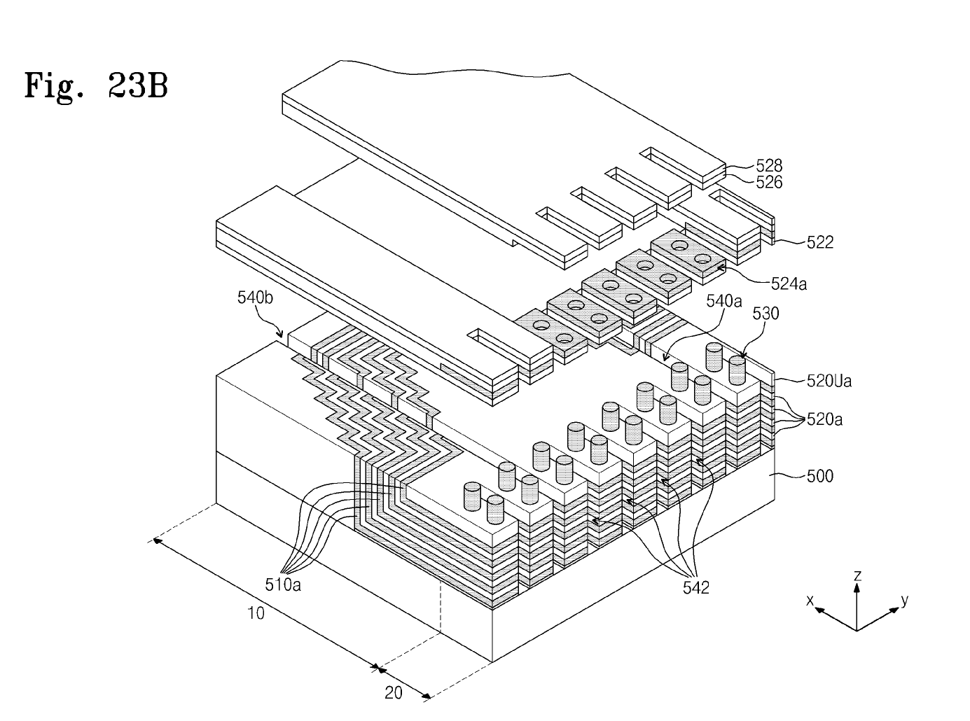

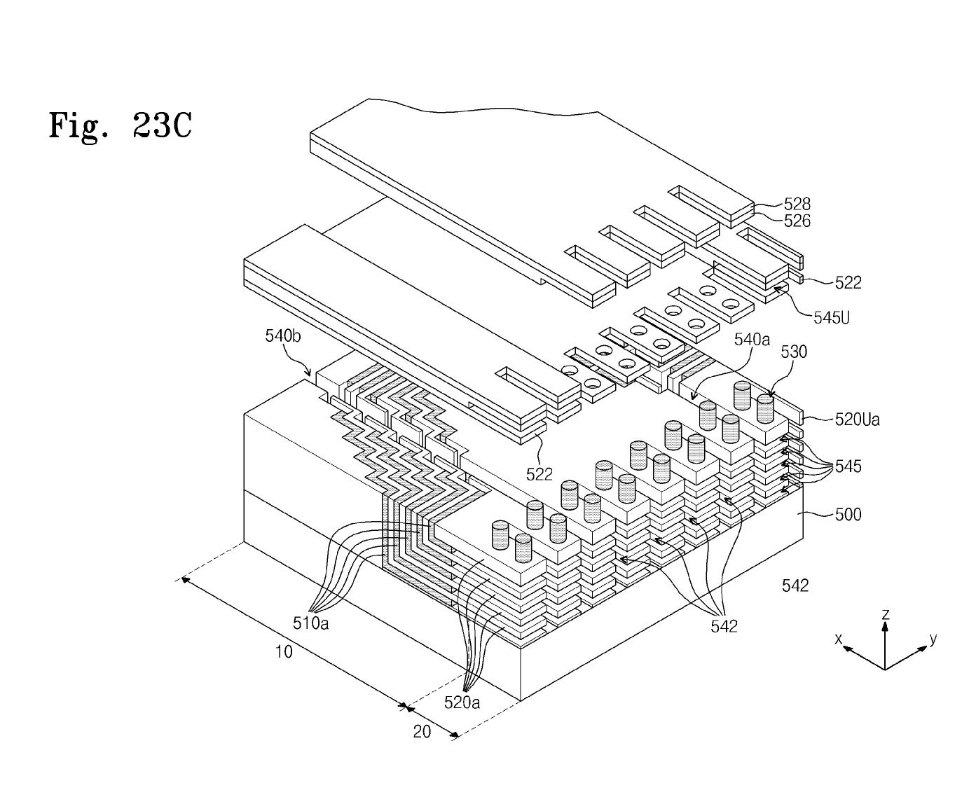

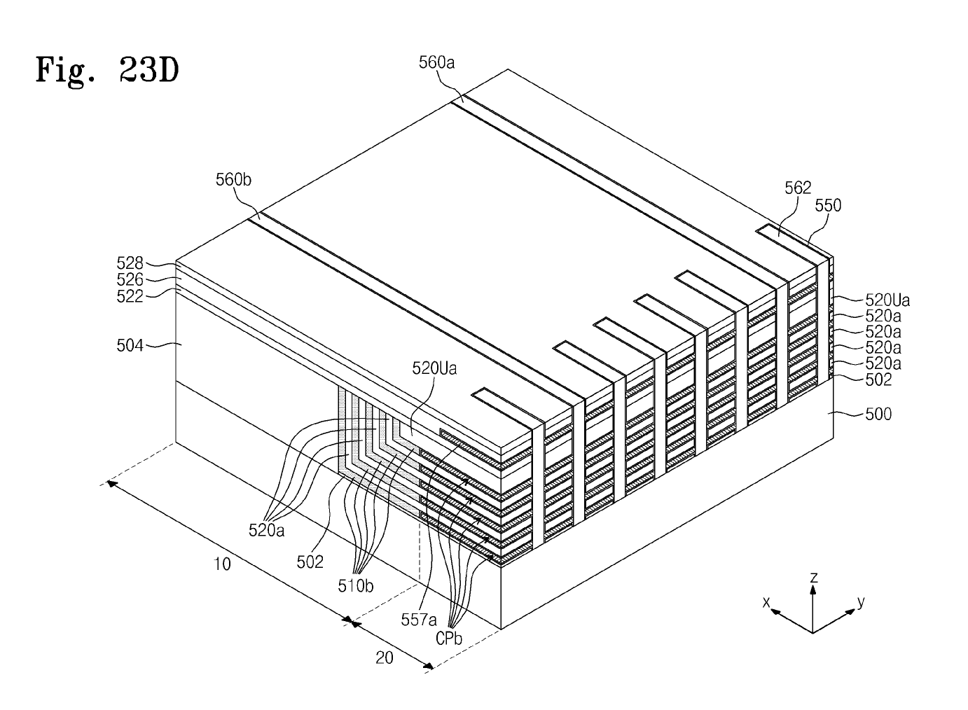

A method of fabricating a semiconductor device according to an exemplary embodiment is described hereinafter. FIGS. 23A to 23D are perspective views illustrating a method of fabricating a semiconductor device according to an exemplary embodiment.

Referring to FIG. 23A, a pattern structure 504 and a buffer dielectric layer 502 are formed on a substrate 500, as described with reference to FIG. 20A planarized sacrificial layers 510 and planarized insulation layers 520 and 520U are alternately and repeatedly formed on the buffer dielectric layer 502, as described with reference to FIG. 20B. A first upper insulation layer 522 is formed to cover the pattern structure 504 and the uppermost insulation layer 520U. An additional sacrificial layer 524 is formed on the first upper insulation layer 522 in the second region 20, and a second upper insulation layer 526 is formed on the first upper insulation layer 522 and the additional sacrificial layer 524. The additional sacrificial layer 524 is formed of the same material as the sacrificial layers 510, and the first and second upper insulation layers 522 and 526 are formed of the same material as the insulation layers 520 and 520U.

Semiconductor pillars 530 are formed to penetrate the first and second upper insulation layers 522 and 526, the additional sacrificial layer 524, the sacrificial layers 510, and the insulation layers 520 and 520U. The semiconductor pillars 530 are formed in the same manner as described with reference to FIG. 20C.

Referring to FIG. 23B, a capping insulation layer 528 is formed on the second upper insulation layer 526. In the same manner as described with reference to FIG. 20D, the pattern structure 504, the sacrificial layers 510, the insulation layers 520 and 520U, the first and second upper insulation layers 522 and 526, the additional sacrificial layer 524 and the capping insulation layer 528 are patterned to form first trenches 540a and 540b. Further, in the same manner as described with reference to FIG. 20D, the pattern structure 504, the sacrificial layers 510, the insulation layers 520 and 520U, the first and second upper insulation layers 522 and 526, the additional sacrificial layer 524 and the capping insulation layer 528 are patterned to form second trenches 542.

During formation of the first and second trenches 540a, 540b and 542, the additional sacrificial layer 524 is patterned to form upper sacrificial patterns 524a that have a line shape extending in the first direction. The upper sacrificial patterns 524a are formed between the second trenches 542. The first and second trenches 540a, 540b and 542 define insulation patterns 520a and 520Ua and sacrificial patterns 510a.

Referring to FIG. 23C, the sacrificial patterns 510a exposed by the first and second trenches 540a, 540b and 542 are partially removed to form recessed regions 545. While the sacrificial patterns 510a are partially removed, the upper sacrificial patterns 524a are removed to form upper recessed regions 545U. The upper recessed regions 545U are formed between the first and second upper insulation layers 522 and 526. The upper recessed regions 545U are formed to have a line shape extending in the first direction.

Referring to FIG. 23D, in the same manner as described with reference with FIG. 20F, a data storage layer 550 and a gate conductive layer are sequentially formed on the substrate including the recessed regions 545 and 545U, and the gate conductive layer positioned outside the recessed regions 545 and 545U is removed. As a result, the conductive patterns CPb, the pad patterns PPb and the auxiliary pad patterns APPb, which are illustrated in FIGS. 21 and 22, are formed in the recessed regions 545, and the string selection lines 557a illustrated in FIGS. 21 and 22 are formed in the upper recessed regions 545U.

First isolation patterns 560a and 560b are formed to fill the first trenches 540a and 540b, respectively. Further, second isolation patterns 562 are formed to fill respective ones of the second trenches 542.

Subsequently, referring again to FIG. 21, cell contact plugs 574 are formed to penetrate the capping insulation layer 528 and the first and second upper insulation layers 522 and 526, and bit line contact plugs (not shown) are formed to penetrate the capping insulation layer 528. The bit line contact plugs are connected to respective ones of the semiconductor pillars 530, and the cell contact plugs 574 are connected to respective corresponding landing sidewall portions of the landing sidewall portions of the pad patterns PPb. Bit lines 582 and conductive interconnection lines 584 are formed on the capping insulation layer 528 to extend in the second direction. The bit lines 582 are connected to the bit line contact plugs, and the conductive interconnection lines 584 are connected to the cell contact plugs 574.

Now, a method of fabricating a semiconductor device according to an eighth exemplary embodiment and a semiconductor device fabricated by the method is described.

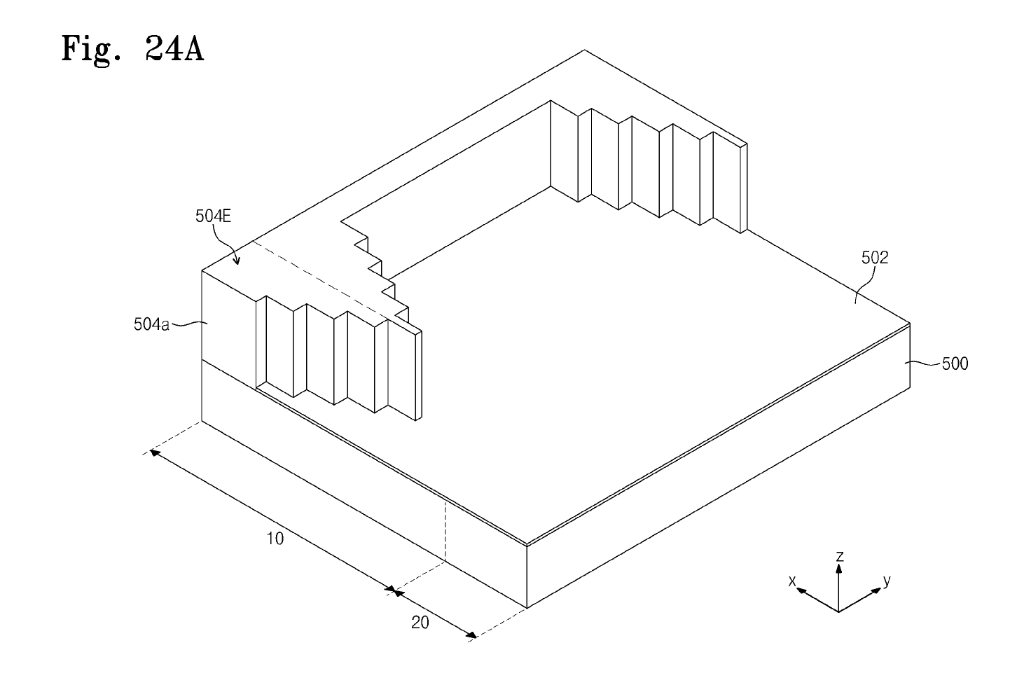

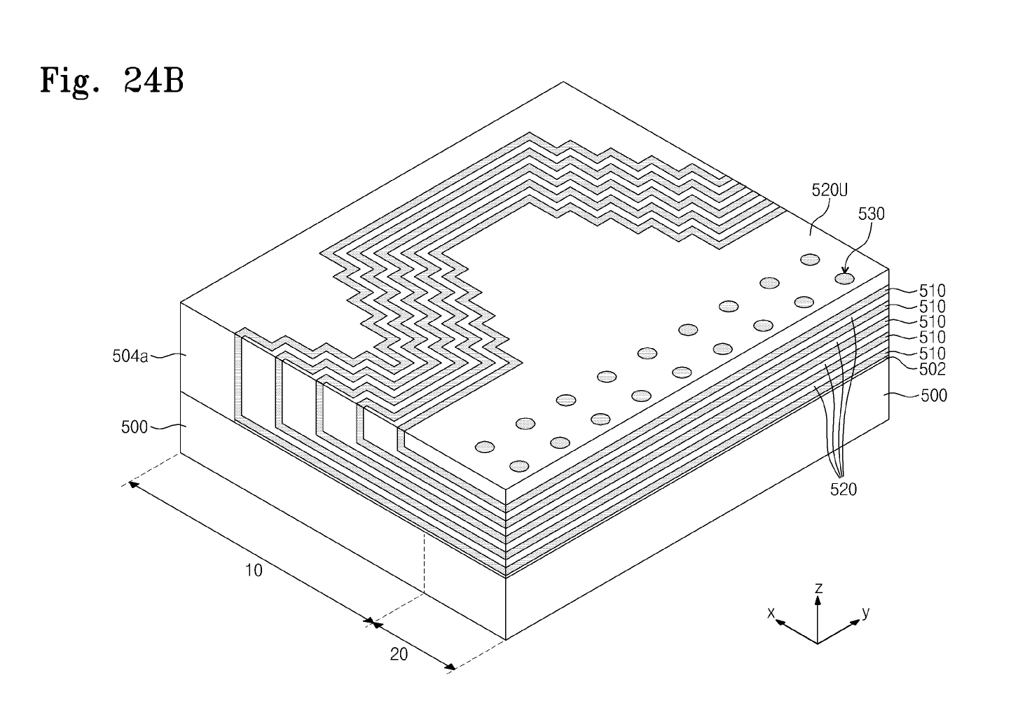

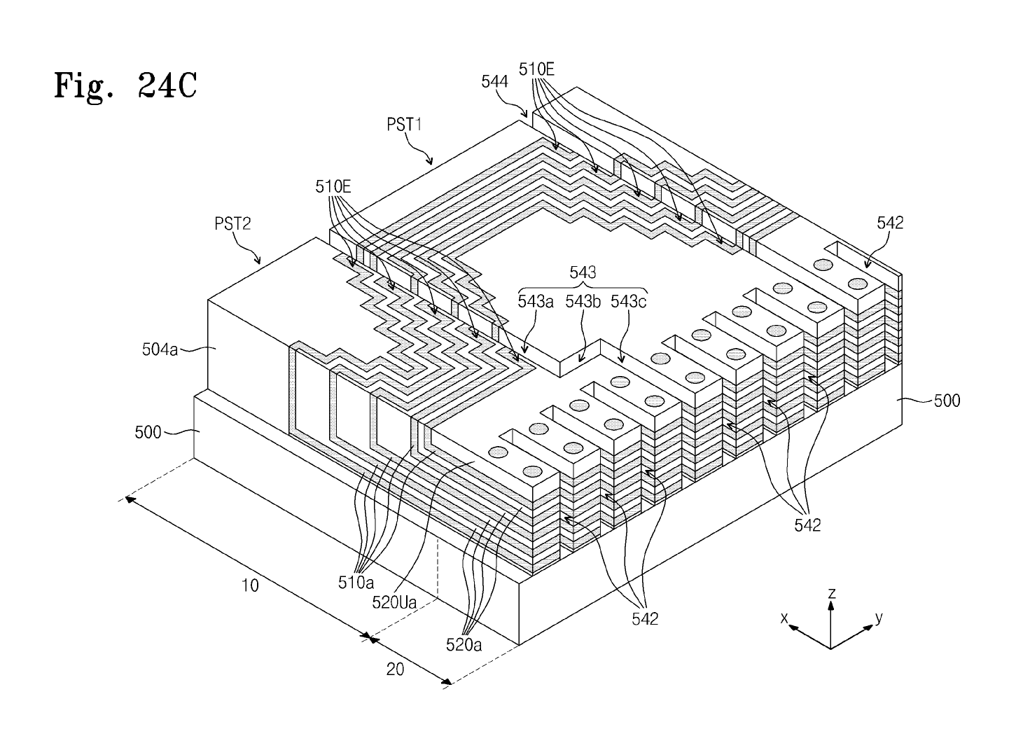

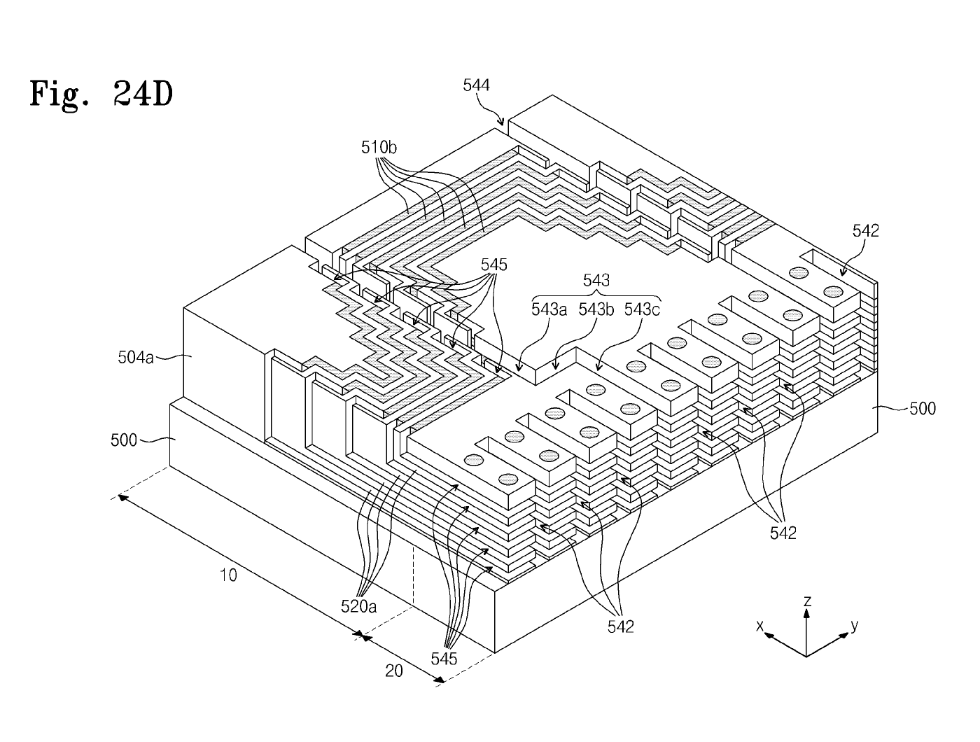

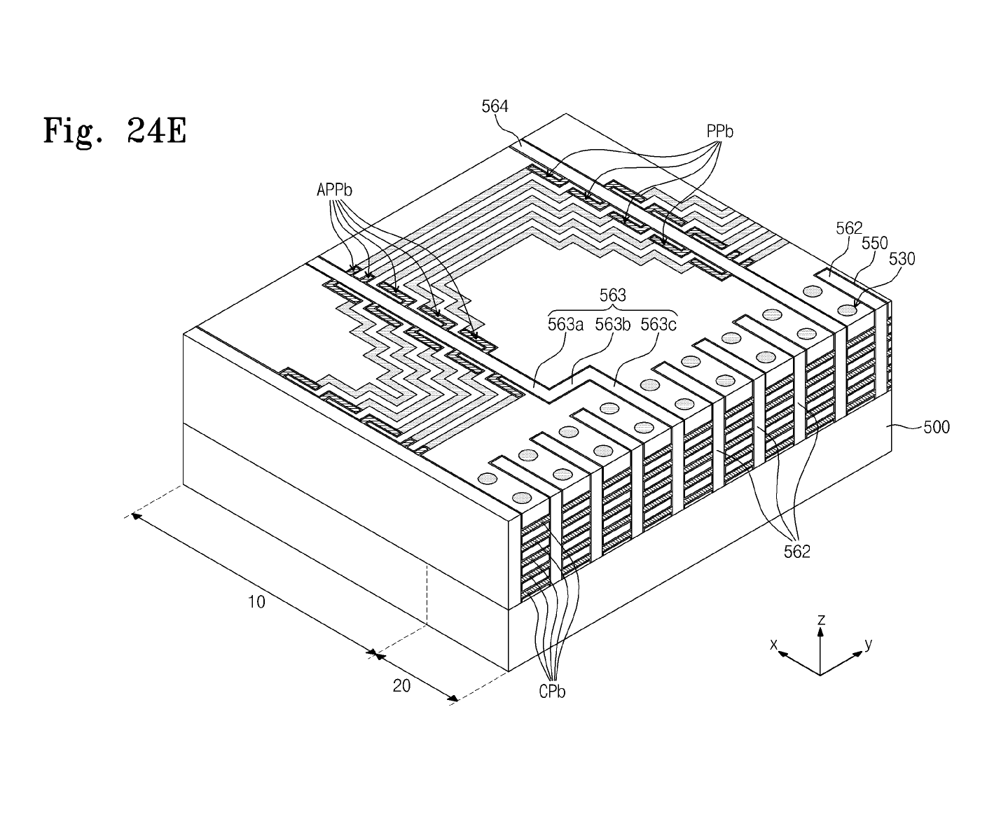

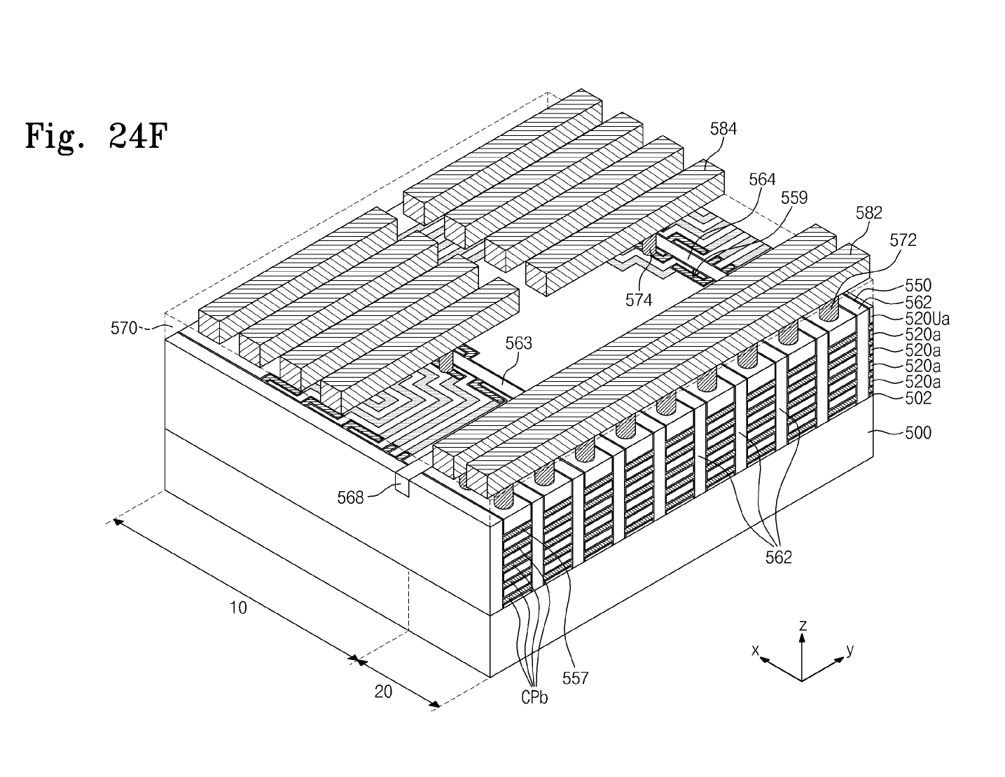

FIGS. 24A to 24F are perspective views illustrating a method of fabricating a semiconductor device according to an exemplary embodiment and a semiconductor device fabricated by the method.

Referring to FIG. 24A, a substrate 500 including first and second regions 10 and 20 is provided, as described with reference to FIG. 20A. A pattern structure 504a is formed on the substrate 500 in the first region 10. The pattern structure 504a is formed in the same manner as the process of forming the pattern structure 107 described with reference to FIG. 4A. The pattern structure 504a is formed to further include a pattern extension 504E, as compared with the pattern structure 504 illustrated in FIG. 20A.

After the pattern structure 504a is formed, a buffer dielectric layer 502 is formed on the substrate 500.

Referring to FIG. 24B, planarized sacrificial layers 510 and planarized insulation layers 520 and 520U are alternately and repeatedly formed on the buffer dielectric layer 502 in the same manner as described with reference to FIG. 20B. Semiconductor pillars 530 are formed to penetrate the sacrificial layers 510 and insulation layers 520 and 520U in the second region 20, as described with reference to FIG. 20C.

Referring to FIG. 24C, the pattern structure 504, the sacrificial layers 510 and the insulation layers 520 and 520U are patterned to form first and second trenches 543 and 544. Further, the sacrificial layers 510 and the insulation layers 520 and 520U are patterned to form third trenches 542 in the second region 20. The first, second and third trenches 543, 544 and 542 define insulation patterns 520a and 520Ua and sacrificial patterns 510a.

The first trench 543 includes a first region 543a extending in a first direction, a second region 543b extending from an end of the first region 543a in a second direction perpendicular to the first direction, and a third region 543c extending from an end of the second region 543b in the first direction. The first direction is an x-axis direction, and the second direction is a y-axis direction. Thus, the first trench 543 has a crank shape in a plan view. The first region 543a is formed to be adjacent to extensions 510E of the sacrificial patterns 510a extending in the first direction, when viewed from a plan view. The third region 543c is formed between two rows which are parallel with the first direction.

The second trench 544 is formed to extend in the first direction and to be adjacent to the extensions 510E of the sacrificial patterns 510a. A single extension group including the extensions 510E arrayed in the first direction is disposed between the second trench 544 and the first region 543a of the first trench 543.

The first trench 543 splits the sacrificial patterns 510a and the insulation patterns 520a and 520Ua into first and second preliminary stack structures PST1 and PST2 which are respectively disposed at two sides of the first trench 543. When the semiconductor pillars 530 one-dimensionally arrayed in the second direction constitute a single column, the number of the columns in the first preliminary stack structures PST1 is equal to the number of the columns in the second preliminary stack structures PST2.

In an embodiment, prior to formation of the first, second and third trenches 543, 544 and 542, a capping insulation layer is formed on the insulation layers 520 and 520U, the sacrificial layers 510, the pattern structure 504a and the semiconductor pillars 530. According to an embodiment, the capping insulation layer is patterned while the first, second and third trenches 543, 544 and 542 are formed. For convenience of description, the capping insulation layer is not illustrated in FIG. 24C.

Referring to FIG. 24D, the sacrificial patterns 510a exposed by the first to third trenches 543, 544 and 542 are partially removed to form recessed regions 545. In an embodiment, while the sacrificial patterns 510a are partially removed, at least the extensions 510E of the sacrificial patterns 510a are removed, and the sacrificial patterns 510a between the insulation patterns 520a and 520Ua in the second region 20 are removed.

Referring to FIG. 24E, in the same manner as described with reference with FIG. 20F, a data storage layer 550 and a gate conductive layer are sequentially formed on the substrate including the recessed regions 545, and the gate conductive layer positioned outside the recessed regions 545 is removed. As a result, conductive patterns CPb, pad patterns PPb and auxiliary pad patterns APPb are formed in the recessed regions 545.

First to third isolation patterns 563, 564 and 562 are formed in the first to third trenches 543, 544 and 542, respectively. The first isolation pattern 563 includes a first portion 564a formed in the first region 543a to extend in the first direction, a second portion 564b formed in the second region 543b to extend in the second direction, and a third portion 543c formed in the third region 543c to extend in the first direction.

Referring to FIG. 24F, an insulation separating pattern 568 is formed to penetrate the uppermost insulation pattern 520Ua and to extend in the second direction. Further, the insulation separating pattern 568 is formed to penetrate the uppermost conductive pattern CPb that is provided at an interface region between the first and second regions 10 and 20. As a result, string selection lines 557 are formed between the uppermost insulation pattern 520Ua and the insulation pattern 520a under the uppermost insulation pattern 520Ua, as described with reference to FIG. 20G.

Subsequently, an interlayer insulation layer 570 is formed on the substrate including the insulation separating pattern 568. Cell contact plugs 574 and the bit line contact plugs 572 are formed to penetrate the interlayer insulation layer 570. The bit line contact plugs 572 are connected to respective ones of the semiconductor pillars 530, and the cell contact plugs 574 are connected to respective ones of the pad patterns PPb. Bit lines 582 and conductive interconnection lines 584 are formed on the interlayer insulation layer 570 to extend in the second direction. The bit lines 582 are connected to the bit line contact plugs 572, and the conductive interconnection lines 584 are connected to the cell contact plugs 574.

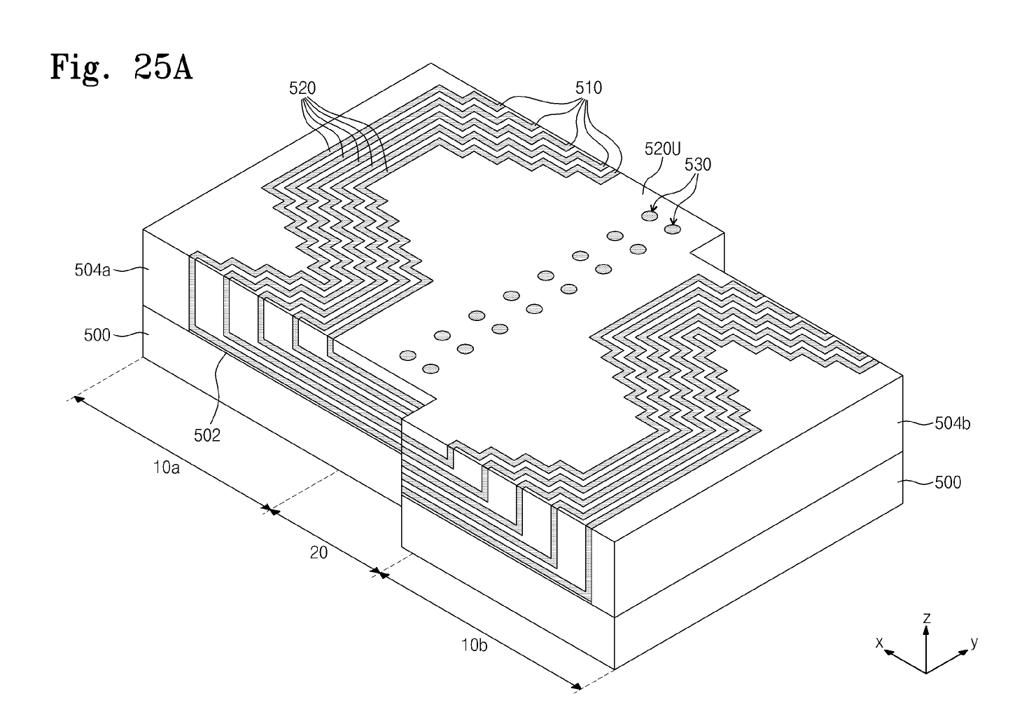

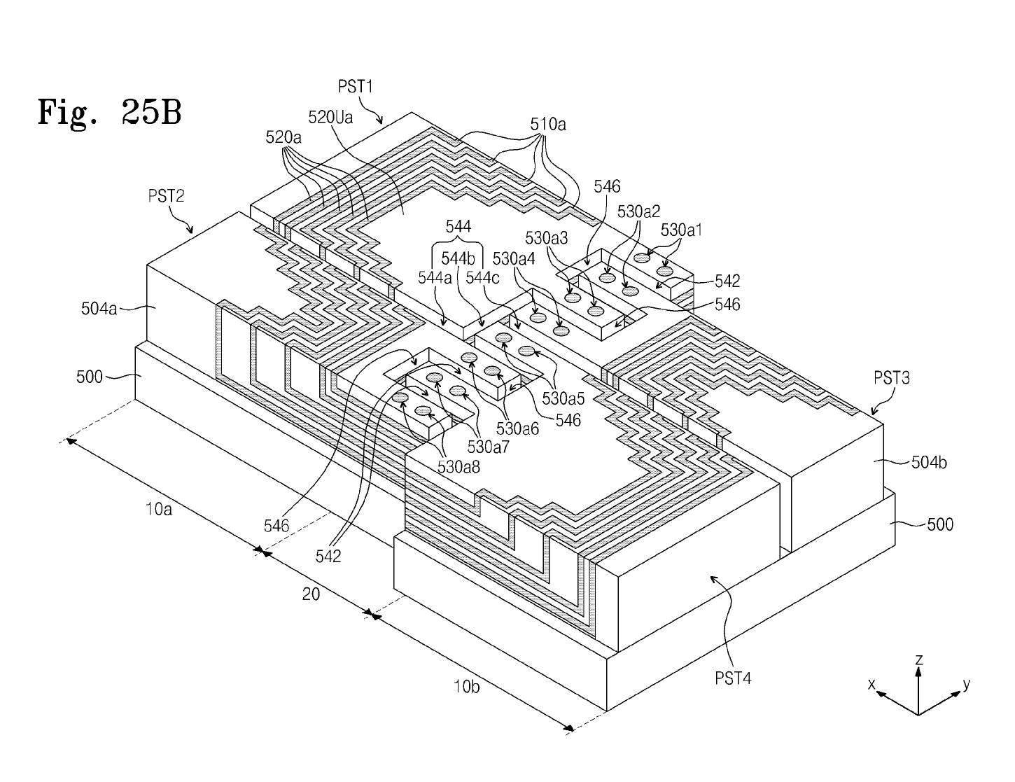

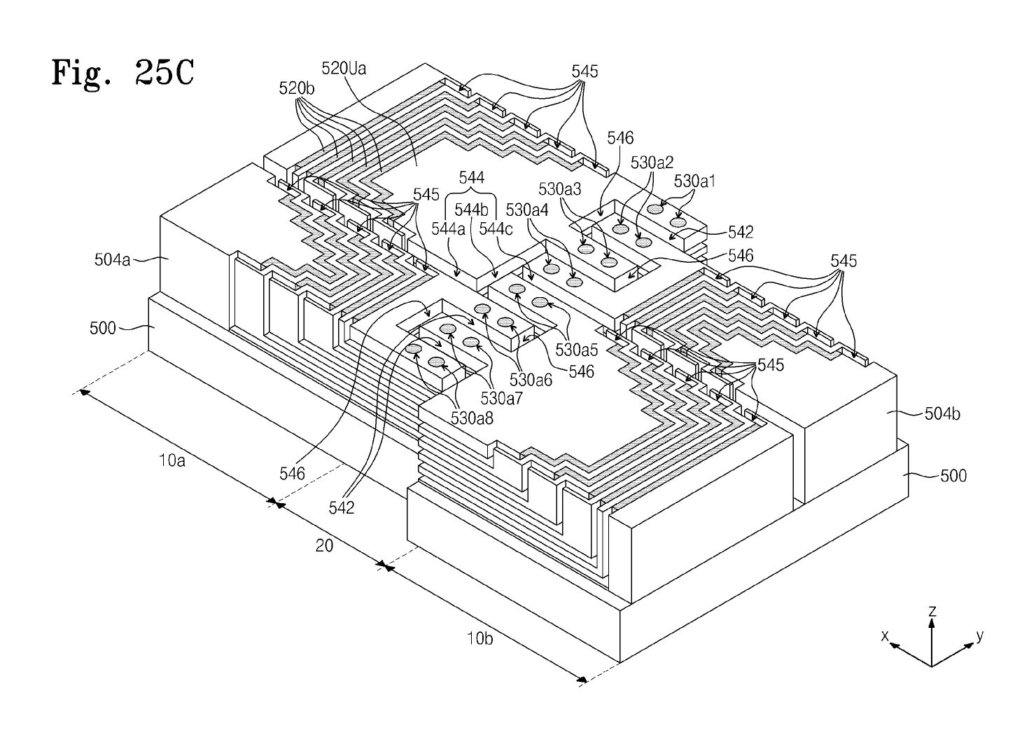

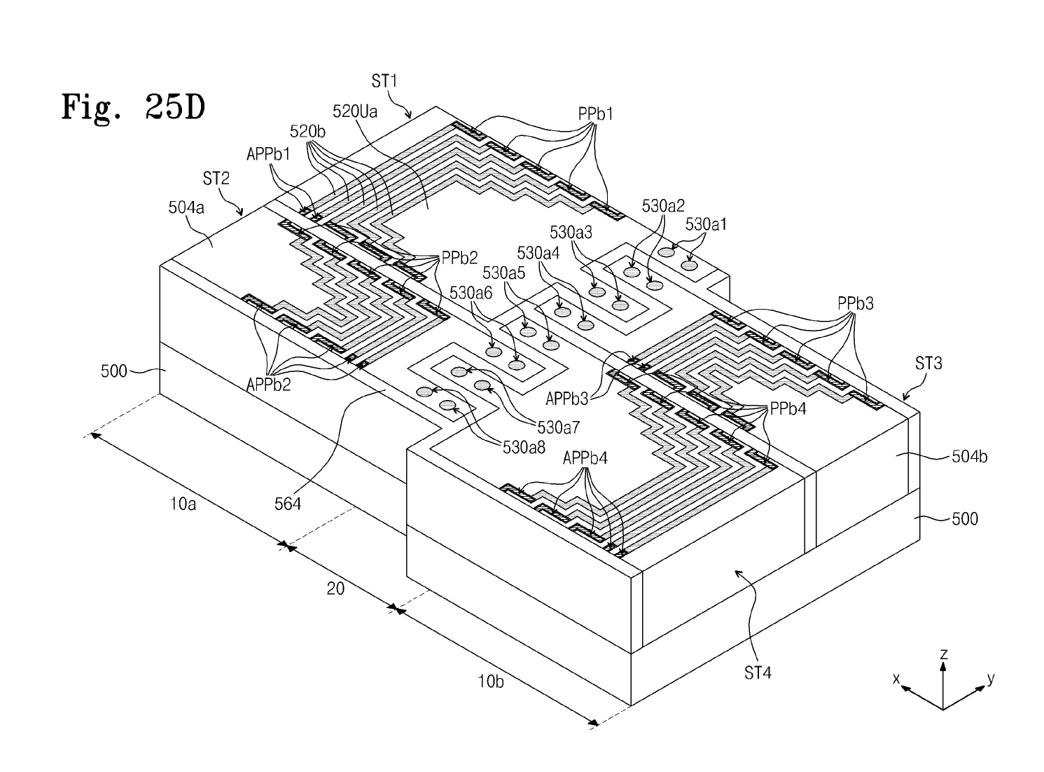

A method of fabricating a semiconductor device according to an exemplary embodiment and a semiconductor device fabricated by the method are now described. FIGS. 25A to 25D are perspective views illustrating a method of fabricating a semiconductor device according to an exemplary embodiment and a semiconductor device fabricated by the method.

Referring to FIG. 25A, the substrate 500, which is described with reference to FIG. 20A, is provided. The substrate 500 includes first and second pad regions 10a and 10b and a cell region 20 between the first and second pad regions 10a and 10b. The pattern structure 504a, which is described with reference to FIG. 24A, is formed on the substrate 500 in the first pad region 10a. An additional pattern structure 504b is formed on the substrate 500 in the second pad region 10b. In an embodiment, the pattern structure 504a and the additional pattern structure 504b are symmetrical to each other with respect to a central point of the cell region 20, as illustrated in FIG. 25A. Alternatively, even though not shown in the drawings, the pattern structure 504a and the additional pattern structure 504b are symmetrical to each other with respect to a straight line that passes through the central point of the cell region 20 and extends in a second direction. The second direction is parallel with a y-axis direction. According to an embodiment, a first direction is parallel with an x-axis direction perpendicular to the second direction.

After formation of the pattern structures 504a and 504b, a buffer dielectric layer 502 is formed on the substrate 500. Planarized sacrificial layers 510 and planarized insulation layers 520 and 520U are alternately and repeatedly stacked on the buffer dielectric layer 502 in the same manner as described with reference to FIG. 20B.

Semiconductor pillars 530 are formed to penetrate the sacrificial layers 510 and insulation layers 520 and 520U in the same manner as described with reference to FIG. 20C. The semiconductor pillars 530 are formed in the cell region 20.

Referring to FIG. 25B, the pattern structures 504a and 504b, the sacrificial layers 510 and the insulation layers 520 and 520U are patterned to form a first trench 544. The first trench 544 includes a first region 544a extending in the first direction, a second region 544b extending from an end of the first region 544a in the second direction, and a third region 544c extending from an end of the second region 544b in the first direction. In an embodiment, the first region 544a is formed in the pad region 10a, and the second region 544b is formed in an interface region between the first pad region 10a and the cell region 20. Further, the third region 544c is formed in the cell region 20 and the second pad region 10b.

The semiconductor pillars 530 are formed in a plurality of rows which are parallel with the first direction. In an embodiment, the semiconductor pillars 530 include first to eighth semiconductor pillars 530a1, 530a2, 530a3, 530a4, 530a5, 530a6, 530a7 and 530a8, which are respectively arrayed in first to eighth rows.

Further, the sacrificial layers 510 and the insulation layers 520 and 520U are patterned to form second and third trenches 542 and 546. The second trenches 542 are formed between the plurality of rows in the cell region 20 to be parallel with the first direction. The third trenches 546 are formed to be parallel with the second direction. The third trenches 546 connect ends of the second trenches 542 to each other. For example, the third trenches 546 are formed to spatially connect the second trenches 542 in series.

The first to third trenches 544, 542 and 546 split the sacrificial layers 510 and the insulation layers 520 and 520U into first to fourth preliminary stack structures PST1, PST2, PST3 and PST4. Each of the first to fourth preliminary stack structures PST1, PST2, PST3 and PST4 includes stacked sacrificial patterns 510a and stacked insulation patterns 520a and 520Ua. As a result, preliminary stack structures PST1, PST2, PST3 and PST4 are separated from each other by the trenches 544, 542 and 546. The first and fourth preliminary stack structures PST1 and PST4 have substantially the same shape, and the second and third preliminary stack structures PST2 and PST3 have substantially the same shape.

While the semiconductor pillars 530 one-dimensionally arrayed in the first direction constitute a row, the semiconductor pillars 530 one-dimensionally arrayed in the second direction constitute a column. According to an embodiment, each row includes three or more semiconductor pillars 530.

In an embodiment, the first and third semiconductor pillars 530a1 and 530a3 penetrate the first preliminary stack structure PST1, and the second and fourth semiconductor pillars 530a2 and 530a4 penetrate the third preliminary stack structure PST3. The fifth and seventh semiconductor pillars 530a5 and 530a7 penetrate the fourth preliminary stack structure PST4, and the sixth and eighth semiconductor pillars 530a6 and 530a8 penetrate the second preliminary stack structure PST2.

In an embodiment, prior to formation of the first, second and third trenches 544, 542 and 546, a capping insulation layer is additionally formed on the insulation layers 520 and 520U, the sacrificial layers 510, the pattern structures 504a and 504b, and the semiconductor pillars 530. According to an embodiment, the capping insulation layer is patterned while the first, second and third trenches 544, 542 and 546 are formed. For convenience of description, the capping insulation layer is not illustrated in FIG. 25B.

Referring to FIG. 25C, the sacrificial patterns 510a exposed by the first to third trenches 544, 542 and 546 are partially removed to form recessed regions 545. Specifically, the sacrificial patterns 510a between the insulation patterns 520a and 520Ua in the cell region 20 are completely removed to expose the semiconductor pillars 530 between the insulation patterns 520a and 520Ua.

Referring to FIG. 25D, in the same manner as described with reference with FIG. 20F, a data storage layer 550 and a gate conductive layer are sequentially formed on the substrate including the recessed regions 545, and the gate conductive layer positioned outside the recessed regions 545 is removed. As a result, conductive patterns, pad patterns PPb1, PPb2, PPb3 and PPb4, and auxiliary pad patterns APPb1, APPb2, APPb3 and APPb4 are formed in the recessed regions 545, thus providing first to fourth stack structures ST1, ST2, ST3, and ST4 on the substrate 500. The first stack structure ST1 includes the insulation patterns 520a and 520Ua, the conductive patterns between the insulation patterns 520a and 520Ua, the pad patterns PPb1 and the auxiliary pad patterns APPb1, and the second stack structure ST2 includes the insulation patterns 520a and 520Ua, the conductive patterns between the insulation patterns 520a and 520Ua, the pad patterns PPb2 and the auxiliary pad patterns APPb2. Similarly, the third stack structure ST3 includes the insulation patterns 520a and 520Ua, the conductive patterns between the insulation patterns 520a and 520Ua, the pad patterns PPb3 and the auxiliary pad patterns APPb3, and the fourth stack structure ST4 includes the insulation patterns 520a and 520Ua, the conductive patterns between the insulation patterns 520a and 520Ua, the pad patterns PPb4 and the auxiliary pad patterns APPb4.

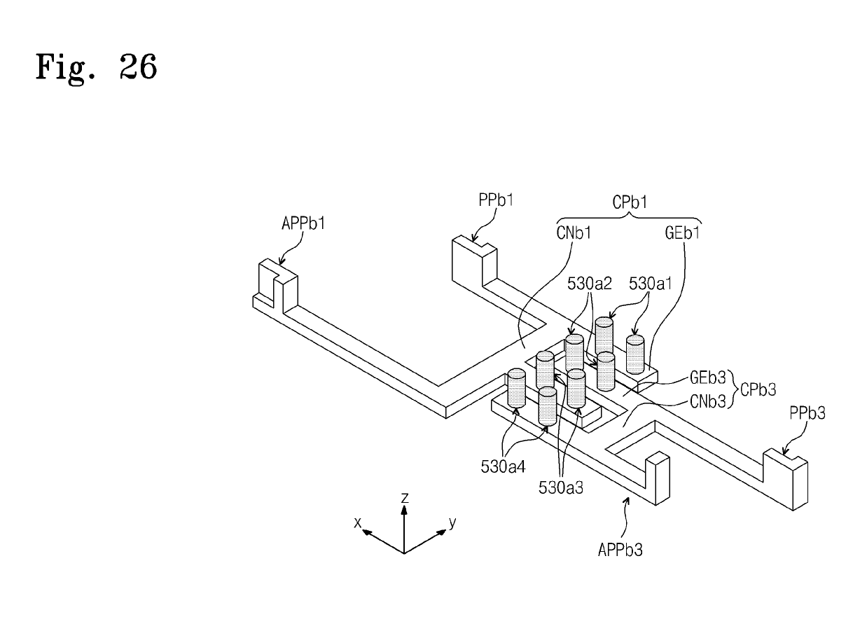

The conductive patterns surrounding the first and third semiconductor pillars 530a1 and 530a3 arrayed in the first and third rows are connected to the first pad patterns PPb1 in the first stack structure ST1, and the conductive patterns surrounding the second and fourth semiconductor pillars 530a2 and 530a4 arrayed in the second and fourth rows are connected to the third pad patterns PPb3 in the third stack structure ST3. Similarly, the conductive patterns surrounding the sixth and eighth semiconductor pillars 530a6 and 530a8 arrayed in the sixth and eighth rows are connected to the second pad patterns PPb2 in the second stack structure ST2, and the conductive patterns surrounding the fifth and seventh semiconductor pillars 530a5 and 530a7 arrayed in the fifth and seventh rows are connected to the fourth pad patterns PPb4 in the fourth stack structure ST4. The relationships between the conductive patterns and the pad patterns are described in more detail with reference to FIG. 26.

FIG. 26 is a perspective view illustrating conductive patterns and pad patterns of a semiconductor device fabricated according to an exemplary embodiment. Specifically, FIG. 26 illustrates conductive patterns, pad patterns, auxiliary pad patterns and semiconductor pillars included in the first and third stack structures ST1 and ST3 of the semiconductor device according to an exemplary embodiment.

Referring to FIGS. 25D and 26, a first conductive pattern CPb1 disposed in the first stack structure ST1 includes first gate electrodes GEb1 and a first connector CNb1 connecting first ends of the first gate electrodes GEb1 to each other. A third conductive pattern CPb3 disposed in the third stack structure ST3 includes third gate electrodes GEb3 and a third connector CNb3 connecting first ends of the third gate electrodes GEb3 to each other. The first and third conductive patterns CPb1 and CPb3 are located at the same level from the substrate 500. One of the first gate electrodes GEb1 is disposed between the two adjacent third gate electrodes GEb3, and one of the third gate electrodes GEb3 is disposed between the two adjacent first gate electrodes GEb1. The first and third conductive patterns CPb1 and CPb3 are electrically insulated from each other.

The first and third semiconductor pillars 530a1 and 530a3 penetrate the first conductive pattern CPb1 (e.g., the first gate electrodes GEb1). The first pad pattern PPb1 is connected to a first end of the first connector CNb1, and the first auxiliary pad pattern APPb 1 is connected to a second end of the first connector CNb1. The second and fourth semiconductor pillars 530a2 and 530a4 penetrate the third conductive pattern CPb3 (e.g., the third gate electrodes GEb3). The third pad pattern PPb3 is connected to a first end of the third connector CNb3, and the third auxiliary pad pattern APPb3 is connected to a second end of the third connector CNb3. The first pad pattern PPb1 extends from the first connector CNb1 in a positive x-axis direction, and the third pad pattern PPb3 extends from the third connector CNb3 in a negative x-axis direction opposite to the positive x-axis direction.

Subsequently, referring again to FIG. 25D, an isolation pattern 564 is formed in the trenches 544, 542 and 546.

An interlayer insulation layer is formed on the substrate including the isolation pattern 564. Cell contact plugs and the bit line contact plugs are formed to penetrate the interlayer insulation layer, as described with reference to FIG. 18. The bit line contact plugs are connected to respective ones of the semiconductor pillars 530, and the cell contact plugs are connected to respective ones of the pad patterns PPb1, PPb2, PPb3 and PPb4. Bit lines and conductive interconnection lines are formed on the interlayer insulation layer. The bit lines are connected to the bit line contact plugs, and the conductive interconnection lines are connected to the cell contact plugs.

Prior to formation of the interlayer insulation layer, an insulation separating pattern is formed to penetrate the uppermost insulation pattern 520Ua and to extend in the second direction, as described with reference to FIG. 20G. The insulation separating pattern is formed to penetrate the uppermost conductive patterns that are provided in the interface regions between the pad regions 10a and 10b and the cell region 20. Thus, string selection lines are formed between the uppermost insulation pattern 520Ua and the insulation pattern 520a under the uppermost insulation pattern 520Ua.

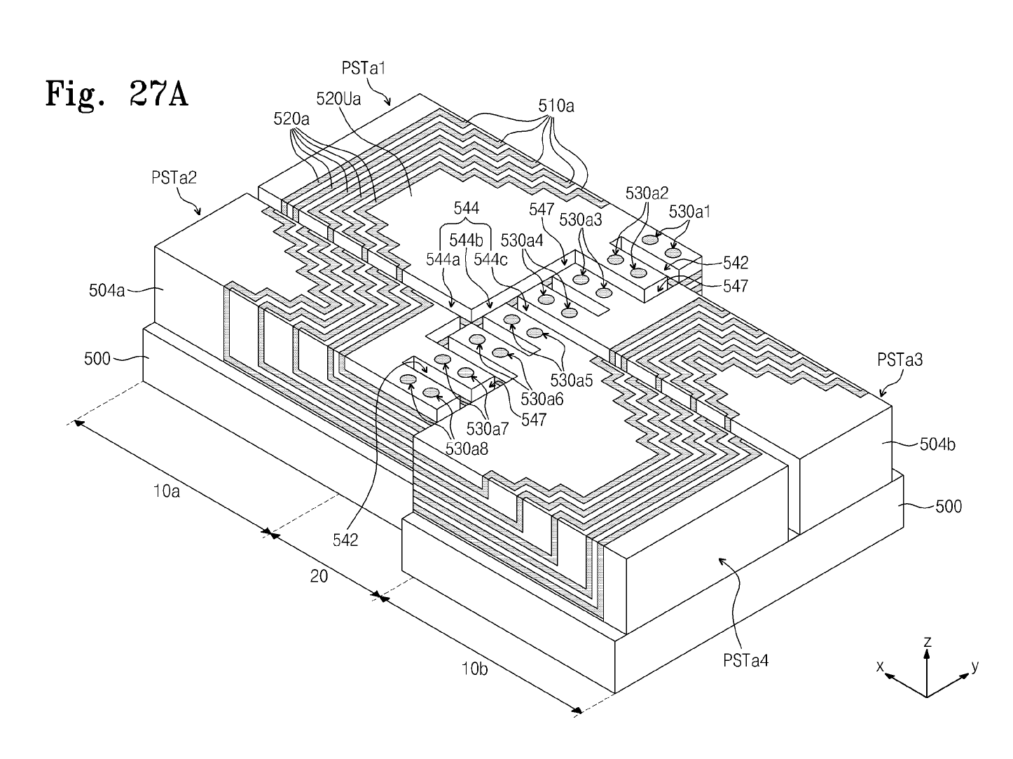

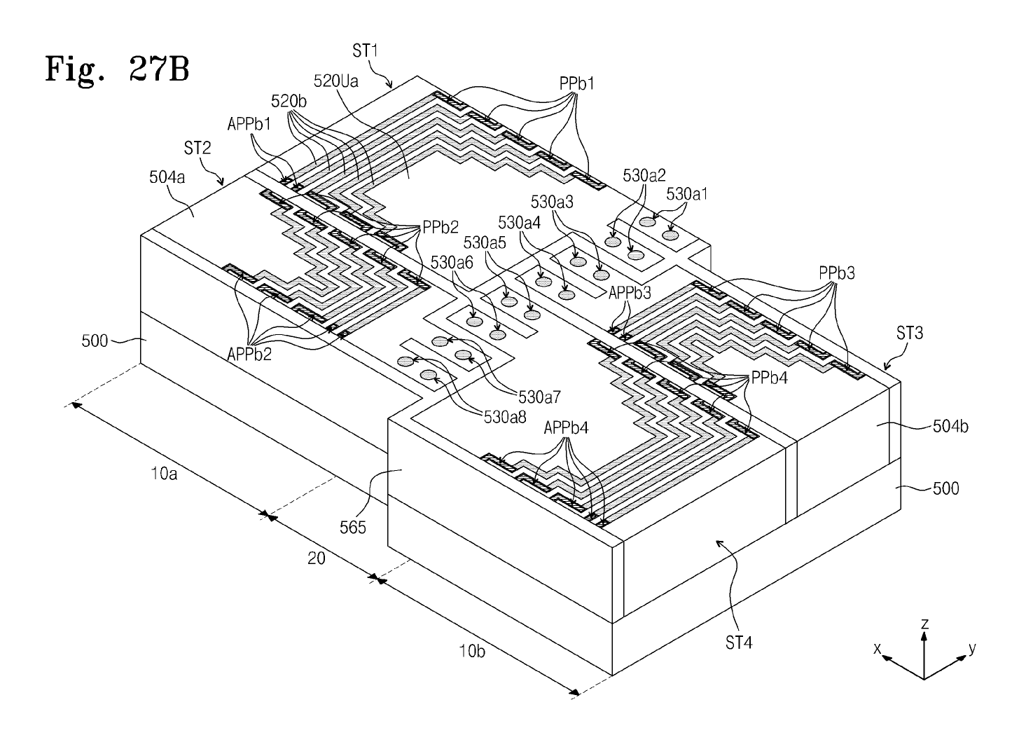

A method of fabricating a semiconductor device according to an exemplary embodiment and a semiconductor device fabricated by the method are now described. FIGS. 27A and 27B are perspective views illustrating a method of fabricating a semiconductor device according to an exemplary embodiment and a semiconductor device fabricated by the method. The method and the semiconductor device are similar to the method and the semiconductor device described above in connection with FIGS. 25A to 26. Differences between the two methods or the two semiconductor devices are mainly described hereinafter.

Referring to FIG. 27A, the substrate 500, the pattern structures 504a and 504b, the semiconductor pillars 530 (e.g., 530a1 to 530a8) arrayed in rows, the sacrificial patterns 510, and the insulation patterns 520 and 520U, which are described with reference to FIG. 25A, are provided.

The pattern structures 504a and 504b, the sacrificial patterns 510, and the insulation patterns 520 and 520U are patterned to form the first trench 544 described with reference to FIG. 25B. The sacrificial patterns 510 and the insulation patterns 520 and 520U are patterned to form second and third trenches 542 and 547. The second trenches 542 are formed between the rows, as described with reference to FIG. 25B. The third trenches 547 connect the second trenches 542 to each other so that the semiconductor pillars 530 arrayed in the two adjacent rows are allocated in any one of first to fourth preliminary stack structures PSTa1, PSTa2, PSTa3 and PSTa4, as illustrated in FIG. 27A.

The first to third trenches 544, 542 and 547 split the sacrificial patterns 510 and the insulation patterns 520 and 520U into a plurality of preliminary stack structures, for example, the first to fourth preliminary stack structures PSTa1, PSTa2, PSTa3 and PSTa4. Each of the preliminary stack structures PSTa1, PSTa2, PSTa3 and PSTa4 includes sacrificial patterns 510a and insulation patterns 520a and 520Ua. The preliminary stack structures PSTa1, PSTa2, PSTa3 and PSTa4 are spaced apart from each other by the first to third trenches 544, 542 and 547. The first and fourth preliminary stack structures PSTa1 and PSTa4 have substantially the same shape, and the second and third preliminary stack structures PSTa2 and PSTa3 have substantially the same shape.

The first and second semiconductor pillars 530a1 and 530a2 arrayed in first and second rows penetrate the first preliminary stack structure PSTa1, and the third and fourth semiconductor pillars 530a3 and 530a4 arrayed in third and fourth rows penetrate the third preliminary stack structure PSTa3. The fifth and sixth semiconductor pillars 530a5 and 530a6 arrayed in fifth and sixth rows penetrate the fourth preliminary stack structure PSTa4, and the seventh and eighth semiconductor pillars 530a7 and 530a8 arrayed in seventh and eighth rows penetrate the second preliminary stack structure PSTa2.

In an embodiment, prior to formation of the first, second and third trenches 544, 542 and 547, a capping insulation layer is formed on the insulation layers 520 and 520U, the sacrificial layers 510, the pattern structures 504a and 504b, and the semiconductor pillars 530. According to an embodiment, the capping insulation layer is patterned while the first, second and third trenches 544, 542 and 547 are formed. For convenience of description, the capping insulation layer is not illustrated in FIG. 27A.

Referring to FIG. 27B, as described with reference to FIGS. 25C and 25D, the sacrificial patterns 510a exposed by the first to third trenches 544, 542 and 547 are partially removed to form recessed regions, and conductive patterns, pad patterns PPb1, PPb2, PPb3 and PPb4, and auxiliary pad patterns APPb1, APPb2, APPb3 and APPb4 are formed in the recessed regions. As a result, first to fourth stack structures ST1a, ST2a, ST3a, and ST4a are formed on the substrate 500. The first stack structure ST1a includes the first pad patterns PPb1 and the first auxiliary pad patterns APPb1, and the second stack structure ST2a includes the second pad patterns PPb2 and the second auxiliary pad patterns APPb2. Similarly, the third stack structure ST3a includes the third pad patterns PPb3 and the third auxiliary pad patterns APPb3, and the fourth stack structure ST4a includes the fourth pad patterns PPb4 and the fourth auxiliary pad patterns APPb4.

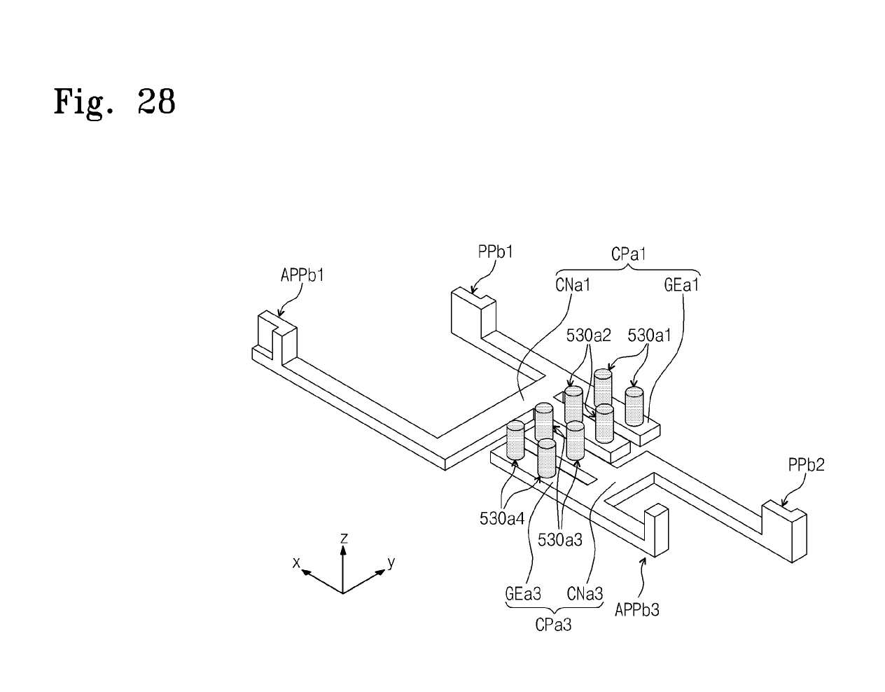

The conductive patterns surrounding the first and second semiconductor pillars 530a1 and 530a2 arrayed in the first and second rows are connected to the first pad patterns PPb1 in the first stack structure ST1a, and the conductive patterns surrounding the third and fourth semiconductor pillars 530a3 and 530a4 arrayed in the third and fourth rows are connected to the third pad patterns PPb3 in the third stack structure ST3a. Similarly, the conductive patterns surrounding the fifth and sixth semiconductor pillars 530a5 and 530a6 arrayed in the fifth and sixth rows are connected to the fourth pad patterns PPb4 in the fourth stack structure ST4a, and the conductive patterns surrounding the seventh and eighth semiconductor pillars 530a7 and 530a8 arrayed in the seventh and eighth rows are connected to the second pad patterns PPb2 in the second stack structure ST2a. The conductive patterns and the pad patterns are described in more detail with reference to FIG. 28.

FIG. 28 is a perspective view illustrating conductive patterns and pad patterns of a semiconductor device fabricated according to an exemplary embodiment Specifically, FIG. 28 illustrates conductive patterns, pad patterns, auxiliary pad patterns and semiconductor pillars included in the first and third stack structures ST1a and ST3a of the semiconductor device according to an exemplary embodiment.

Referring to FIGS. 27B and 28, a first conductive pattern CPa1 disposed in the first stack structure ST1a includes first gate electrodes GEa1 and a first connector CNa1 connecting first ends of the first gate electrodes GEa1 to each other. A third conductive pattern CPa3 disposed in the third stack structure ST3a includes third gate electrodes GEa3 and a third connector CNa3 connecting first ends of the third gate electrodes GEa3 to each other. The first and third conductive patterns CPa1 and CPa3 are located at the same level from the substrate 500. The first connector CNa1 is formed in an interface region between the first pad region 10a and the cell region 20, and the third connector CNa3 is formed in an interface region between the second pad region 10b and the cell region 20. The first gate electrodes GEa1 are disposed to surround the first and second semiconductor pillars 530a1 and 530a2, and the third gate electrodes GEa3 are disposed to surround the third and fourth semiconductor pillars 530a3 and 530a4. Thus, no first gate electrodes GEa1 are disposed between the third gate electrodes GEa3, and no third gate electrodes GEa3 are disposed between the first gate electrodes GEa1.

The first and second semiconductor pillars 530a1 and 530a2 penetrate the first conductive pattern CPa1 (e.g., the first gate electrodes GEa1). The first pad pattern PPb1 is connected to a first end of the first connector CNa1, and the first auxiliary pad pattern APPb1 is connected to a second end of the first connector CNa1. The third and fourth semiconductor pillars 530a3 and 530a4 penetrate the third conductive pattern CPa3 (e.g., the third gate electrodes GEa3). The third pad pattern PPb3 is connected to a first end of the third connector CNa3, and the third auxiliary pad pattern APPb3 is connected to a second end of the third connector CNa3. The first pad pattern PPb1 extends from the first connector CNa1 in a positive x-axis direction, and the third pad pattern PPb3 extends from the third connector CNa3 in a negative x-axis direction opposite to the positive x-axis direction.

Subsequently, referring to FIG. 27B, an isolation pattern 565 is formed in the trenches 544, 542 and 547. An interlayer insulation layer is formed on the substrate including the isolation pattern 565. Cell contact plugs and the bit line contact plugs are formed to penetrate the interlayer insulation layer, as described with reference to FIG. 18. The bit line contact plugs are connected to respective ones of the semiconductor pillars 530, and the cell contact plugs are connected to respective ones of the pad patterns PPb1, PPb2, PPb3 and PPb4. Bit lines and conductive interconnection lines are formed on the interlayer insulation layer. The bit lines are connected to the bit line contact plugs, and the conductive interconnection lines are connected to the cell contact plugs.

Prior to formation of the interlayer insulation layer, an insulation separating pattern is formed to penetrate the uppermost insulation pattern 520Ua and to extend in the second direction, as described with reference to FIG. 20G. The insulation separating pattern is formed to penetrate the uppermost conductive patterns that are provided in the interface regions between the pad regions 10a and 10b and the cell region 20. Thus, string selection lines are formed between the uppermost insulation pattern 520Ua and the insulation pattern 520a under the uppermost insulation pattern 520Ua.

The semiconductor devices according to the foregoing exemplary embodiments are encapsulated by various packaging techniques, such as, for example, a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique, or a wafer-level processed stack package (WSP) technique. According to an embodiment, the package in which the semiconductor device is mounted further includes a controller device and/or a logic device that controls the semiconductor device.

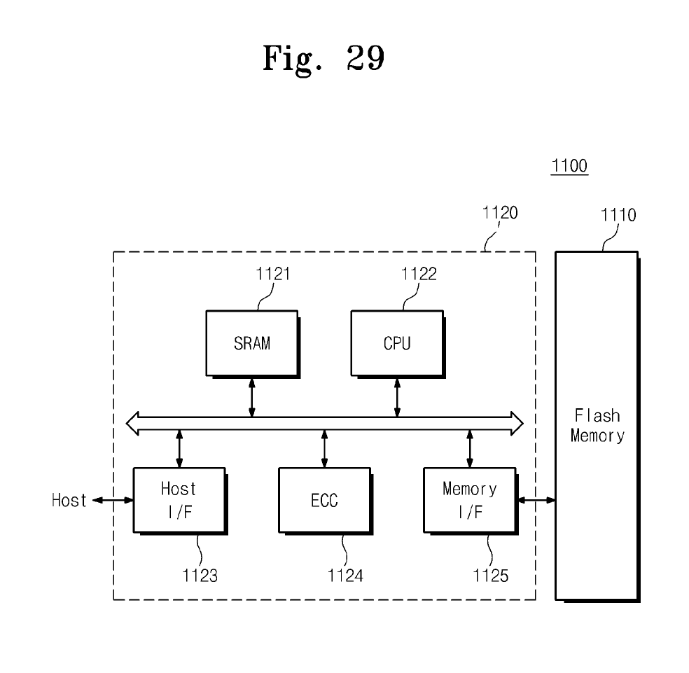

FIG. 29 is a schematic block diagram illustrating an exemplary memory card including a semiconductor device according to an exemplary embodiment.

Referring to FIG. 29, a memory card 1100 includes a memory device 1110, for example, a flash memory device. The memory device 1110 includes at least one of the semiconductor devices according to the various embodiments described above. In an embodiment, the memory device 1110 further includes another type of semiconductor devices which are different from the semiconductor devices according to the embodiments described above. For example, the memory device 1110 further includes a magnetic memory device, a phase change memory device, a dynamic random access memory (DRAM) device and/or a static random access memory (SRAM) device. The memory card 1100 further includes a memory controller 1120 that controls data communication between a host and the memory device 1110.

The memory controller 1120 includes a central processing unit (CPU) 1122 that controls overall operation of the memory card 1100. The memory controller 1120 includes an SRAM device 1121 used as an operation memory of the CPU 1122. Moreover, the memory controller 1220 further includes a host interface unit 1123 and a memory interface unit 1125. The host interface unit 1123 is configured to include a data communication protocol between the memory card 1100 and the host. The memory interface unit 1125 connects the memory controller 1120 to the memory device 1110. The memory controller 1120 further includes an error check and correction (ECC) block 1124. The ECC block 1124 detects and corrects errors of data which are read out from the memory device 1110. According to an embodiment, the memory card 1100 further includes a read only memory (ROM) device that stores code data to interface with the host. The memory card 1100 is used as a portable data storage card. Alternatively, the memory card 1100, instead of hard disks of computer systems, includes solid state disks of the computer systems.

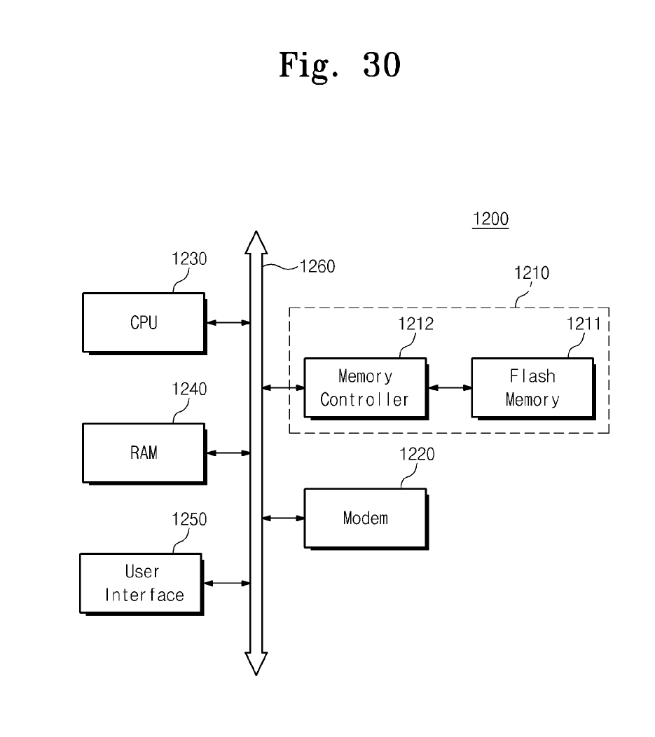

FIG. 30 is a block diagrams illustrating an exemplary information processing system including a semiconductor devices according to an exemplary embodiments.

Referring to FIG. 30, an information processing system 1200 includes a memory system 1210, and the memory system 1210 includes at least one of the semiconductor devices (e.g., a flash memory device) according to the exemplary embodiments. The information processing system 1200 is applied to a mobile system, a computer or the like.

In an embodiment, the information processing system 1200 further includes a modulator-demodulator (MODEM) 1220, a central processing unit (CPU) 1230, a random access memory (RAM) device 1240 and a user interface unit 1250. The memory system 1210, the modulator-demodulator (MODEM) 1220, the central processing unit (CPU) 1230, the random access memory (RAM) device 1240 and the user interface unit 1250 communicate with each other through a data bus 1260. The memory system 1210 stores data processed by the CPU 1230 or data transmitted from an external system. The memory system 1210 includes a flash memory device 1211 and a memory controller 1212, and is configured to have substantially the same structure as the memory card 1100 illustrated in FIG. 29. The memory controller 1212 controls overall operation of the memory device 1211. The information processing system 1200 is configured to include a memory card, a solid state disk, a camera image processor or an application chipset. In an embodiment, the memory system 1210 includes the solid state disk. According to an embodiment, the information processing system 1200 exhibits a stable and reliable operation since the solid state disk can stably store a large capacity of data.

According to the embodiments set forth above, a plurality of conductive patterns, which are vertically stacked to act as gate electrodes are provided, and pad patterns electrically connected to the stacked conductive patterns are provided. Each of the pad patterns includes a flat portion horizontally extending from the conductive pattern in a first direction and a landing sidewall portion upwardly extending from the flat portion. A width of the each of the landing sidewall portions in the first direction is greater than a width thereof in a second direction intersecting the first direction. Thus, contact holes exposing the landing sidewall portions electrically connected to the conductive patterns are formed to have a uniform depth, and an alignment margin between the contact holes and the landing sidewall portions may be increased. As a result, a high reliable semiconductor device can be realized.

While the embodiments of the inventive concept has been described, it will be apparent to those skilled in the art that various changes and modifications may be made without departing from the spirit and scope of the embodiments of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A semiconductor device comprising:
conductive patterns vertically stacked on a substrate, the conductive patterns spaced apart from each other; and
pad patterns electrically connected to respective ones of the conductive patterns,
wherein at least one of the pad patterns includes a flat portion extending from an end of a conductive pattern corresponding to the at least one pad pattern in a first direction parallel with the substrate and a landing sidewall portion upwardly extending from an end of the flat portion, and
wherein a width of a portion of the landing sidewall portion in a second direction parallel with the substrate and perpendicular to the first direction is less than a width of the flat portion in the second direction.

2. The semiconductor device of claim 1, wherein the landing sidewall portion includes a first portion extending in the first direction and a second portion extending in the second direction, and wherein a width of the first portion in the first direction is greater than a thickness of at least one of the conductive patterns in a third direction perpendicular to a top surface of the substrate.

3. The semiconductor device of claim 1, further comprising auxiliary pad patterns extending from respective ones of the conductive patterns in the first direction, the auxiliary pad patterns spaced apart from the pad patterns,
wherein at least one of the auxiliary pad patterns includes an auxiliary flat portion parallel with the substrate and an auxiliary sidewall portion upwardly extending from an end of the auxiliary flat portion.

4. The semiconductor device of claim 3, a top surface area of the auxiliary sidewall portion is equal to a top surface area of the landing sidewall portion in a plan view.

5. The semiconductor device of claim 1, wherein the conductive patterns include first and second conductive patterns spaced apart from each other, the first and second conductive patterns located at the same level from the substrate,
wherein the first conductive pattern includes first gate electrodes and a first connector connecting first ends of the first gate electrodes to each other,
wherein the second conductive pattern includes second gate electrodes and a second connector connecting first ends of the second gate electrodes to each other,
wherein one of the first gate electrodes is disposed between the second gate electrodes, and
wherein one of the second gate electrodes is disposed between the first gate electrodes.

6. The semiconductor device of claim 5, wherein the pad patterns include a first pad pattern extending from the first connector in the first direction and a second pad pattern extending from the second connector in a direction opposite to the first direction.

7. The semiconductor device of claim 1, wherein the conductive patterns include first and second conductive patterns spaced apart from each other, the first and second conductive patterns located at the same level from the substrate,
wherein the first conductive pattern includes first gate electrodes and a first connector connecting first ends of the first gate electrodes to each other,
wherein the second conductive pattern includes second gate electrodes and a second connector connecting first ends of the second gate electrodes to each other,
wherein the first gate electrodes are not disposed between the second gate electrodes, and wherein the second gate electrodes are not disposed between the first gate electrodes.

8. The semiconductor device of claim 1, further comprising:
semiconductor pillars penetrating the conductive patterns; and
a data storage layer between the semiconductor pillars and the conductive patterns.

9. The semiconductor device of claim 1, further comprising a contact plug on the landing sidewall portion.

10.-14. (canceled)

15. A semiconductor device comprising:
a first conductive pattern, an insulation pattern, and a second conductive pattern sequentially formed on a substrate, and
a first pad pattern and a second pad pattern, wherein the first pad pattern has a first portion extending in a first direction from an end of the first conductive pattern and a second portion extending from the first portion of the first pad pattern in a second direction perpendicular to the first direction and wherein the second pad pattern has a first portion extending in the first direction from an end of the second conductive pattern and a second portion extending from the first portion of the second pad pattern,
wherein the first portion of the first pad pattern is longer than the first portion of the second pad pattern in the first direction.

16. The semiconductor device of claim 15, wherein a width of the second portion of the first pad pattern or the second pad pattern in a third direction perpendicular to the first direction and parallel with a top surface of the substrate is smaller than a width of the first portion of the first pad pattern or the second pad pattern in the third direction.

17. The semiconductor device of claim 15, wherein the second portion of the first pad pattern or the second pad pattern is shaped as L when viewed in a direction opposite to the second direction.

18. The semiconductor device of claim 15, further comprising:
a first auxiliary pad pattern and a second auxiliary pad pattern, wherein the first auxiliary pad pattern has a first portion extending in the first direction from an end of the first conductive pattern and a second portion extending from the first portion of the first auxiliary pad pattern in the second direction, and wherein the second auxiliary pad pattern has a first portion extending in the first direction from an end of the second conductive pattern and a second portion extending from the first portion of the second auxiliary pad pattern, wherein the first portion of the first auxiliary pad pattern is longer than the first portion of the second auxiliary pad pattern in the first direction, and wherein the first auxiliary pad pattern is spaced apart from the first pad pattern in a third direction perpendicular to the first direction and parallel with a top surface of the substrate, and the second auxiliary pad pattern is spaced apart from the second pad pattern in the third direction.

19. The semiconductor device of claim 18, wherein a width of the second portion of the first auxiliary pad pattern or the second auxiliary pad pattern in the third direction is the same as a width of the first portion of the first auxiliary pad pattern or the second auxiliary pad pattern in the third direction.

20. The semiconductor device of claim 18, a top surface area of the second portion of the first or second auxiliary pad pattern is the same as a top surface area of the second portion of the first or second pad pattern.
